(19) United States
(12) Patent Application Publication
(10) Pub. No.: US 2026/0274651 A1
(43) Pub. Date: Sep. 17, 2026

(54) THROUGH-HOLE ELECTRODE SUBSTRATE, MEMS DEVICE, MANUFACTURING METHOD OF MEMS DEVICE, AND MULTILAYERED DEVICE

(71) Applicant: TDK CORPORATION, Tokyo (JP)

(72) Inventors: Yoshitaka SASAKI, San Jose, CA (US); Jotaro AKIYAMA, Tokyo (JP); Kenichi TOCHI, Tokyo (JP); Kento KANEKO, Tokyo (JP); Daishi ARIMATSU, Tokyo (JP); Yuki SHIBANO, Tokyo (JP); Sal AKRAM, San Jose, CA (US); Yaoching WANG, San Jose, CA (US)

(73) Assignee: TDK CORPORATION, Tokyo (JP)

(21) Appl. No.: 19/469,089

(22) PCT Filed: Mar. 27, 2024
(86) PCT No.: PCT/JP2024/012511

§ 371 Date: Sep. 25, 2025

Related U.S. Application Data
(60) Provisional application No. 63/492,870, filed on Mar. 29, 2023.

(51) Int. Cl. B81B 7/00; B81C 1/00; H10W 20/00; H10W 20/20

(52) U.S. Cl. CPC B81B 7/007; B81C 1/00301; H10W 20/0245; H10W 20/2134; B81B 2207/096

(57) ABSTRACT

A through-hole electrode substrate includes a substrate including a first surface and a second surface on a side opposite to the first surface, at least one electrode extending from the first surface to the second surface, and an insulating film including a first part extending along the at least one electrode and contacting with the at least one electrode, a second part extending along the first part and being adjacent to the first part, and a boundary surface between the first part and the second part.

### BACKGROUND

The disclosure relates to a through-hole electrode substrate, a MEMS device using a through-hole substrate, a manufacturing method of a MEMS device, and a multilayered device.

As a compact motion sensor incorporated in a smartphone or a tablet terminal, a capacitive-type motion sensor has been known. As a capacitive-type motion sensor, a MEMS device configured such that the static capacitance between an electrode of a movable element and an electrode of a fixed element changes has been known. The MEMS device has a structure for fixing the movable element serving as a weight, and is configured to detect acceleration applied to the movable element.

In recent years, a motion sensor has been increasingly incorporated not only in a smartphone or a tablet terminal, but also in a device such as a game console. As a result, a strong demand exists for price reduction of a motion sensor, and manufacturing cost reduction of a motion sensor is required. When a motion sensor is a MEMS device, formation of a greater number of MEMS device chips from a single wafer is considered as a method for reducing the manufacturing cost, for example. The number of chips per wafer can be increased by reducing a planar area of each chip. The use of a through-electrode substrate is considered as a method for reducing the planar area of the chip, for example.

U.S. Pat. No. 6,841,453 B2 discloses a MEMS device in which a through-hole connection region being an N+region passes through a silicon substrate. U.S. Pat. No. 6,846,690 B2 discloses a MEMS device in which a contact pad passes through a substrate. U.S. Pat. No. 6,750,516 B2 discloses a structure in which a conductor formed of a substrate material such as silicon doped with an impurity passes through a wafer.

### SUMMARY

Herein, description is made on a case in which a through-hole electrode is formed in a chip including a signal processing circuit in a MEMS device. In the related art, for example, the signal processing circuit is formed, and then a plurality of trenches (groove portions) are formed from a chip front surface, an insulating film and an electrode are sequentially formed in the plurality of trenches, a chip back surface is polished so that the electrode is exposed, the insulating film including a contact hole from which the electrode is exposed is formed on the chip back surface, and an electrode pad is formed in the contact hole. In this manner, the through-hole electrode is formed. However, the following problems occur by the method in the related art.

The insulating film in the plurality of trenches requires satisfactory step coverage. Thus, in the related art, the insulating film is formed by the atomic layer deposition (ALD) method, for example. However, in the atomic layer deposition method, there arises a problem in that the time required to form an insulating film having a predetermined thickness is increased, resulting in an increase in manufacturing cost.

When the insulating film is thicker, or an opening of the trench is narrower, a keyhole is generated in the electrode formed in the trench. As a result, there arises a problem in that the resistance of the through-hole electrode is increased. On the other hand, when the insulating film is thinner, there arises a problem in that the parasitic capacitance of the electrode is increased. When the trench is formed after the signal processing circuit is formed, it is necessary to use a plurality of etching gases in order to simultaneously etch the plurality of insulating films and the silicon substrate that are formed of different materials and formed by different methods. Thus, there arises a problem in that the manufacturing cost is increased.

The disclosure has been made in view of such problems, and has an object to provide a through-hole electrode substrate that can achieve manufacturing cost reduction, a MEMS device using the through-hole electrode substrate, and a multilayered device.

A through-hole electrode substrate of the disclosure includes a substrate including a first surface and a second surface on a side opposite to the first surface, at least one electrode extending from the first surface to the second surface, and an insulating film including a first part extending along the at least one electrode and contacting with the at least one electrode, a second part extending along the first part and being adjacent to the first part, and a boundary surface between the first part and the second part.

A MEMS device according to a first aspect of the disclosure is a MEMS device including a movable unit, and a circuit unit and a cap that are arranged to sandwich the movable unit. The circuit unit is configured by using the through-hole electrode substrate of the disclosure.

A manufacturing method of the MEMS device according to the first aspect of the disclosure includes a step of forming the movable unit and the cap, and a step of forming the circuit unit. The step of forming the circuit unit includes a through-hole electrode formation step of forming the at least one electrode and the insulating film on the substrate, and a circuit formation step of forming a signal processing circuit on the substrate.

A MEMS device according to a second aspect of the disclosure includes a movable unit, and a circuit unit and a cap that are arranged to sandwich the movable unit. The cap is configured by using the through-hole electrode substrate of the disclosure.

A manufacturing method of the MEMS device according to the second aspect of the disclosure includes a step of forming the movable unit and the cap, and a step of forming the circuit unit. The step of forming the movable unit and the cap includes a through-hole electrode formation step of forming the at least one electrode and the insulating film on the substrate, a step of forming an insulating portion on the substrate, a step of forming the movable unit on the substrate and the insulating portion, and a step of forming a cavity in the substrate by forming the movable unit and then removing the insulating portion through etching.

A multilayered device of the disclosure includes a plurality of devices being stacked. Each of the plurality of devices is configured by using the through-hole electrode substrate of the disclosure. Among the plurality of devices, the at least one electrode of one of two adjacent devices is electrically connected to the at least one electrode of the other of two adjacent devices.

In the disclosure, the through-hole electrode substrate is configured so that the insulating film includes the first part, the second part, and the boundary surface. With this, according to the disclosure, an effect of achieving manufacturing cost reduction can be exerted.

### BRIEF DESCRIPTION OF THE DRAWINGS

FIG. 1 is a cross-sectional view illustrating a device configured by using a through-hole electrode substrate according to a first embodiment of the disclosure.

FIG. 2 is a cross-sectional view illustrating an electrode having a monolithic structure in the first embodiment of the disclosure.

FIG. 3 is a cross-sectional view illustrating the electrode having a monolithic structure in the first embodiment of the disclosure.

FIG. 4 is a cross-sectional view illustrating a plurality of electrodes having a multilayered structure in the first embodiment of the disclosure.

FIG. 5 is a cross-sectional view illustrating the plurality of electrodes having a multilayered structure in the first embodiment of the disclosure.

FIG. 6 is a cross-sectional view illustrating a step of a method of manufacturing a through-hole electrode substrate according to the first embodiment of the disclosure.

FIG. 7 is a cross-sectional view illustrating a step subsequent to the step illustrated in FIG. 6.

FIG. 8 is a cross-sectional view illustrating a step subsequent to the step illustrated in FIG. 7.

FIG. 9 is a cross-sectional view illustrating a step subsequent to the step illustrated in FIG. 8.

FIG. 10 is a cross-sectional view illustrating a step subsequent to the step illustrated in FIG. 9.

FIG. 11 is a cross-sectional view illustrating a step subsequent to the step illustrated in FIG. 10.

FIG. 12 is a cross-sectional view illustrating a step subsequent to the step illustrated in FIG. 11.

FIG. 13 is a cross-sectional view illustrating a step subsequent to the step illustrated in FIG. 12.

FIG. 14 is a cross-sectional view illustrating a step subsequent to the step illustrated in FIG. 13.

FIG. 15 is a cross-sectional view illustrating a device in a comparative example.

FIG. 16 is a cross-sectional view illustrating a step of a method of manufacturing a through-hole electrode substrate according to a second embodiment of the disclosure.

FIG. 17 is a cross-sectional view illustrating a step subsequent to the step illustrated in FIG. 16.

FIG. 18 is a cross-sectional view illustrating a step subsequent to the step illustrated in FIG. 17.

FIG. 19 is a cross-sectional view illustrating a step subsequent to the step illustrated in FIG. 18.

FIG. 20 is a cross-sectional view illustrating a step subsequent to the step illustrated in FIG. 19.

FIG. 21 is a cross-sectional view illustrating an electrode having a monolithic structure in a third embodiment of the disclosure.

FIG. 22 is a cross-sectional view illustrating an electrode having a multilayered structure in the third embodiment of the disclosure.

FIG. 23 is a cross-sectional view illustrating a step of a method of manufacturing a through-hole electrode substrate according to the third embodiment of the disclosure.

FIG. 24 is a cross-sectional view illustrating a step subsequent to the step illustrated in FIG. 23.

FIG. 25 is a cross-sectional view illustrating a step subsequent to the step illustrated in FIG. 24.

FIG. 26 is a cross-sectional view illustrating a step subsequent to the step illustrated in FIG. 25.

FIG. 27 is a cross-sectional view illustrating a step subsequent to the step illustrated in FIG. 26.

FIG. 28 is a cross-sectional view illustrating a step subsequent to the step illustrated in FIG. 27.

FIG. 29 is a cross-sectional view illustrating a step subsequent to the step illustrated in FIG. 28.

FIG. 30 is a cross-sectional view illustrating a step subsequent to the step illustrated in FIG. 29.

FIG. 31 is a cross-sectional view illustrating a step of a method of manufacturing a through-hole electrode substrate according to a fourth embodiment of the disclosure.

FIG. 32 is a cross-sectional view illustrating a step subsequent to the step illustrated in FIG. 31.

FIG. 33 is a cross-sectional view illustrating a step of a method of manufacturing a through-hole electrode substrate according to a fifth embodiment of the disclosure.

FIG. 34 is a cross-sectional view illustrating a step subsequent to the step illustrated in FIG. 33.

FIG. 35 is a cross-sectional view illustrating a step subsequent to the step illustrated in FIG. 34.

FIG. 36 is a cross-sectional view illustrating a step subsequent to the step illustrated in FIG. 35.

FIG. 37 is a cross-sectional view illustrating a step subsequent to the step illustrated in FIG. 36.

FIG. 38 is a cross-sectional view illustrating a MEMS device according to the sixth embodiment of the disclosure.

FIG. 39 is a plan view illustrating the MEMS device according to the sixth embodiment of the disclosure.

FIG. 40 is a block diagram illustrating a configuration of the MEMS device according to the sixth embodiment of the disclosure.

FIG. 41 is a cross-sectional view illustrating a first example of a state in which the MEMS device according to the sixth embodiment of the disclosure is mounted on a mounting target object.

FIG. 42 is a cross-sectional view illustrating a second example of a state in which the MEMS device according to the sixth embodiment of the disclosure is mounted on a mounting target object.

FIG. 43 is a cross-sectional view illustrating a step of a manufacturing method of a MEMS device according to the sixth embodiment of the disclosure.

FIG. 44 is a cross-sectional view illustrating a step subsequent to the step illustrated in FIG. 43.

FIG. 45 is a cross-sectional view illustrating a MEMS device in a comparative example.

FIG. 46 is a plan view illustrating the MEMS device in the comparative example.

FIG. 47 is a cross-sectional view illustrating a step of a manufacturing method of a MEMS device according to a seventh embodiment of the disclosure.

FIG. 48 is a cross-sectional view illustrating a step subsequent to the step illustrated in FIG. 47.

FIG. 49 is a cross-sectional view illustrating a step subsequent to the step illustrated in FIG. 48.

FIG. 50 is a cross-sectional view illustrating a step subsequent to the step illustrated in FIG. 49.

FIG. 51 is a cross-sectional view illustrating a step subsequent to the step illustrated in FIG. 50.

FIG. 52 is a cross-sectional view illustrating a step subsequent to the step illustrated in FIG. 51.

FIG. 53 is a cross-sectional view illustrating a MEMS device according to an eighth embodiment of the disclosure.

FIG. 54 is a cross-sectional view illustrating a multilayered device according to a ninth embodiment of the disclosure.

FIG. 55 is a cross-sectional view illustrating a step of a manufacturing method of a MEMS device according to a tenth embodiment of the disclosure.

FIG. 56 is a cross-sectional view illustrating a step subsequent to the step illustrated in FIG. 55.

FIG. 57 is a cross-sectional view illustrating a step subsequent to the step illustrated in FIG. 56.

FIG. 58 is a cross-sectional view illustrating a step subsequent to the step illustrated in FIG. 57.

FIG. 59 is a cross-sectional view illustrating a step subsequent to the step illustrated in FIG. 58.

FIG. 60 is a cross-sectional view illustrating a step subsequent to the step illustrated in FIG. 59.

FIG. 61 is a cross-sectional view illustrating a step subsequent to the step illustrated in FIG. 60.

FIG. 62 is a cross-sectional view illustrating a step subsequent to the step illustrated in FIG. 61.

FIG. 63 is a cross-sectional view illustrating a step subsequent to the step illustrated in FIG. 62.

FIG. 64 is a cross-sectional view illustrating a step subsequent to the step illustrated in FIG. 63.

FIG. 65 is a cross-sectional view illustrating a step subsequent to the step illustrated in FIG. 64.

FIG. 66 is a cross-sectional view illustrating a step subsequent to the step illustrated in FIG. 65.

FIG. 67 is a cross-sectional view illustrating a step subsequent to the step illustrated in FIG. 66.

FIG. 68 is a cross-sectional view illustrating a step subsequent to the step illustrated in FIG. 67.

FIG. 69 is a cross-sectional view illustrating a step subsequent to the step illustrated in FIG. 68.

FIG. 70 is a cross-sectional view illustrating a step subsequent to the step illustrated in FIG. 69.

FIG. 71 is a cross-sectional view illustrating a step subsequent to the step illustrated in FIG. 70.

FIG. 72 is a cross-sectional view illustrating a step in a modification example of the manufacturing method of a MEMS device according to the tenth embodiment of the disclosure.

FIG. 73 is a cross-sectional view illustrating a step subsequent to the step illustrated in FIG. 72.

FIG. 74 is a cross-sectional view illustrating a step of a manufacturing method of a MEMS device according to an eleventh embodiment of the disclosure.

FIG. 75 is a cross-sectional view illustrating a step subsequent to the step illustrated in FIG. 74.

FIG. 76 is a cross-sectional view illustrating a step subsequent to the step illustrated in FIG. 75.

FIG. 77 is a cross-sectional view illustrating a step subsequent to the step illustrated in FIG. 76.

FIG. 78 is a cross-sectional view illustrating a step of a manufacturing method of a MEMS device according to a twelfth embodiment of the disclosure.

FIG. 79 is a cross-sectional view illustrating a step subsequent to the step illustrated in FIG. 78.

FIG. 80 is a cross-sectional view illustrating a step subsequent to the step illustrated in FIG. 79.

FIG. 81 is a cross-sectional view illustrating a step subsequent to the step illustrated in FIG. 80.

FIG. 82 is a cross-sectional view illustrating a step subsequent to the step illustrated in FIG. 81.

FIG. 83 is a cross-sectional view illustrating a step subsequent to the step illustrated in FIG. 82.

FIG. 84 is a cross-sectional view illustrating a step subsequent to the step illustrated in FIG. 83.

FIG. 85 is a cross-sectional view illustrating a step of a manufacturing method of a MEMS device according to a thirteenth embodiment of the disclosure.

FIG. 86 is a cross-sectional view illustrating a step subsequent to the step illustrated in FIG. 85.

FIG. 87 is a cross-sectional view illustrating a step subsequent to the step illustrated in FIG. 86.

FIG. 88 is a cross-sectional view illustrating a step subsequent to the step illustrated in FIG. 87.

FIG. 89 is a cross-sectional view illustrating a step subsequent to the step illustrated in FIG. 88.

FIG. 90 is a cross-sectional view illustrating a step subsequent to the step illustrated in FIG. 89.

FIG. 91 is a cross-sectional view illustrating a step subsequent to the step illustrated in FIG. 90.

FIG. 92 is a cross-sectional view illustrating a step subsequent to the step illustrated in FIG. 91.

FIG. 93 is a cross-sectional view illustrating a step subsequent to the step illustrated in FIG. 92.

FIG. 94 is a cross-sectional view illustrating a step subsequent to the step illustrated in FIG. 93.

FIG. 95 is a cross-sectional view illustrating a step subsequent to the step illustrated in FIG. 94.

FIG. 96 is a cross-sectional view illustrating a step subsequent to the step illustrated in FIG. 95.

FIG. 97 is a cross-sectional view illustrating a MEMS device according to a fourteenth embodiment of the disclosure.

### DETAILED DESCRIPTION

### First Embodiment

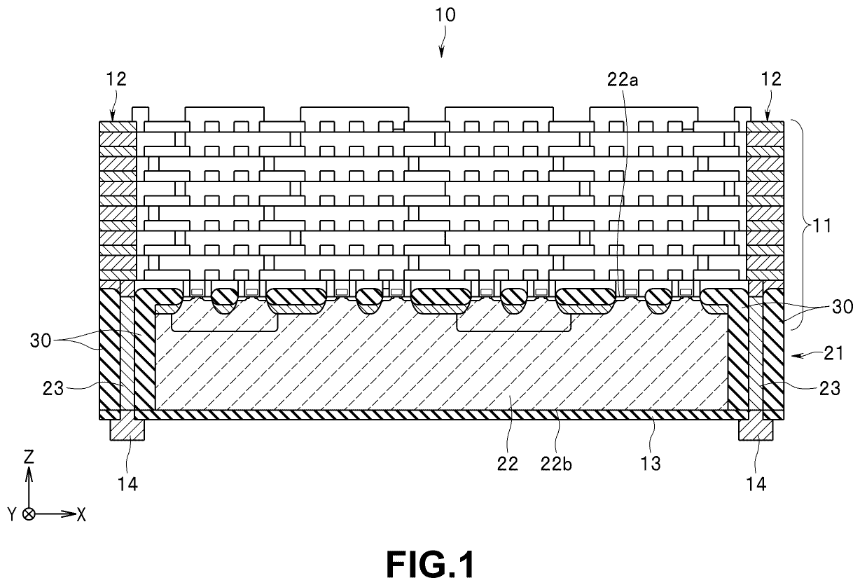

Embodiments of the present invention are described below in detail with reference to the drawings. First, with reference to FIG. 1, description is made on an outline of a device configured by using a through-hole electrode substrate according to a first embodiment of the disclosure. FIG. 1 is a cross-sectional view the device in illustrating the present embodiment. A through-hole electrode substrate 21 according to the present embodiment includes a substrate 22 and at least one electrode. The substrate 22 includes a first surface 22a and a second surface 22b on a side opposite to the first surface 22a. The at least one electrode extends from the first surface 22a to the second surface 22b, and substantially passes through the substrate 22. In the present embodiment, the through-hole electrode substrate 21 includes a plurality of electrodes 23 as the at least one electrode.

The through-hole electrode substrate 21 further includes an insulating film 30 that provides insulation between the substrate 22 and the plurality of electrodes 23.

The insulating film 30 is formed of SiO₂, for example.

Here, as illustrated in FIG. 1, an X direction, a Y direction, and a Z direction are defined. The X direction, the Y direction, and the Z direction are orthogonal to one another. In the present embodiment, a direction that is vertical to the first surface 22a of the substrate 22 and extends from the second surface 22b to the first surface 22a is defined as the Z direction. A direction opposite to the X direction is defined as a-X direction, a direction opposite to the Y direction is defined as a −Y direction, and a direction opposite to the Z direction is defined as a −Z direction.

Hereinafter, a position located ahead in the Z direction with respect to a reference position is referred to as “upper”, and a position located on a side opposite to the “upper” side with respect to the reference position is referred to as “lower”. With regard to the constituent elements of the through-hole electrode substrate 21, a surface positioned at an end in the Z direction is referred to as an “upper surface”, and a surface positioned at an end in the −Z direction is referred to as a “lower surface”. The expression “as viewed in a predetermined direction (for example, the Z direction)” indicates that a target object is viewed from a position that is separated in a predetermined direction or in a direction parallel to the predetermined direction.

FIG. 1 illustrates an arbitrary device 10 configured by using the through-hole electrode substrate 21. For example, the device 10 may be a processor including a signal processing circuit, or a memory chip including a storage circuit. In the example illustrated in FIG. 1, the substrate 22 is a silicon substrate. The device 10 includes the substrate 22 and a circuit part 11 formed on the first surface 22a of the substrate 22.

The circuit part 11 includes a plurality of electrode portions 12. The plurality of electrode portions 12 are arranged above the plurality of electrodes 23, and are connected to the plurality of electrodes 23, respectively. Each of the plurality of electrode portions 12 includes at least one conductive layer. When the at least one conductive layer includes a plurality of conductive layers, the plurality of conductive layers may be stacked in the Z direction. The at least one conductive layer may be formed of a metal material, or may be formed of polysilicon.

The device 10 further includes an insulating film 13 that covers the second surface 22b of the substrate 22. The insulating film 13 is formed of SiO₂, for example. The insulating film 13 includes a plurality of opening portions from which the plurality of electrodes 23 are exposed respectively. The device 10 further includes a plurality of electrode pads 14 that are connected to the plurality of electrodes 23 via the plurality of opening portions, respectively.

Next, a configuration of the electrode 23 is described in detail. One electrode 23 may be connected to one electrode portion 12 and one electrode pad 14. Alternatively, a plurality of electrodes 23 may be connected to one electrode portion 12 and one electrode pad 14. Hereinafter, a structure in which one electrode 23 is connected to one electrode portion 12 and one electrode pad 14 is referred to as a monolithic structure, and a structure in which a plurality of electrodes 23 are connected to one electrode portion 12 and one electrode pad 14 is referred to as a multilayer structure.

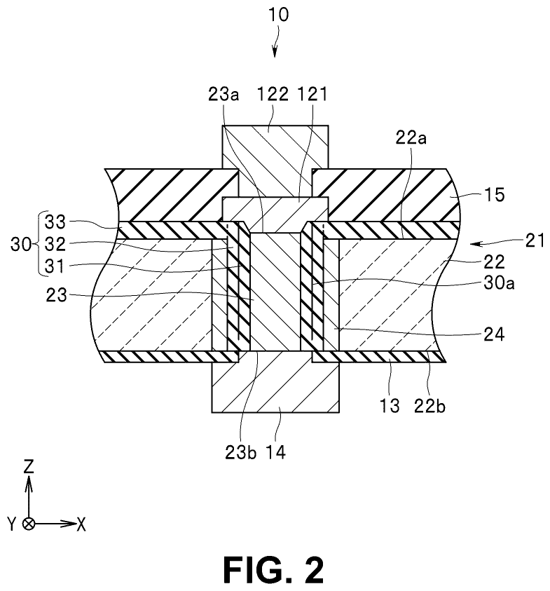

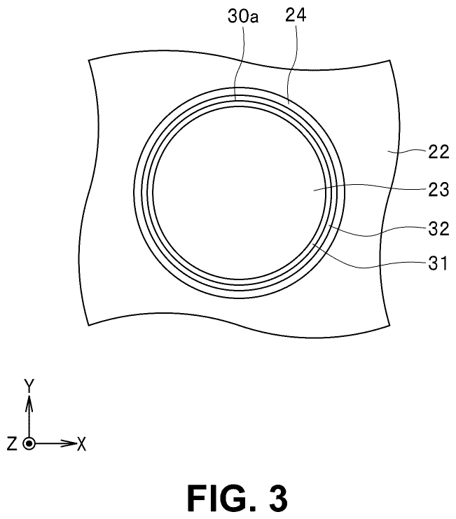

First, with reference to FIG. 2 and FIG. 3, the electrode 23 having a monolithic structure is described. FIG. 2 and FIG. 3 are cross-sectional views illustrating the electrode 23 having a monolithic structure. FIG. 2 illustrates a cross-section vertical to the Y direction. FIG. 3 illustrates a cross-section vertical to the Z direction.

In the monolithic structure, the insulating film 30 is provided in the periphery of one electrode 23. The insulating film 30 includes a first part 31 that extends along the electrode 23 and contacts with the electrode 23, a second part 32 that extends along the first part 31 and is adjacent to the first part 31, and the boundary surface 30a between the first part 31 and the second part 32. The first part 31 and the second part 32 may be continuous to each other, or may not be continuous to each other. FIG. 2 illustrates an example in which the first part 31 and the second part 32 are continuous to each other. As illustrated in FIG. 3, the electrode 23 is surrounded doubly by the first part 31 and the second part 32.

The insulating film 30 further includes a third part 33 arranged on the first surface 22a of the substrate 22. A total thickness of the first part 31 and the second part 32 is equal to or more than a thickness of the third part 33. The second part 32 and the third part 33 may be continuous to each other, or may not be continuous to each other. Alternatively, the insulating film 30 may include the third part 33 that is continuous to the second part 32, and the third part 33 that is not continuous to the second part 32. FIG. 2 illustrates the third part 33 that is continuous to the second part 32. In FIG. 2, the boundary between the second part 32 and the third part 33 is indicated by the dot line.

FIG. 1 illustrates both the third part 33 that is continuous to the second part 32 and the third part 33 that is not continuous to the second part 32. For example, when a plurality of CMOS circuits are formed on the substrate 22, the third part 33 that is not continuous to the second part 32 may be used as an insulating film (LOCOS) that isolates the plurality of CMOS circuits.

As described later, in the present embodiment, the electrode 23 is formed of silicon in which an impurity is diffused, and is formed by doping the substrate 22 with the impurity. The electrode 23 may be a heavily impurity-doped N-type conductor, or may be a heavily impurity-doped P-type conductor. In FIG. 2 and FIG. 3, the reference symbol 24 indicates a region of the impurity diffusion region of the substrate 22, which is not used as the electrode 23.

The electrode 23 includes a first end portion 23a and a second end portion 23b that are positioned at both ends in the extension direction of the electrode 23 (the direction parallel to the Z direction). The first end portion 23a is at a position closer to the first surface 22a with respect to the second surface 22b. The second end portion 23b is at a position closer to the second surface 22b with respect to the first surface 22a. In the vicinity of the electrode 23, an interval between the first end portion 23a and the second end portion 23b in the extension direction of the electrode 23 is more than an interval between the first surface 22a and the second surface 22b in the extension direction of the electrode 23. Particularly in the present embodiment, the second end portion 23b and the second surface 22b are at the same position in the direction parallel to the Z direction. Therefore, the first end portion 23a is located ahead in the Z direction with respect to the first surface 22a.

In FIG. 2, the reference symbols 121 and 122 indicate a first layer and a second layer of the electrode portion 12 illustrated in FIG. 1, respectively. The first layer 121 contacts with the first end portion 23a of the electrode 23. The device 10 further includes an insulating layer 15 arranged on the third part 33 of the insulating film 30. The insulating layer 15 includes an opening portion from which the upper surface of the first layer 121 is exposed. The second layer 122 contacts with the upper surface of the first layer 121 via the opening portion of the insulating layer 15. Note that the first layer 121 may be formed of polysilicon, and the second layer 122 may be formed of a metal material. The first layer 121 formed of polysilicon is not a necessary constituent element, and may not be provided. In this case, the second layer 122 contacts with the first end portion 23a of the electrode 23.

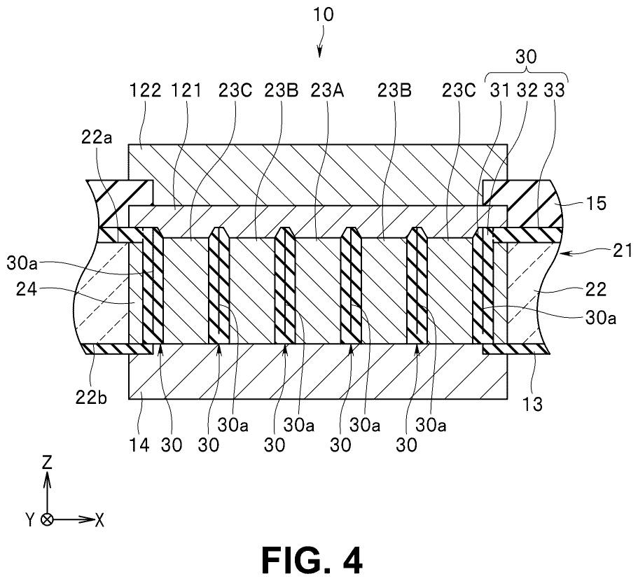

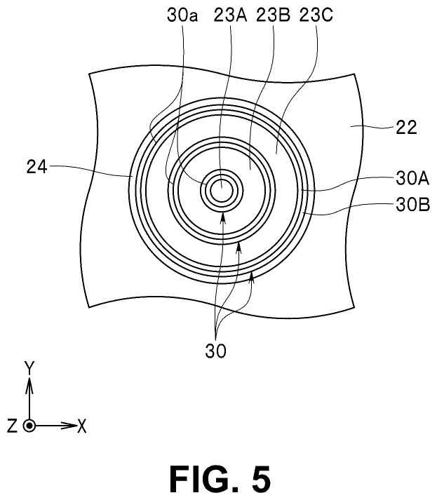

Next, with reference to FIG. 4 and FIG. 5, the plurality of electrodes 23 having a multilayered structure are described. FIG. 4 and FIG. 5 are cross-sectional views illustrating the plurality of electrodes 23 having a multilayered structure. FIG. 4 illustrates a cross-section vertical to the Y direction. FIG. 5 illustrates a cross-section vertical to the Z direction.

In the multilayer structure, the insulating film 30 is provided in the periphery of each of the plurality of electrodes 23. In the example illustrated in FIG. 4 and FIG. 5, the plurality of electrodes 23 includes a first electrode 23A positioned at the center, a second electrode 23B arranged to surround the first electrode 23A and a third electrode 23C arranged to surround the second electrode 23B. The first electrode 23A has a columnar shape. Each of the second electrode 23B and the third electrode 23C has a tubular shape. In the example illustrated in FIG. 4 and FIG. 5, the first electrode 23A has a cylindrical shape. Each of the second electrode 23B and the third electrode 23C has a hollow cylindrical shape.

Two parts of the insulating film 30 and the boundary surface 30a exist between the first electrode 23A and the second electrode 23B. With the first electrode 23A as a reference, a part of the two parts of the insulating film 30, which contacts with the first electrode 23A, corresponds to “the first part of the insulating film” in the disclosure, and the part that does not contact with the first electrode 23A corresponds to “the second part of the insulating film” in the disclosure. With the second electrode 23B as a reference, a part of the two parts of the insulating film 30, which contacts with the second electrode 23B, corresponds to “the first part of the insulating film” in the disclosure, and the part that does not contact with the second electrode 23B corresponds to “the second part of the insulating film” in the disclosure.

Similarly, two parts of the insulating film 30 and the boundary surface 30a exist between the second electrode 23B and the third electrode 23C. With the second electrode 23B as a reference, a part of the two parts of the insulating film 30, which contacts with the second electrode 23B, corresponds to “the first part of the insulating film” in the disclosure, and the part that does not contact with the second electrode 23B corresponds to “the second part of the insulating film” in the disclosure. With the third electrode 23C as a reference, a part of the two parts of the insulating film 30, which contacts with the third electrode 23C, corresponds to “the first part of the insulating film” in the disclosure, and the part that does not contact with the third electrode 23C corresponds to “the second part of the insulating film” in the disclosure.

The first part 31 of the insulating film 30 contacts with the outer periphery portion of the third electrode 23C, the second part 32 of the insulating film 30 contacts with the first part 31, and the third part 33 is continuous to the second part 32.

The first layer 121 of the electrode portion 12 contacts with the upper surface of each of the first electrode 23A to the third electrode 23C. The electrode pad 14 contacts with the lower surface of each of the first electrode 23A to the third electrode 23C.

Note that the multilayer structure is not limited to the example illustrated in FIG. 4 and FIG. 5. For example, the multilayer structure may be achieved by providing a plurality of electrodes 23 each having a monolithic structure (illustrated in FIG. 2 and FIG. 3). In this case, the first layer 121 of the electrode portion 12 contacts with the upper surface of each of the plurality of electrodes 23, and the electrode pad 14 contacts with the lower surface of each of the plurality of electrodes 23.

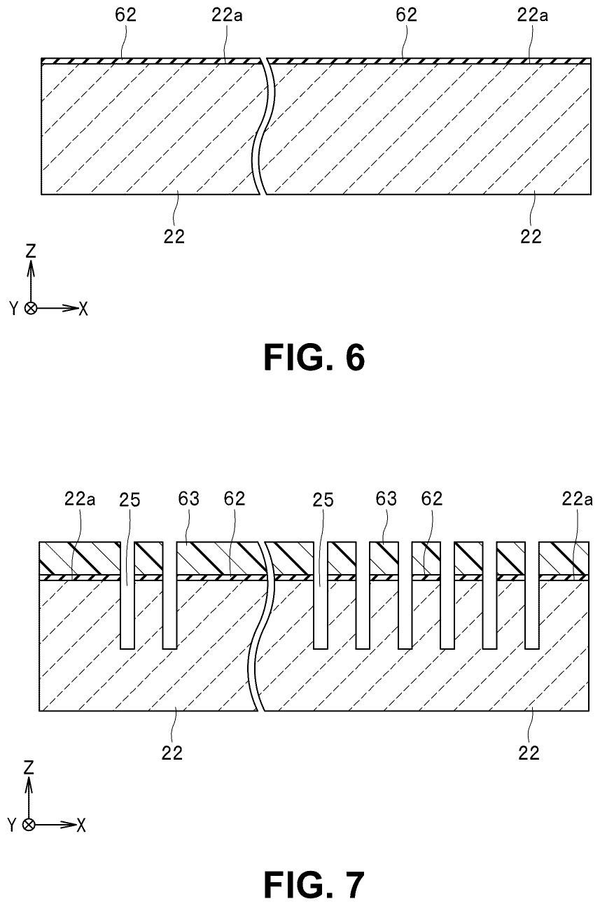

Next, with reference to FIG. 6 to FIG. 14, a manufacturing method of the through-hole electrode substrate 21 according to the present embodiment is described. FIG. 6 to FIG. 14 are cross-sectional views illustrating a stacked body in the manufacturing process of the through-hole electrode substrate 21. Herein, description is made on an example in which the device 10 illustrated in FIG. 1 is configured by using the through-hole electrode substrate 21. Herein, description is made on an example in which the electrode 23 having a monolithic structure, which is illustrated in FIG. 2 and FIG. 3, and the plurality of electrodes 23 having a multilayered structure, which are illustrated in FIG. 4 and FIG. 5. Note that, in the following description, it is assumed that the substrate 22 is a silicon substrate.

In the manufacturing method of the through-hole electrode substrate 21, first, as illustrated in FIG. 6, the insulating film 62 formed of, for example, Si₃N₄ is formed on the first surface 22a of the substrate 22. The thickness of the insulating film 62 falls within the range from 100 nm to 200 nm, for example. Note that a buffer film, which is omitted in illustration, may be formed before the insulating film 62 is formed. The buffer film may be an oxide film formed of SiO₂. The thickness of the buffer film falls within the range from 10 nm to 20 nm, for example.

FIG. 7 illustrates the following step. In this step, first, a photoresist mask 63 is formed on the insulating film 62. Subsequently, the insulating film 62 is selectively subjected to etching, for example, reactive ion etching (hereinafter, referred to as RIE) by using the photoresist mask 63. Subsequently, the insulating film 62 and the photoresist mask 63 are used as etching masks, and the substrate 22 is subjected to deep etching. In this manner, a plurality of trenches 25 are formed. The plurality of trenches 25 are formed from the first surface 22a of the substrate 22 to the inside of the substrate 22. For example, the Bosch process may be employed for deep etching of the substrate 22. The plurality of trenches 25 have a shape corresponding to the first part 31 and the second part 32 of the insulating film 30 that are formed later.

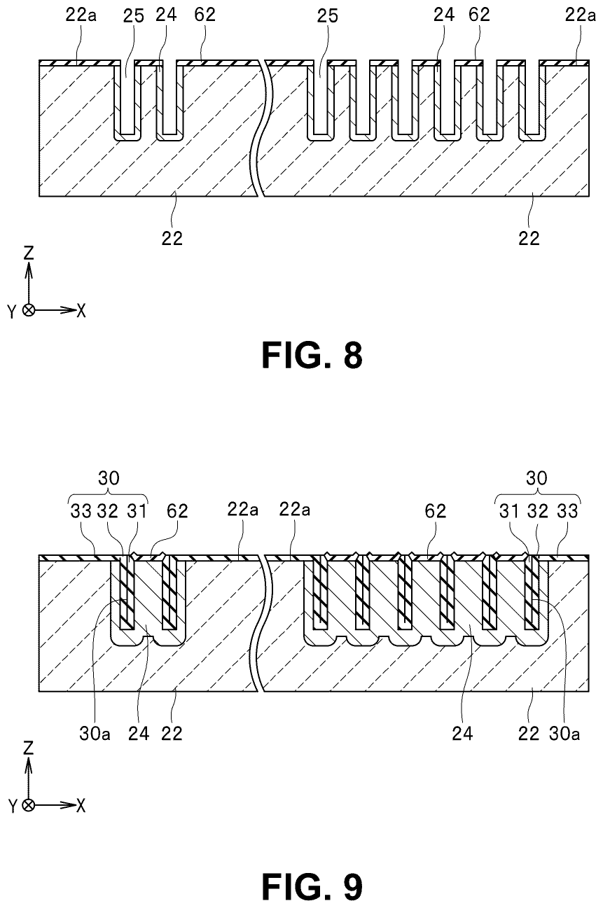

FIG. 8 illustrates the following step. In this step, first, the photoresist mask 63 is removed. Subsequently, an impurity is diffused from the wall surfaces and the bottom surfaces of the plurality of trenches 25 into the substrate 22. In this manner, the impurity diffusion region 24 that later serves as the plurality of electrodes 23 is formed on the substrate 22. Note that FIG. 8 illustrates the stacked body during the process of forming the impurity diffusion region 24.

FIG. 9 illustrates the following step. In this step, first, a part of the insulating film 62 other than the part located above a region where the plurality of electrodes 23 are to be subsequently formed is selectively removed. Subsequently, the insulating film 30 is formed on a part of the substrate 22, which is not covered with the insulating film 62. The insulating film 30 is formed so as to completely fill the plurality of trenches 25. The thickness of the insulating film 30 falls within the range from 500 nm to 1500 nm, for example. The insulating film 30 may be an SiO₂ film formed by the thermal oxidation method, for example. In this case, the substrate 22 is oxidized from the wall surface and the bottom surface of each of the plurality of trenches 25, and an SiO₂ film (the insulating film 30) is formed in the plurality of trenches 25. The oxidation temperature falls within the range from 1,000 degrees Celsius to 1,100 degrees Celsius, for example.

In each of the plurality of trenches 25, the insulating film 30 is formed from each of one wall of the trench 25 and the other wall facing the one wall surface. The boundary surface 30a is formed between the insulating film formed of one wall surface and the insulating film 30 formed of the other wall surface. The insulating film formed of one wall surface corresponds to “the first part of the insulating film” in the disclosure, and the insulating film formed of the other wall surface corresponds to “the second part of the insulating film” in the disclosure.

The third part 33 of the insulating film 30 is formed on the first surface 22a of the substrate 22. The insulating film 30 may include the third part 33 that is continuous to the second part 32 and the third part 33 that is not continuous to the second part 32. As described above, when a plurality of CMOS circuits are formed on the substrate 22, the third part 33 that is not continuous to the second part 32 may be used as an insulation film (LOCOS) that isolates the plurality of CMOS circuits. In this case, in the step illustrated in FIG. 9, the insulating film 30 that completely fills the plurality of trenches and the insulating film that separates the plurality of CMOS circuits may be formed simultaneously.

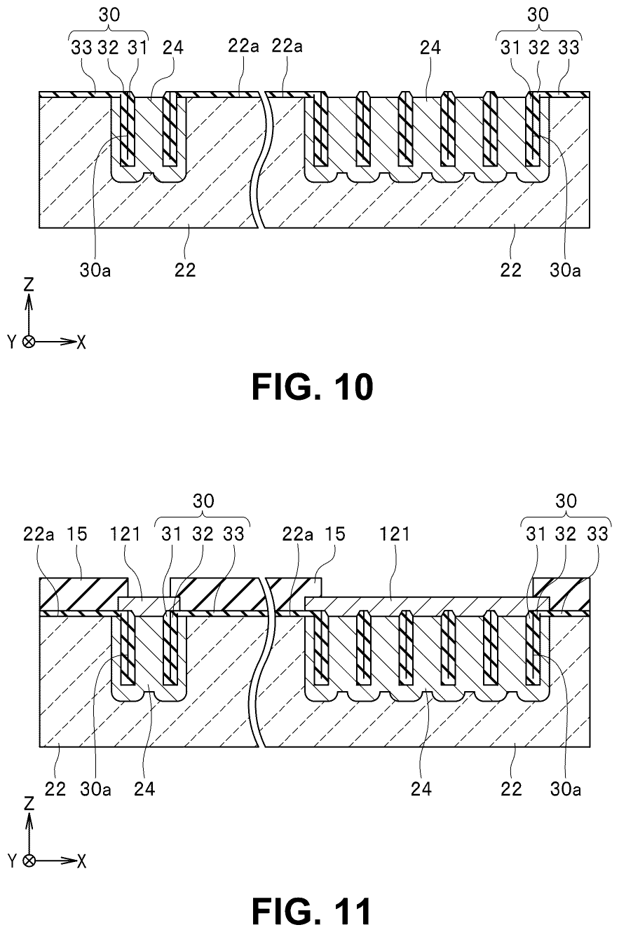

FIG. 10 illustrates the following step. In this step, the insulating film 62 is selectively removed so as to expose the impurity diffusion region 24. By selectively removing the insulating film 62, a contact hole for connecting the electrode portion 12 (see FIG. 1) to the impurity diffusion region 24 is formed in the stacked body.

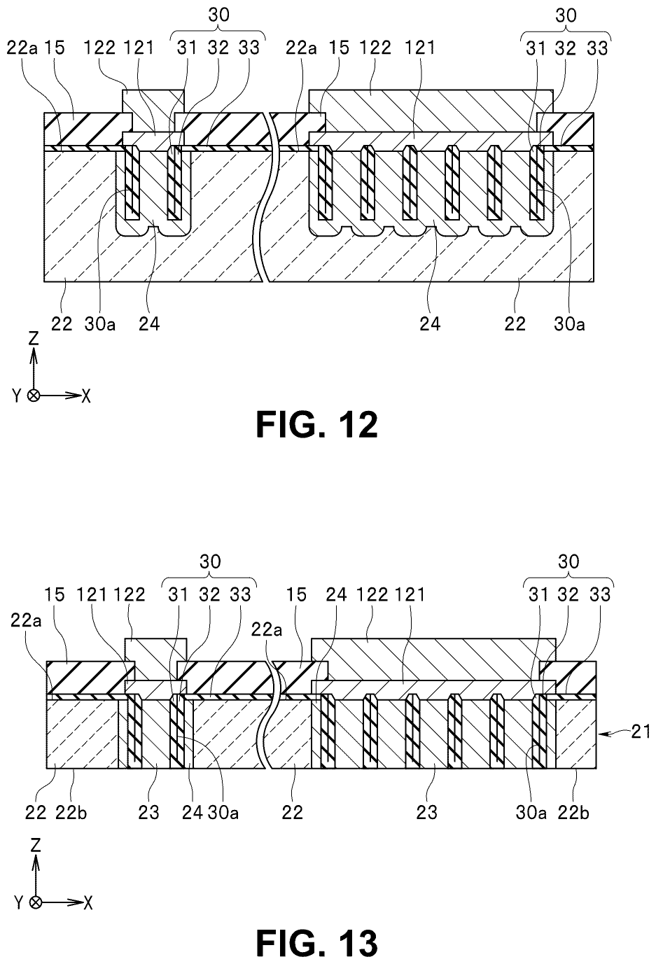

FIG. 11 illustrates the following step. In this step, first, the first layer 121 of the electrode portion 12 is formed on the impurity diffusion region 24. Subsequently, the insulating layer 15 including the opening portion from which the upper surface of the first layer 121 is exposed is formed on the insulating film 30. Subsequently, as illustrated in FIG. 12, the second layer 122 of the electrode portion 12 is formed on the first layer 121.

Although not illustrated, after the step illustrated in FIG. 11, a step of forming the circuit part 11 of the device 10 (see FIG. 1) is performed.

FIG. 13 illustrates the following step. In this step, the substrate 22 is polished so that the impurity diffusion region 24 serves as the plurality of electrodes 23. The substrate 22 is polished from a polishing surface on a side opposite to the first surface 22a of the substrate 22, and is polished until the insulating film 30 and the impurity diffusion region 24 that are formed in the plurality of trenches 25 are exposed. The polishing surface after polishing serves as the second surface 22b of the substrate 22. The part of the impurity diffusion region 24, which remains after polishing, partially serves as the plurality of electrodes 23. With this, the through-hole electrode substrate 21 is completed.

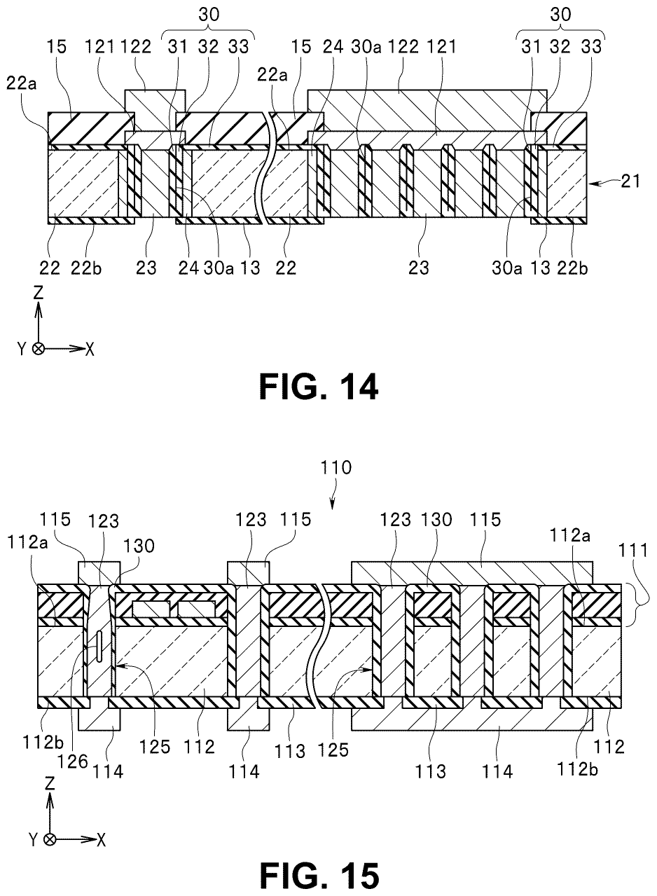

FIG. 14 illustrates the following step. In this step, the insulating film 13 including the plurality of opening portions from which the plurality of electrodes 23 are exposed is formed on the second surface 22b of the substrate 22. Then, the electrode pad 14 illustrated in FIG. 1 and the like are formed, and thus the device 10 is completed.

Next, the operation and effects of the through-hole electrode substrate 21 according to the present embodiment are described. According to the present embodiment, the device 10 is configured by using the through-hole electrode substrate 21, and thus the manufacturing cost of the device 10 can be reduced. The effect is described below in comparison with a device 110 in a comparative example.

First, with reference to FIG. 15, a configuration of the device 110 in the comparative example is described. FIG. 15 is a cross-sectional view illustrating the device 110 in the comparative example. The device 110 in the comparative example includes the circuit part 111 and a substrate 112. The substrate 112 includes a first surface 112a and a second surface 112b on a side opposite to the first surface 112a. The circuit part 111 is formed on the substrate 112 and the first surface 112a of the substrate 112. Note that FIG. 15 illustrates the circuit part 111 in a simplified manner as compared to the circuit part 11 illustrated in FIG. 1.

The device 110 further includes a plurality of through holes 125 that respectively pass through the circuit part 111 and the substrate 112, a plurality of electrodes 123 that are formed respectively in the plurality of through holes 125, and an insulating film 130 that provides insulation between the plurality of electrodes 123, and the circuit part 111 and the substrate 112. Particularly in the comparative example, each of the plurality of electrodes 123 extends from the upper surface of the device 110 to the lower surface of the device 110.

The device 110 further includes an insulating film 113 that covers the second surface 112b of the substrate 112. The insulating film 113 includes a plurality of opening portions from which the plurality of electrodes 123 are exposed, respectively. The device 110 further includes a plurality of electrode pads 114 that are respectively connected to the lower surfaces of the plurality of electrodes 123 via the plurality of opening portions and a plurality of electrode pads 115 that are respectively connected to the upper surfaces of the plurality of electrodes 123.

Next, a manufacturing method of the device 110 in the comparative example is described in a simplified manner. First, the circuit part 111 is formed on the substrate 112 and the first surface 112a of the substrate 112. Subsequently, the circuit part 111 and the substrate 112 are subjected to deep etching to form a plurality of trenches. For example, the Bosch process may be employed for deep etching of the circuit part 111 and the substrate 112. The plurality of trenches have a shape corresponding to the plurality of electrodes 123 that are formed later.

Subsequently, the insulating film 130 is formed so as to cover the upper surface of the circuit part 111, and the wall surface and the bottom surface of each of the plurality of trenches. Subsequently, an electrode material layer that later serves as the plurality of electrodes 123 is formed so as to fill the plurality of trenches.

Subsequently, a part of the electrode material layer other than the part formed in the plurality of trenches is removed. Subsequently, the plurality of electrode pads 115 are formed on the upper surface of the electrode material layer.

Subsequently, the substrate 112 is polished until the electrode material layer formed in the plurality of trenches is exposed. The substrate 112 is polished from a polishing surface on a side opposite to the first surface 112a of the substrate 112. The polishing surface after polishing serves as the second surface 112b of the substrate 112, and the plurality of trenches after polishing serve as the plurality of through holes 125. The part of the electrode material layer, which remains after polishing, serves as the plurality of electrodes 123.

Subsequently, the insulating film 113 including the plurality of opening portions from which the plurality of electrodes 123 are exposed is formed on the second surface 112b of the substrate 112. Subsequently, the plurality of electrode pads 114 are formed. With this, the device 110 is completed.

The problem in the manufacturing method of the device 110 in the comparative example is described below. In the comparative example, it is required to form the insulating film 130 in the plurality of trenches so that a space for forming the plurality of electrodes 123 is left. Thus, the insulating film 130 in the plurality of trenches requires satisfactory step coverage. Thus, the insulating film 130 is formed by the atomic layer deposition (ALD) method, for example. However, the atomic layer deposition method requires a long time period for forming the insulating film 130 having a predetermined thickness. Therefore, the manufacturing cost is increased.

When the thickness of the insulating film 130 is increased, or the opening portion of the trench is reduced, a key hole may be generated in the electrode material layer formed in the trench. In FIG. 15, the reference symbol 126 indicates a key hole. When the key hole 126 described above is generated, the resistance of the electrode 123 is increased. In contrast, when the insulating film 130 is reduced in thickness, the parasitic capacitance of the electrode 123 is increased.

The circuit part 111 includes the plurality of insulating films that are formed by different materials and formed by different methods. Thus, when the circuit part 111 and the substrate 112 are subjected to deep etching, it is necessary to use a plurality of etching gases in order to simultaneously etch the plurality of insulating films and the silicon substrate. Consequently, the manufacturing cost is increased.

In contrast, in the present embodiment, there is no need to form the insulating film 30 so that a space for forming the plurality of electrodes 23. Thus, the insulating film 30 can be formed by the method with lower manufacturing cost as compared to the atomic layer deposition method. In the present embodiment, the insulating film 30 and the impurity diffusion region 24 that serves as the plurality of electrodes 23 are formed before the circuit part 11 is formed. Thus, in the present embodiment, the through-hole electrode substrate 21 can be formed without subjecting the circuit part 11 to deep etching. In the present embodiment, the impurity diffusion region 24 and the insulating film 30 can be formed while performing the step of forming the circuit part 11. From the above, according to the present embodiment, the manufacturing cost of the device 10 can be reduced.

In the present embodiment, there is no need to form the insulating film 30 so that a space for generating the plurality of electrodes 23 is left. Thus, the thickness of the insulating film 30 can be increased, and there is no risk of generating a key hole in the plurality of electrodes 23. With this, according to the present embodiment, the through-hole electrode substrate 21 and the device 10 that are highly reliable can be achieved.

### Second Embodiment

Next, a manufacturing method of the through-hole electrode substrate 21 according to a second embodiment of the disclosure is described. The manufacturing method of the through-hole electrode substrate 21 according to the present embodiment is different from the first embodiment in the timing of forming the plurality of trenches 25.

With reference to FIG. 16 to FIG. 20, the manufacturing method of the through-hole electrode substrate 21 according to the present embodiment is described below. FIG. 16 to FIG. 20 are cross-sectional views illustrating a stacked body in the manufacturing process of the through-hole electrode substrate 21. Note that, among the constituent elements of through-hole electrode substrate 21 according to the present embodiment, the same constituent elements as those of the through-hole electrode substrate 21 according to the first embodiment are denoted with the same reference symbols as those in the first embodiment.

In the manufacturing method of the through-hole electrode substrate 21, first, as illustrated in FIG. 16, an impurity is diffused from the first surface 22a of the substrate 22 into the substrate 22, and thus the impurity diffusion region 24 is formed on the substrate 22. Note that, when a plurality of CMOS circuits are formed on the substrate 22, the impurity diffusion region 24 may be formed simultaneously with an impurity diffusion region used for the plurality of CMOS circuits.

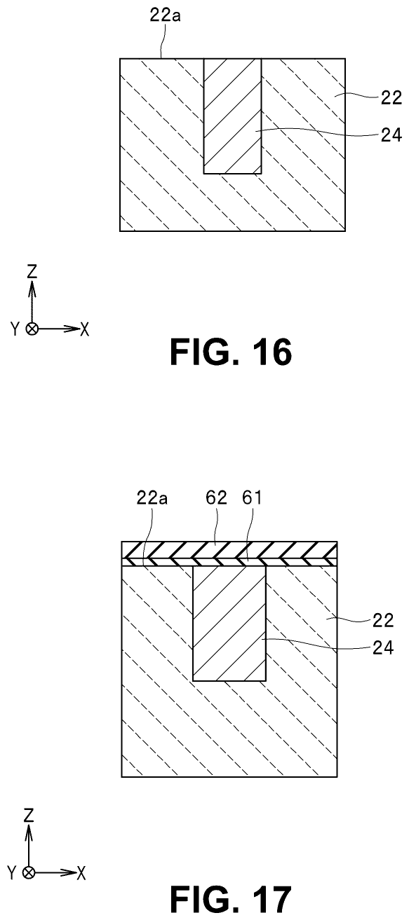

FIG. 17 illustrates the following step. In this step, a buffer film 61 is formed on the first surface 22a of the substrate 22. The buffer film 61 may be an oxide film formed of SiO₂. The thickness of the buffer film 61 falls within the range from 10 nm to 20 nm, for example. Subsequently, the insulating film 62 is formed on the buffer film 61.

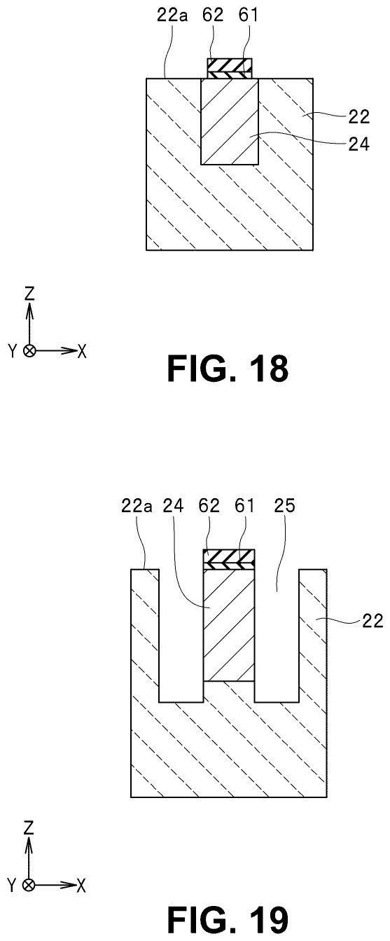

FIG. 18 illustrates the following step. In this step, the buffer film 61 and the insulating film 62 are selectively subjected to etching, for example, RIE by using a photoresist mask, which is omitted in illustration, as an etching mask so that the buffer film 61 and the insulating film 62 are left on the impurity diffusion region 24.

FIG. 19 illustrates the following step. In this step, first, the buffer film 61, the insulating film 62, and the photoresist mask, which is omitted in illustration, are used as etching masks, and the substrate 22 is subjected to deep etching. In this manner, the plurality of trenches 25 are formed. The plurality of trenches 25 are formed in the periphery of the impurity diffusion region 24. Subsequently, the photoresist mask, which is omitted in illustration, is removed.

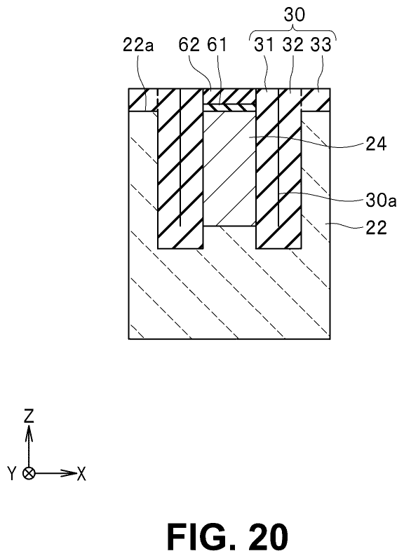

FIG. 20 illustrates the following step. In this step, the insulating film 30 is formed on a part of the substrate 22, which is not covered with the insulating film 62. The insulating film 30 is formed so as to completely fill the plurality of trenches 25. The subsequent steps are similar to those in the first embodiment.

The configuration, operation and effects of the present embodiment are otherwise the same as those of the first embodiment.

### Third Embodiment

Next, a third embodiment of the disclosure is described. The through-hole electrode substrate 21 according to the present embodiment includes a plurality of electrodes 27 in place of the plurality of electrodes 23 in the first embodiment. The plurality of electrodes 27 are formed of a metal material. In the present embodiment, the impurity diffusion region 24 in the first embodiment is not provided. The other configurations of the through-hole electrode substrate 21 according to the present embodiment are similar to those in the first embodiment.

Next, the electrode 27 is described in detail. Similarly to the first embodiment, the plurality of electrodes 27 can be categorized into the electrode 27 having a monolithic structure and the electrode 27 having a multilayered structure.

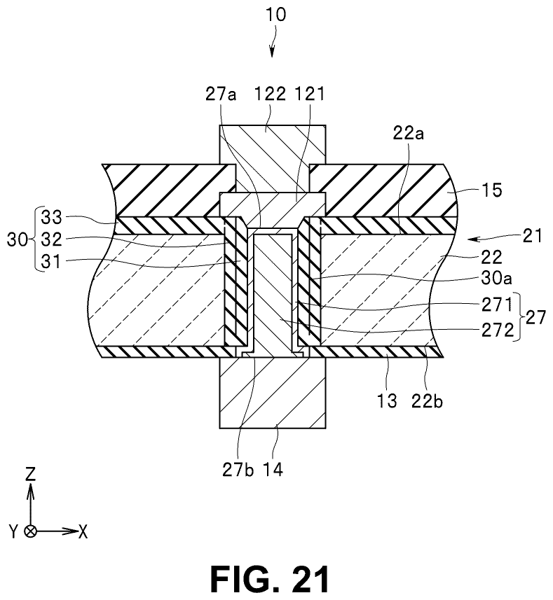

First, with reference to FIG. 21, the electrode 27 having a monolithic structure is described. FIG. 21 is a cross-sectional view illustrating the electrode 27 having a monolithic structure. The electrode 27 includes a first layer 271 and a second layer 272. In the monolithic structure, the second layer 272 extends from the first surface 22a of the substrate 22 to the second surface 22b of the substrate 22. The first layer 271 is interposed between the second layer 272 and the first part 31 of the insulating film 30 and between the second layer 272 and the first layer 121 of the electrode portion 12. The lower surface of the second layer 272 contacts with the electrode pad 14. The material of the first layer 271 and the second layer 272 is described later.

The electrode 27 includes a first end portion 27a and a second end portion 27b that are positioned at both ends in the extension direction of the electrode 27 (the direction parallel to the Z direction). The first end portion 27a is at a position closer to the first surface 22a with respect to the second surface 22b. The second end portion 27b is at a position closer to the second surface 22b with respect to the first surface 22a. In the vicinity of the electrode 27, an interval between the first end portion 27a and the second end portion 27b in the extension direction of the electrode 27 is more than an interval between the first surface 22a and the second surface 22b in the extension direction of the electrode 27. Particularly in the present embodiment, the second end portion 27b and the second surface 22b are at the same position in the direction parallel to the Z direction. Therefore, the first end portion 27a is located ahead in the Z direction with respect to the first surface 22a.

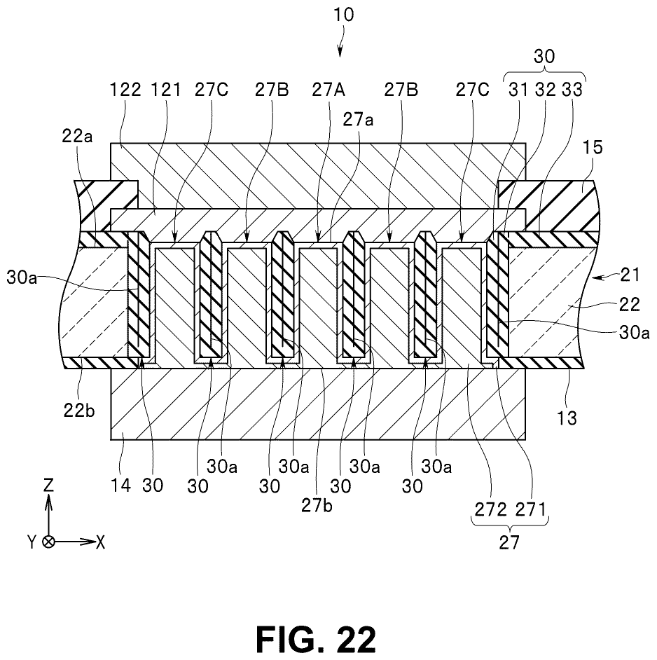

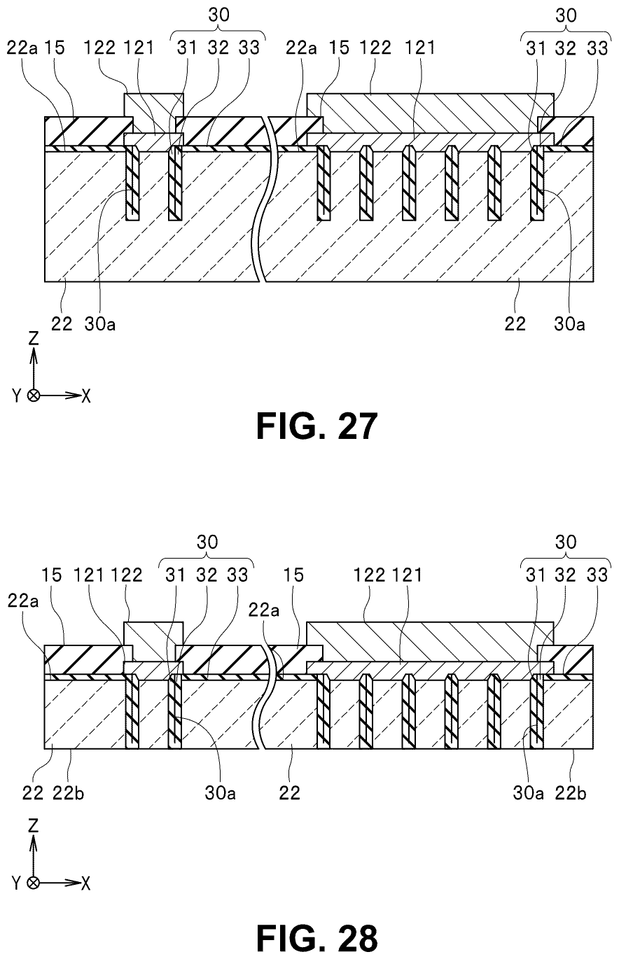

Next, with reference to FIG. 22, the electrode 27 having a multilayered structure is described. FIG. 27 is a cross-sectional view illustrating the electrode 27 having a multilayered structure. In the multilayered structure, the electrode 27 includes a plurality of electrode portions. In the example illustrated in FIG. 22, the electrode 27 includes a first electrode portion 27A positioned at the center, a second electrode portion 27B arranged to surround the first electrode portion 27A, and a third electrode portion 27C arranged to surround the second electrode portion 27B. The first electrode portion 27A has a columnar shape. Each of the second electrode portion 27B and the third electrode portion 27C has a tubular shape.

Two parts of the insulating film 30 and the boundary surface 30a exist between the first electrode portion 27A and the second electrode portion 27B. The relationship between the first electrode portion 27A and the second electrode portion 27B, and the two parts of the insulating film 30 is similar to the relationship between the first electrode 23A and the second electrode 23B, and the two parts of the insulating film 30 in the first embodiment.

Similarly, two parts of the insulating film 30 and the boundary surface 30a exist between the second electrode portion 27B and the third electrode portion 27C. The relationship between the second electrode portion 27B and the third electrode portion 27C, and the two parts of the insulating film 30 is similar to the relationship between the second electrode 23B and the third electrode 23C, and the two parts of the insulating film 30 in the first embodiment.

The first part 31 of the insulating film 30 contacts with the outer periphery portion of the third electrode portion 27C, the second part 32 of the insulating film 30 contacts with the first part 31, and the third part 33 is continuous to the second part 32.

Similarly to the electrode 27 having a monolithic structure, the electrode 27 having a multilayered structure includes the first layer 271 and the second layer 272, and also includes the first end portion 27a and the second end portion 27b. Each of the first electrode portion 27A to the third electrode portion 27C is configured by a part of the first layer 271 and a part of the second layer 272. In the vicinity of the second end portion 27b, the first electrode portion 27A to the third electrode portion 27C may be connected to another part of the second layer 272.

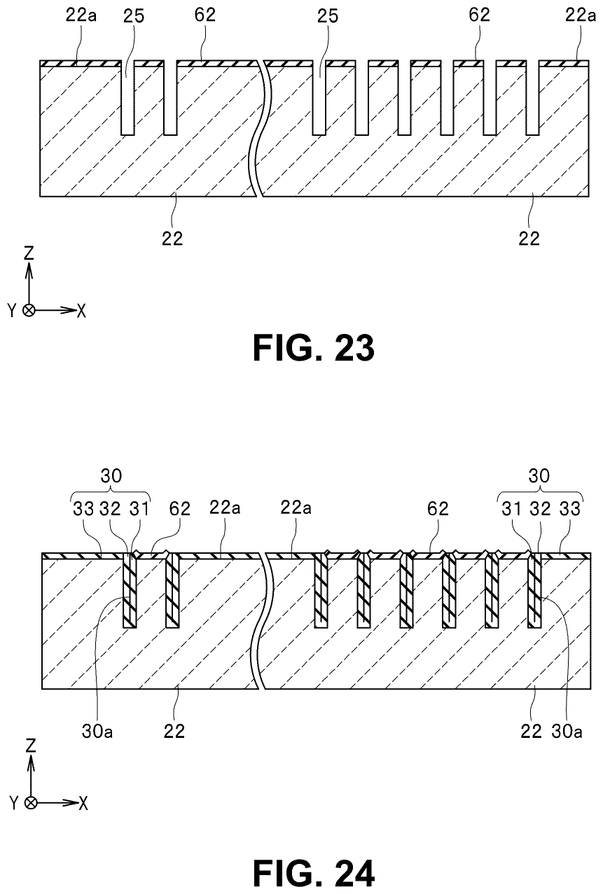

Next, with reference to FIG. 23 to FIG. 30, the manufacturing method of the through-hole electrode substrate 21 according to the present embodiment is described. FIG. 23 to FIG. 30 are cross-sectional views illustrating a stacked body in the manufacturing process of the through-hole electrode substrate 21. Herein, similarly to the first embodiment, description is made on an example in which the device 10 illustrated in FIG. 1 is configured by using the through-hole electrode substrate 21. Herein, description is made on an example in which the electrode 27 having a monolithic structure illustrated in FIG. 21 and the electrode 27 having a multilayered structure illustrated in FIG. 22 are formed.

The manufacturing method of the through-hole electrode substrate 21 in the present embodiment is similar to the first embodiment up to the step of forming the plurality of trenches 25. FIG. 23 illustrates the stacked body after the plurality of trenches 25 are formed.

FIG. 24 illustrates the following step. In this step, first, a part of the insulating film 62 other than the part located above a region where the plurality of electrodes 27 are to be subsequently formed is selectively removed. Subsequently, the insulating film 30 is formed on a part of the substrate 22, which is not covered with the insulating film 62. The insulating film 30 is formed so as to completely fill the plurality of trenches 25. The formation method of the insulating film 30 is similar to that in the first embodiment.

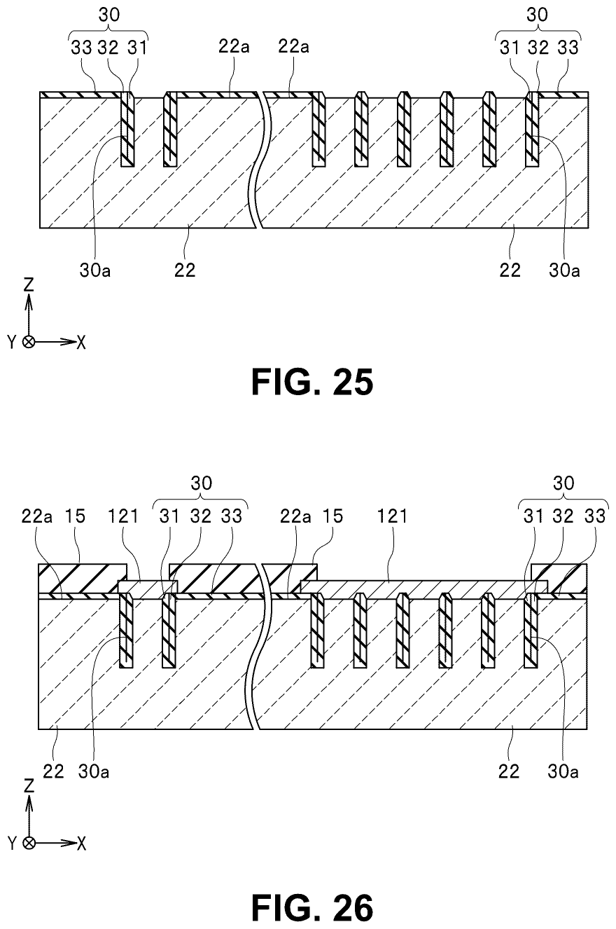

FIG. 25 illustrates the following step. In this step, the insulating film 62 is selectively removed so that the region where the plurality of electrodes 27 are to be subsequently formed is exposed from the insulating film 30.

FIG. 26 illustrates the following step. In this step, the first layer 121 of the electrode portion 12 is formed on first, the substrate 22. Subsequently, the insulating layer 15 including the opening portion from which the upper surface of the first layer 121 is exposed is formed on the insulating film 30. Subsequently, as illustrated in FIG. 27, the second layer 122 of the electrode portion 12 is formed on the first layer 121.

Although not illustrated, after the step illustrated in FIG. 27, a step of forming the circuit part 11 of the device 10 (see FIG. 1) is performed.

FIG. 28 illustrates the following step. In this step, the substrate 22 is polished until the insulating film 30 formed in the plurality of trenches 25 is exposed. The substrate 22 is polished from a polishing surface on a side opposite to the first surface 22a of the substrate 22. The polishing surface after polishing serves as the second surface 22b of the substrate 22.

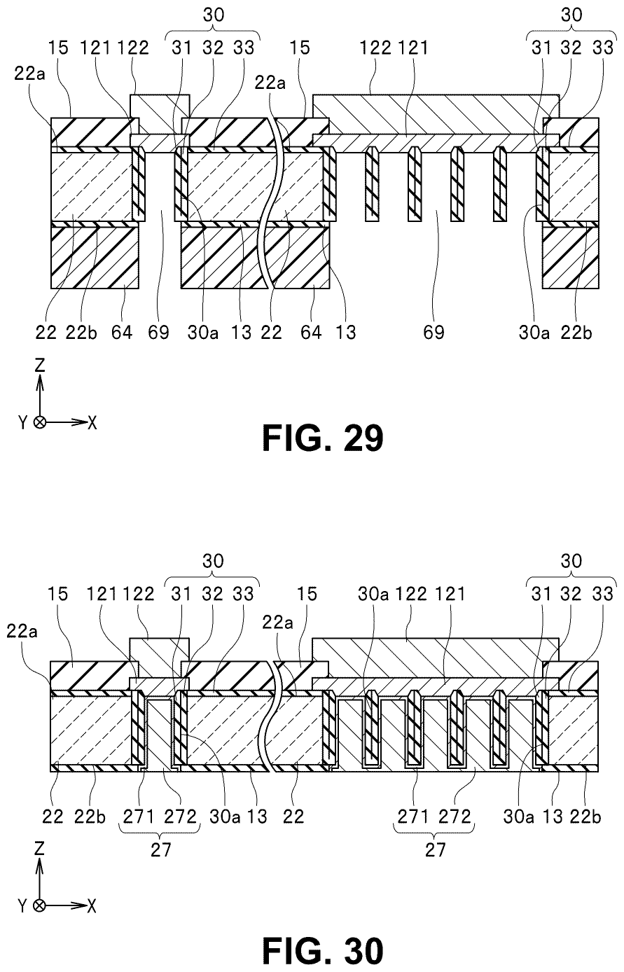

FIG. 29 illustrates the following step. In this step, first, the insulating film 13 is formed on the second surface 22b of the substrate 22. Subsequently, a photoresist mask 64 is formed on the insulating film 13. Subsequently, the photoresist mask 64 is used as an etching mask, and the insulating film 13 and the substrate 22 are subjected to etching, for example, RIE. The etching continues until a plurality of through holes 69 are formed in the substrate 22 to expose the first layer 121 of the electrode portion 12. During the etching, the insulating film 30 functions as an etching stopper. Thus, the substrate 22 can be subjected to etching without employing deep etching such as the Bosch process.

FIG. 30 illustrates the following step. In this step, first, the photoresist mask 64 is removed. Subsequently, a step of forming the plurality of electrodes 27 in the plurality of through holes 69 is performed. In this step, first, the first layer 271 is formed in the plurality of through holes 69. The first layer 271 is also formed on the insulating film 13. The first layer 271 is formed by the electroless plating method, for example. Examples of the material of the first layer 271 include Ni, Cu, Au, and the like. Subsequently, the second layer 272 is formed on the first layer 271. The second layer 272 is formed by the electroplating method, for example. The first layer 271 is used as an electrode and a seed layer at the time of forming the second layer 272 by the electroplating method. Examples of the material of the second layer 272 include Ni, NiFe, Fe, W, Ta, Cu, and the like. Subsequently, the first layer 271 and the second layer 272 are polished until the insulating film 13 is exposed. With this, the plurality of electrodes 27 are completed. Then, the electrode pad 14 and the like are formed, and thus the device 10 is completed.

The configuration, operation and effects of the present embodiment are otherwise the same as those of the first embodiment.

### Fourth Embodiment

Next, a fourth embodiment of the disclosure is described. The through-hole electrode substrate 21 according to the present embodiment includes the plurality of electrodes 27 in the third embodiment in place of the plurality of electrodes 23 in the first embodiment. In the present embodiment, the impurity diffusion region 24 in the first embodiment is present, which is different from the third embodiment. The other configurations of the through-hole electrode substrate 21 according to the present embodiment are similar to those in the first embodiment and the third embodiment.

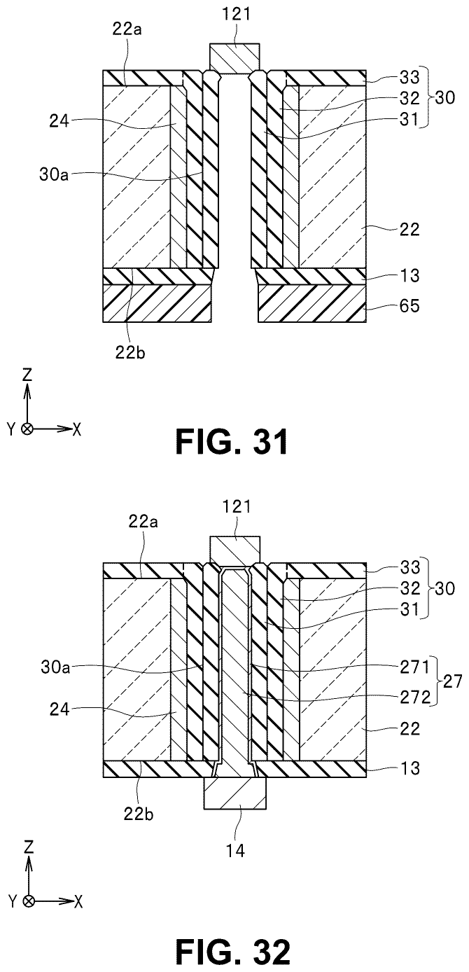

With reference to FIG. 31 and FIG. 32, the manufacturing method of the through-hole electrode substrate 21 according to the present embodiment is described below. FIG. 31 and FIG. 32 are cross-sectional views illustrating a stacked body in the manufacturing process of the through-hole electrode substrate 21. Herein, similarly to the first embodiment, description is made on an example in which the device 10 illustrated in FIG. 1 is configured by using the through-hole electrode substrate 21.

The manufacturing method of the through-hole electrode substrate 21 according to the present embodiment is similar to the first embodiment up to the step of polishing the substrate 22. FIG. 31 illustrates the following step. In this step, first, the insulating film 13 is formed on the second surface 22b of the substrate 22. Subsequently, a photoresist mask 65 is formed on the insulating film 13. Subsequently, the photoresist mask 65 is used as an etching mask, and the insulating film 13 and the impurity diffusion region 24 are subjected to etching, for example, RIE. The etching continues until the first layer 121 of the electrode portion 12 is exposed.

FIG. 32 illustrates the following step. In this step, first, the photoresist mask 65 is removed. Subsequently, the first layer 271 and the second layer 272 are subsequently formed. The formation method of the first layer 271 and the second layer 272 is similar to that in the third embodiment. Subsequently, the first layer 271 and the second layer 272 are polished until the insulating film 13 is exposed. With this, the plurality of electrodes 27 are completed. Then, the electrode pad 14 and the like are formed, and thus the device 10 is completed.

The configuration, operation and effects of the present embodiment are otherwise the same as those of the first embodiment or the third embodiment.

### Fifth Embodiment

Next, a fifth embodiment of the disclosure is described. The manufacturing method of the through-hole electrode substrate 21 according to the present embodiment are different from the third embodiment in the following points. In the present embodiment, the insulating film 30 is formed so as not to completely fill the plurality of trenches 25. Thus, in the present embodiment, the boundary surface 30a is not formed on the insulating film 30.

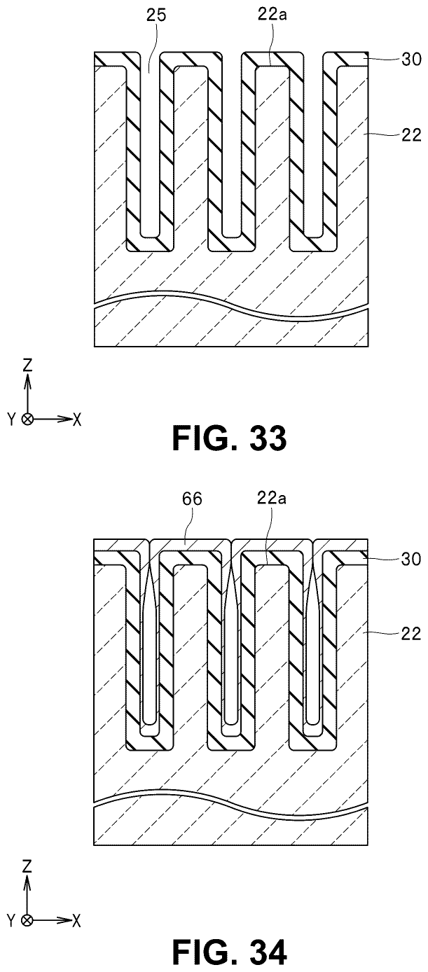

With reference to FIG. 33 to FIG. 37, the manufacturing method of the through-hole electrode substrate 21 according to the present embodiment is described below. FIG. 33 to FIG. 37 are cross-sectional views illustrating a stacked body in the manufacturing process of the through-hole electrode substrate 21. Herein, similarly to the first embodiment, description is made on an example in which the device 10 illustrated in FIG. 1 is configured by using the through-hole electrode substrate 21. Note that, for the sake of convenience, the plurality of constituent elements are omitted in illustration in FIG. 33 to FIG. 37.

The manufacturing method of the through-hole electrode substrate 21 according to the present embodiment is similar to the third embodiment up to the step of forming the plurality of trenches 25. FIG. 33 illustrates the following step. In this step, the insulating film 30 is formed. The insulating film 30 is formed so as not to fill the plurality of trenches 25.

FIG. 34 illustrates the following step. In this step, a silicon film 66 formed of polysilicon or amorphous silicon is formed on the front surface of the insulating film 30. The silicon film 66 is formed to seal the opening portions of the plurality of trenches 25. Note that the silicon film 66 may be formed so as not to completely fill the plurality of trenches 25.

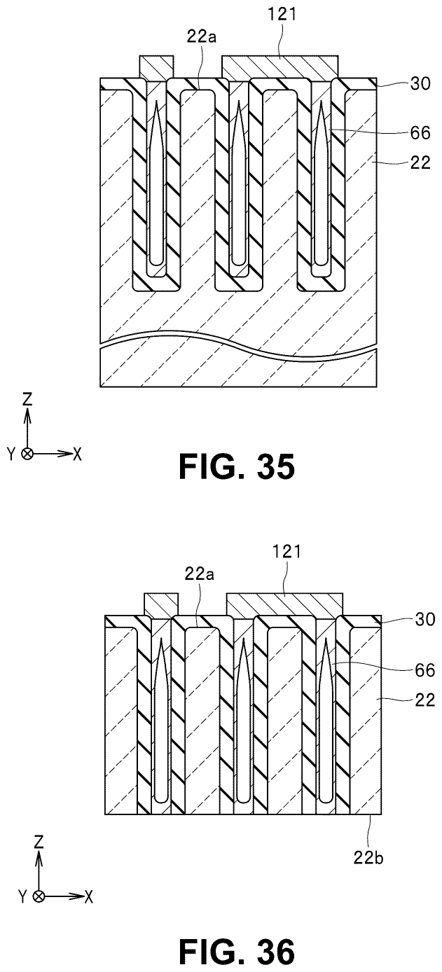

FIG. 35 illustrates the following step. In this step, first, the silicon film 66 is polished until the insulating film 30 is exposed. Subsequently, the first layer 121 of the electrode portion 12 is formed on the silicon film 66.

FIG. 36 illustrates the following step. In this step, the substrate 22 is polished until the silicon film 66 formed in the plurality of trenches 25 is exposed. The substrate 22 is polished from a polishing surface on a side opposite to the first surface 22a of the substrate 22. The polishing surface after polishing serves as the second surface 22b of the substrate 22.

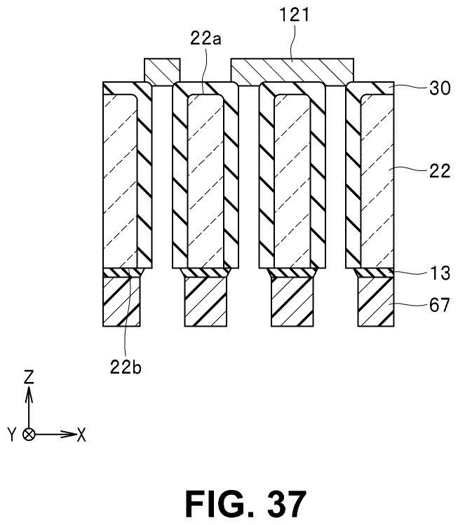

FIG. 37 illustrates the following step. In this step, first, the insulating film 13 is formed on the second surface 22b of the substrate 22. Subsequently, a photoresist mask 67 is formed on the insulating film 13. Subsequently, the photoresist mask 67 is used as an etching mask, and the insulating film 13 and the silicon film 66 are subjected to etching, for example, RIE. The etching continues until the first layer 121 of the electrode portion 12 is exposed. Subsequently, the photoresist mask 67 is removed. The subsequent steps are similar to those in the third embodiment.

In the present embodiment, the boundary surface 30a is not formed on the insulating film 30. In other words, in the present embodiment, in the manufacturing process of the through-hole electrode substrate 21, a part of the insulating film growing from one wall surface of the trench 25 and another part of the insulating film 30 growing from the other wall surface do not push each other. With this, according to the present embodiment, the generation of unnecessary stress in the substrate 22 can be suppressed. As a result, according to the present embodiment, the occurrence of defects in the substrate 22 caused by stress can be suppressed.

The configuration, operation and effects of the present embodiment are otherwise the same as those of the third embodiment.

### Sixth Embodiment

Next, a MEMS device according to a sixth embodiment of the disclosure is described. The MEMS device 100 according to the present embodiment is configured by using the through-hole electrode substrate 21 of the first embodiment or the second embodiment.

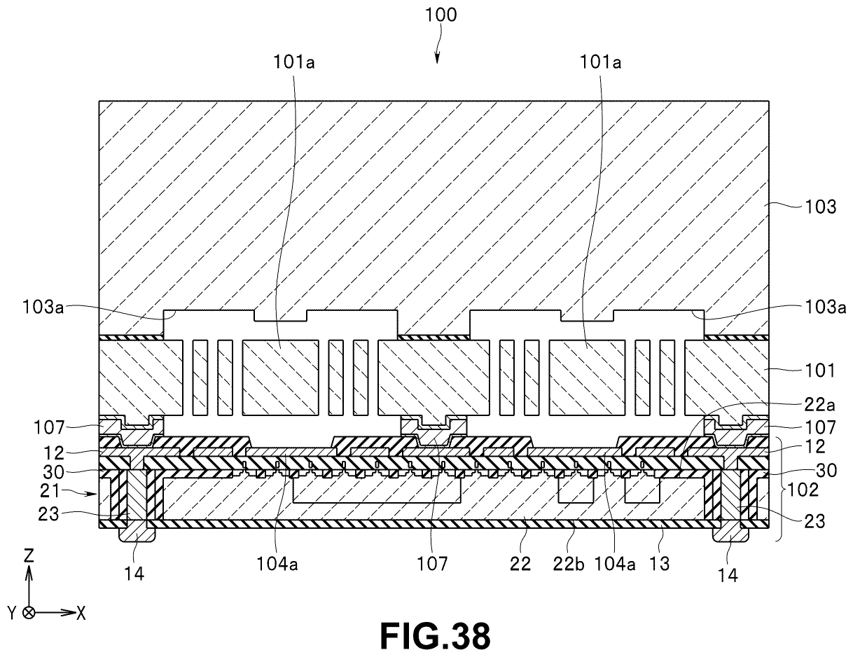

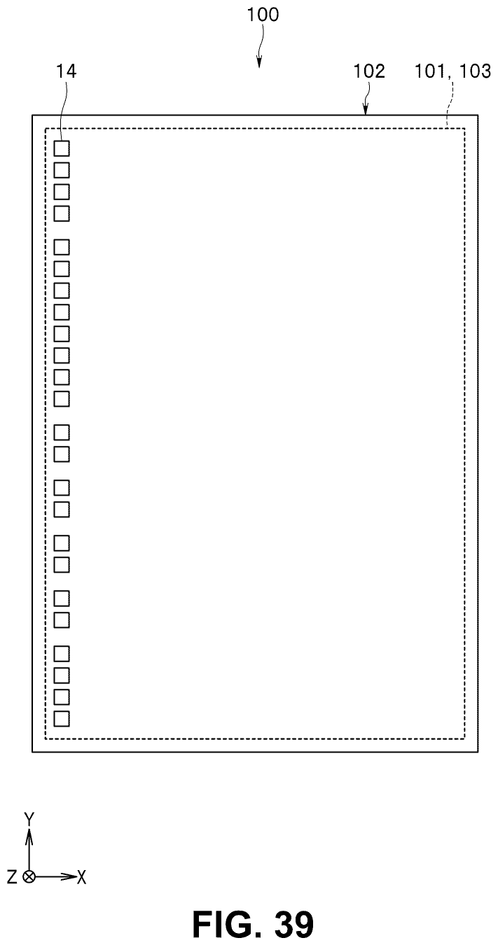

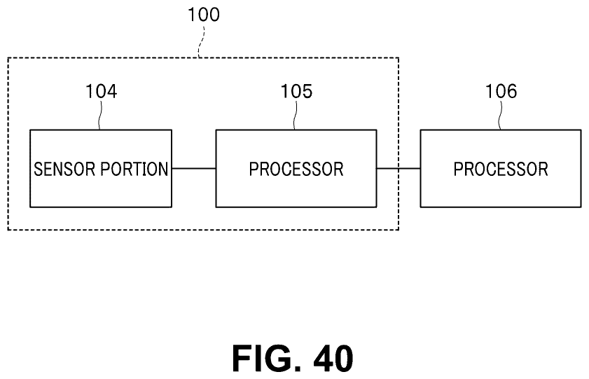

The MEMS device 100 may be a microphone, a pressure sensor, or a motion sensor. A configuration of the MEMS device 100 is described below while giving an example in which the MEMS device 100 is a capacitive-type motion sensor. FIG. 38 is a cross-sectional view illustrating the MEMS device 100. FIG. 38 illustrates an example in which the MEMS device 100 is configured by using the through-hole electrode substrate 21 according to the first embodiment. FIG. 39 is a plan view illustrating the MEMS device 100. FIG. 40 is a block diagram illustrating a configuration of the MEMS device 100.

The MEMS device 100 includes a movable unit 101, and a circuit unit 102 and a cap 103 that are arranged to sandwich the movable unit 101. The movable unit 101 includes a movable element 101a as a weight, a structure of fixing the movable element 101a, and an electrode provided on the lower surface of the movable element 101a. Hereinafter, the electrode provided to the movable element 101a is referred to as the movable electrode. Note that the movable electrode is omitted in FIG. 38. A part of the movable unit 101 other than the movable electrode is formed of a silicon substrate, polysilicon, epitaxial polysilicon, or the like.

The circuit unit 102 is configured by using the through-hole electrode substrate 21, corresponds to the device 10 in the first embodiment. In the following description, the constituent elements of the circuit unit 102 that are commonly shared as the constituent elements of the device 10 are denoted with the same reference symbols as the constituent elements of the device 10.

The movable unit 101 is arranged on the first surface 22a of the substrate 22 of the through-hole electrode substrate 21. The MEMS device 100 further includes a plurality of electrode portions 107 that connect the movable unit 101 and the circuit unit 102 to each other.

The circuit unit 102 includes a stationary electrode 104a that is formed on the first surface 22a of the substrate 22 of the through-hole electrode substrate 21 and a processor 105 serving as a signal processing circuit that is formed on the substrate 22 of the through-hole electrode substrate 21 and the first surface 22a of the substrate 22.

The movable electrode and the stationary electrode 104a form a sensor unit 104. When the position of the movable element 101a is changed, the distance between the movable electrode and the stationary electrode 104a is changed. As a result, the static capacitance between the movable electrode and the stationary electrode 104a is changed. The processor 105 is configured to detect the change in static capacitance and generate a detection value corresponding to the static capacitance. The detection value may be a value of the static capacitance, acceleration, or angular velocity. The processor 105 is configured to output the generated detection value to an external processor 106.

The cap 103 seals the internal structure of the MEMS device 100, such as the movable element 101a and the stationary electrode 104a. The cap 103 includes a cavity 103a having a predetermined shape. The movable element 101a is positioned within a space that includes the cavity 103a and is surrounded by the circuit unit 102 and the cap 103. The movable element 101a is configured to be movable in the space including the cavity 103a. The cap 103 is formed of a silicon substrate, for example.

FIG. 39 illustrates the MEMS device 100 as viewed from the second surface 22b of the substrate 22. Note that FIG. 39 illustrates some of the plurality of electrode pads 14. The planar shape of the cap 103 (the shape as viewed in the Z direction) is the same or substantially the same as the planar shape of the movable unit 101. The planar shape of the circuit unit 102 may be the same as the planar shapes of the movable unit 101 and the cap 103, or may be slightly larger than the planar shapes of the movable unit 101 and the cap 103. As viewed in the Z direction, the plurality of electrode pads 14 are arranged at the positions overlapping with the movable unit 101 and the cap 103.

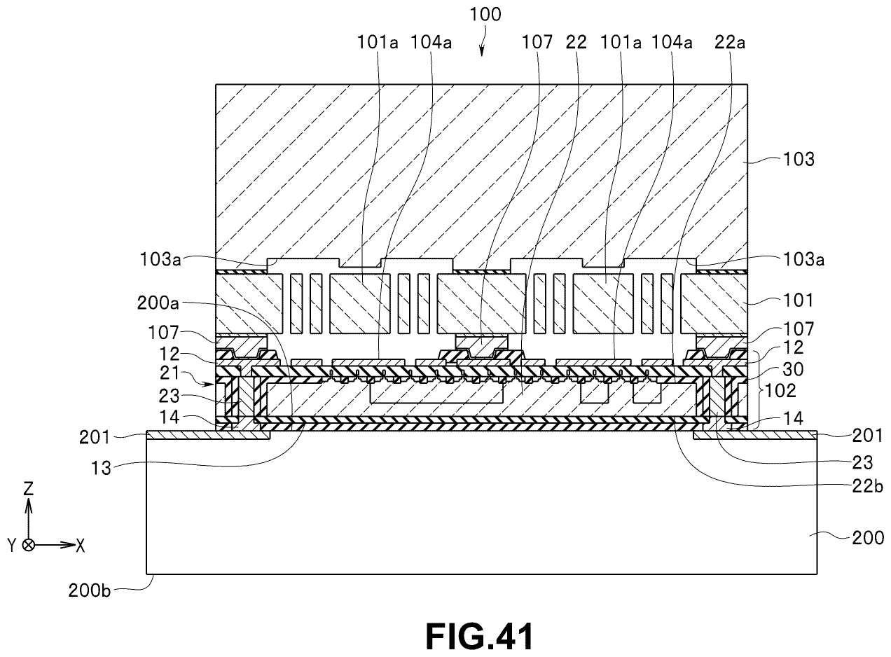

Next, a first example and a second example in which the MEMS device 100 is mounted on a mounting target object are described. First, with reference to FIG. 41, the first example is described. FIG. 41 is a cross-sectional view illustrating the first example in which the MEMS device 100 is mounted on a mounting target object 200. The mounting target object 200 is a mounting substrate, for example. The mounting target object 200 includes a first surface 200a and a second surface 200b on a side opposite to the first surface 200a, and includes a plurality of wiring layers 201 formed in the first surface 200a.

In the first example, the MEMS device 100 is fixed to the mounting target object 200 so that the circuit unit 102 is fixed to the mounting target object 200. In other words, the MEMS device 100 is fixed to the mounting target object 200 in a posture where the second surface 22b of the substrate 22 faces the first surface 200a of the mounting target object 200. The plurality of electrode pads 14 are directly connected to the plurality of wiring layers 201.

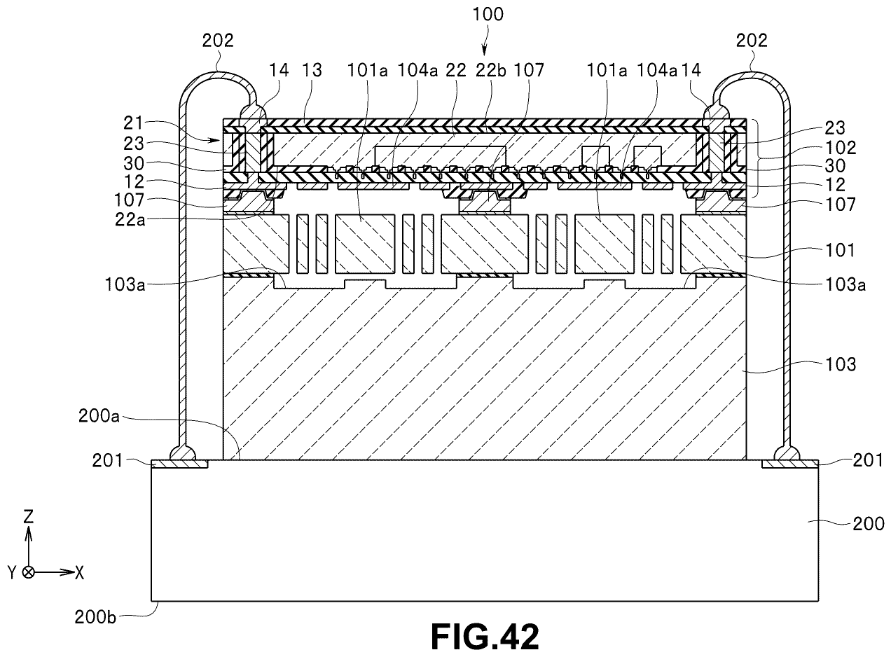

Next, with reference to FIG. 42, the second example is described. FIG. 42 is a cross-sectional view illustrating the second example in which the MEMS device 100 is mounted on the mounting target object 200. In the second example, the MEMS device 100 is fixed to the mounting target object 200 so that the cap 103 is fixed to the mounting target object 200. In other words, the MEMS device 100 is fixed to the mounting target object 200 in a posture where the first surface 22a of the substrate 22 is fixed to the first surface 200a of the mounting target object 200. For example, the plurality of electrode pads 14 are connected to the plurality of wiring layers 201 via a plurality of bonding wires 202.

Next, a manufacturing method of the MEMS device 100 according to the present embodiment is described. The manufacturing method of the MEMS device 100 includes a step of forming the movable unit 101 and the cap 103 and a step of forming the circuit unit 102.

The step of forming the movable unit 101 and the cap 103 includes a step of forming an insulating portion on a cap substrate that later serves as the cap 103, a step of forming the movable unit 101 on the cap substrate and the insulating portion, and a step of forming the cavity 103a by performing etching to remove the insulating portion after forming the movable unit 101. For example, the insulating portion may include an insulating layer formed of phosphosilicate glass and an insulating film formed of SiO₂. In this case, for example, the insulating portion is removed by a buffered oxide etchant (BOE).

The step of forming the circuit unit 102 includes a through-hole electrode formation step of forming the at least one electrode and the insulating film 30 on the substrate 22, and a circuit formation step of forming the processor 105 serving as a signal processing circuit on the substrate 22. The through-hole electrode formation step is substantially the same as the manufacturing method of the through-hole electrode substrate 21, which is described in the first embodiment. In other words, the through-hole electrode formation step includes a step of forming the plurality of trenches 25 from the first surface 22a of the substrate 22 to the inside of the substrate 22, a step of diffusing an impurity from the wall surfaces and the bottom surfaces of the plurality of trenches 25 into the substrate 22 and forming the impurity diffusion region 24, a step of forming the insulating film 30 in the plurality of trenches 25, and a polishing step of polishing the surface (the polishing surface) on a side opposite to the first surface 22a of the substrate 22 so that the impurity diffusion region 24 serves as the plurality of electrodes 23. The polishing step is performed until the insulating film 30 and the impurity diffusion region 24 are exposed. The polishing step is performed after the circuit formation step.

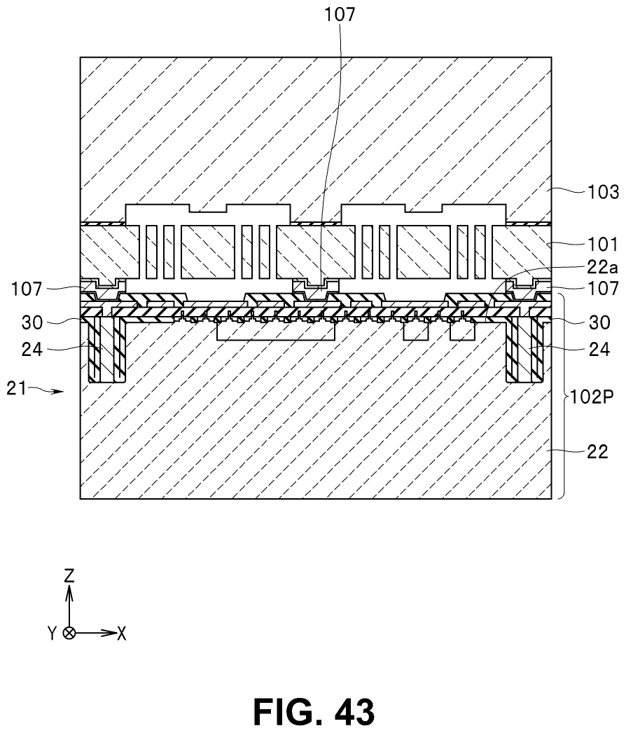

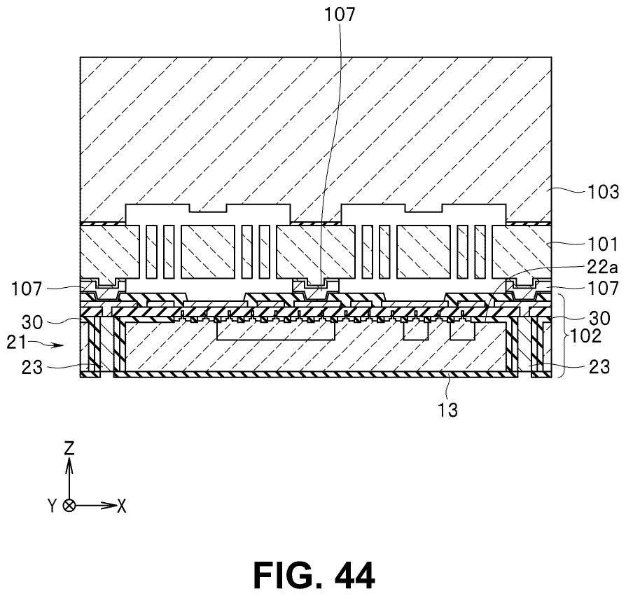

Herein, the circuit unit 102 before performing the polishing step is referred to as an initial circuit unit 102P. The steps after the polishing step may be performed while the movable unit 101 and the cap 103 are fixed to the initial circuit unit 102P. With reference to FIG. 43 and FIG. 44, description is made below on the steps after the polishing step that are performed while the movable unit 101 and the cap 103 are fixed to the initial circuit unit 102P. FIG. 43 and FIG. 44 are cross-sectional views illustrating a stacked body in the manufacturing process of the MEMS device 100.

FIG. 43 illustrates a state in which the movable unit 101 and the cap 103 are fixed to the initial circuit unit 102P. Directly before the polishing step, the movable unit 101 and the cap 103 are fixed to the initial circuit unit 102P. The movable unit 101 and the cap 103 may be fixed to the initial circuit unit 102P by eutectic bonding, for example.

FIG. 44 illustrates the following step. In this step, first, similarly to the step illustrated in FIG. 13 in the first embodiment, the substrate 22 is polished. The substrate 22 is polished from a polishing surface on a side opposite to the first surface 22a of the substrate 22, and is polished until the insulating film 30 and the impurity diffusion region 24 that are formed in the plurality of trenches 25 are exposed. The polishing surface after polishing serves as the second surface 22b of the substrate 22. The part of the impurity diffusion region 24, which remains after polishing, partially serves as the plurality of electrodes 23. Subsequently, the insulating film 13 including the plurality of opening portions from which the plurality of electrodes 23 are exposed is formed on the second surface 22b of the substrate 22. Then, the electrode pad 14 illustrated in FIG. 1 and the like are formed, and thus the MEMS device 100 is completed.

Next, the operation and effects of the MEMS device 100 according to the present embodiment are described. In the present embodiment, the circuit unit 102 is configured by using the through-hole electrode substrate 21. With this, according to the present embodiment, the manufacturing cost of the MEMS device 100 can be reduced. The effect is described below in comparison with a MEMS device 300 in a comparative example.

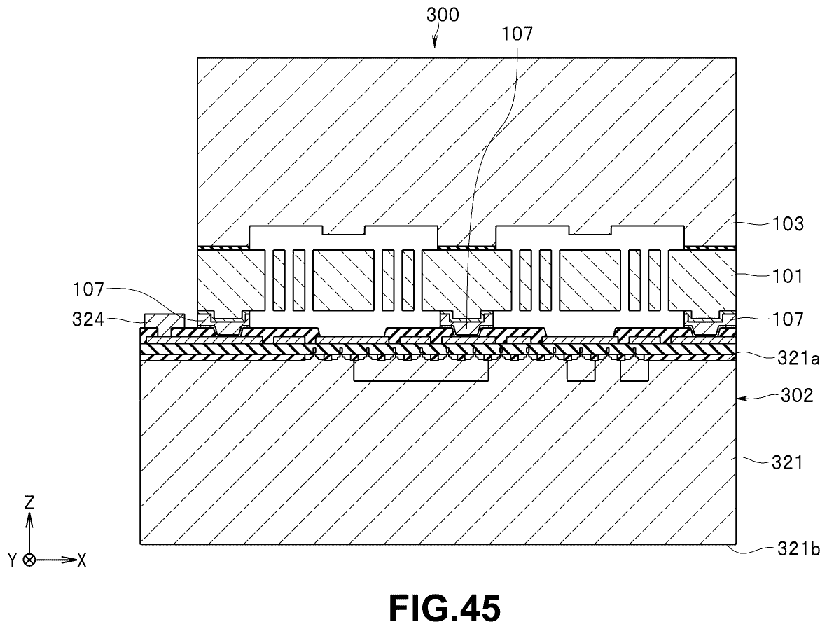

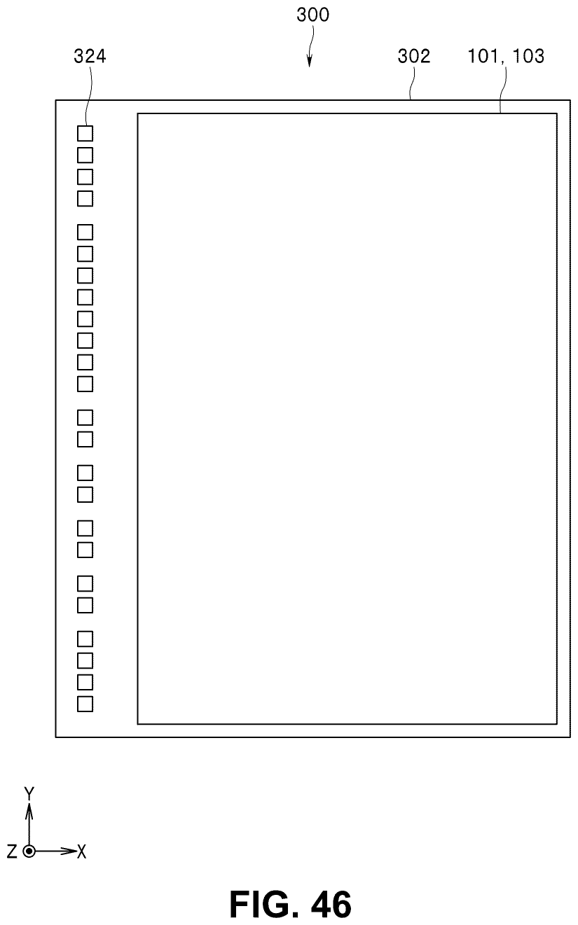

FIG. 45 is a cross-sectional view illustrating the MEMS device 300 in the comparative example. FIG. 46 is a plan view illustrating the MEMS device 300 in the comparative example. The MEMS device 300 in the comparative example includes a circuit unit 302 in the comparative example in place of the circuit unit 102 in the present embodiment. In the comparative example, the movable unit 101 and the cap 103 are fixed onto the circuit unit 302. The configurations of the movable unit 101 and the cap 103 are the same as the configurations of the movable unit 101 and the cap 103 in the present embodiment.

The circuit unit 302 is configured by using a substrate 321 in place of the through-hole electrode substrate 21 in the present embodiment. The substrate 321 includes a first surface 321a facing the movable unit 101 and a second surface 321b on a side opposite to the first surface 321a. A signal processing circuit is formed on the substrate 321 and the first surface 321a of the substrate 321.

The circuit unit 302 further includes a plurality of electrode pads 324 that are formed on the first surface 321a of the substrate 321. The plurality of electrode pads 324 are electrically connected to a wiring layer of a mounting target object, which is omitted in illustration. As illustrated in FIG. 45 and FIG. 46, the plurality of electrode pads 324 are arranged so as not to overlap with the movable unit 101 and the cap 103 as viewed in the Z direction.

In the comparative example, as illustrated in FIG. 45 and FIG. 46, the planar shape of the circuit unit 302 is larger than the planar shapes of the movable unit 101 and the cap 103 so that the plurality of electrode pads 324 are prevented from being covered with the movable unit 101 and the cap 103. Thus, when comparison is made while using the same wafer size, the number of circuit units 302 that can be fabricated from one wafer is less than the number of movable units 101 and caps 103 that can be fabricated from one wafer.

In contrast, in the present embodiment, the circuit unit 102 is configured by using the through-hole electrode substrate 21. With this, as illustrated in FIG. 39, the planar shape of the circuit unit 102 can be the same or substantially the same as the planar shapes of the movable unit 101 and the cap 103. With this, according to the present embodiment, a larger number of circuit units 102 can be fabricated from one wafer as compared to the comparative example. As a result, according to the present embodiment, the manufacturing cost of the MEMS device 100 can be reduced.

The configuration, operation and effects of the present embodiment are otherwise the same as those of the first embodiment or the second embodiment.

### Seventh Embodiment

Next, a seventh embodiment of the disclosure is described. The MEMS device 100 according to the present embodiment is different from the sixth embodiment in that it is configured by using the through-hole electrode substrate 21 of the third embodiment or the fourth embodiment.

The manufacturing method of the MEMS device 100 according to the present embodiment is described below. In the present embodiment, the through-hole electrode formation step is the same as the manufacturing method of the through-hole electrode substrate 21, which is described in the third embodiment. In other words, the through-hole electrode formation step includes a step of forming the plurality of trenches 25 from the first surface 22a of the substrate 22 to the inside of the substrate 22, a step of forming the insulating film 30 in the plurality of trenches 25, a polishing step of polishing the surface (the polishing surface) on a side opposite to the first surface 22a of the substrate 22 so as to expose the insulating film 30, a step of forming a plurality of through holes by removing a part of the substrate 22 that is surrounded by the insulating film 30, and a step of forming the plurality of electrodes 27 in the plurality of through holes. The polishing step is performed after the circuit formation step.

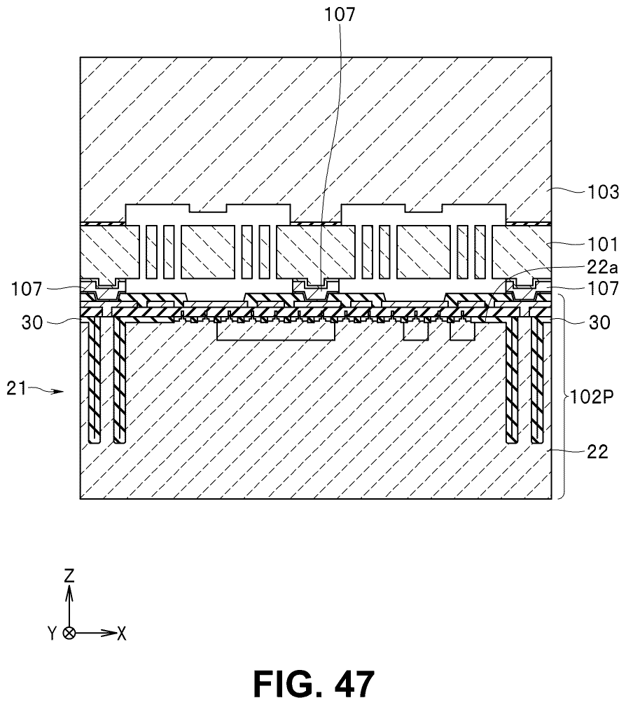

The steps after the polishing step may be performed while the movable unit 101 and the cap 103 are fixed to the initial circuit unit 102P. With reference to FIG. 47 to FIG. 52, description is made below on the steps after the polishing step that are performed while the movable unit 101 and the cap 103 are fixed to the initial circuit unit 102P. FIG. 47 to FIG. 52 are cross-sectional views illustrating a stacked body in the manufacturing process of the MEMS device 100.

FIG. 47 illustrates a state in which the movable unit 101 and the cap 103 are fixed to the initial circuit unit 102P. Directly before the polishing step, the movable unit 101 and the cap 103 are fixed to the initial circuit unit 102P.

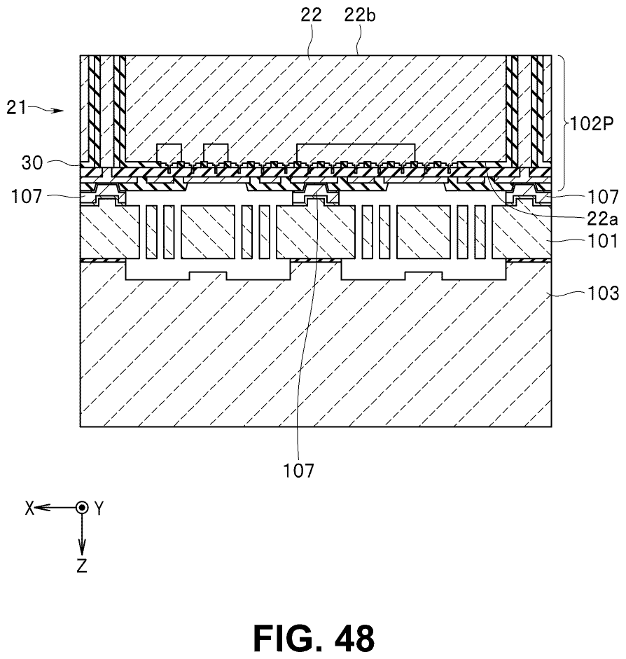

FIG. 48 illustrates the following step. In this step, similarly to the step illustrated in FIG. 28 in the third embodiment, the substrate 22 is polished until the insulating film 30 formed in the plurality of trenches 25 is exposed. The substrate 22 is polished from a polishing surface on a side opposite to the first surface 22a of the substrate 22. The polishing surface after polishing serves as the second surface 22b of the substrate 22.

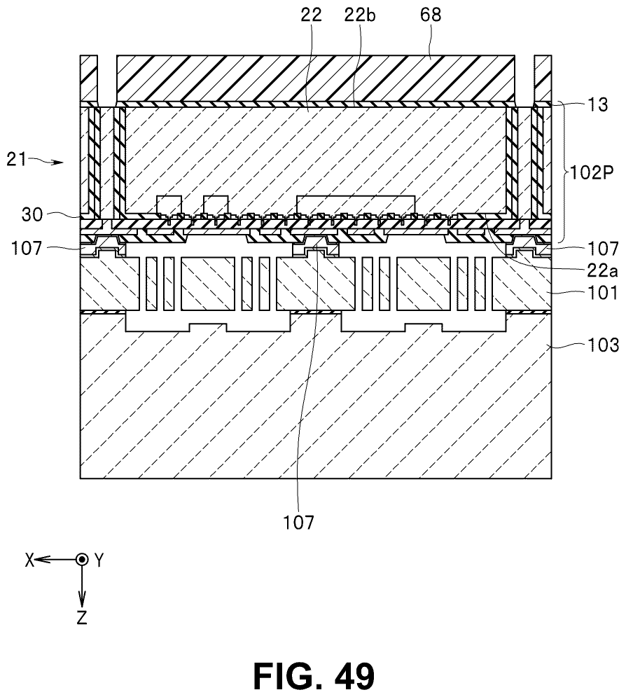

FIG. 49 illustrates the following step. In this step, first, the insulating film 13 is formed on the second surface 22b of the substrate 22. Subsequently, a photoresist mask 68 is formed on the insulating film 13. Subsequently, the photoresist mask 68 is used as an etching mask, and the insulating film 13 is subjected to etching, for example, RIE.

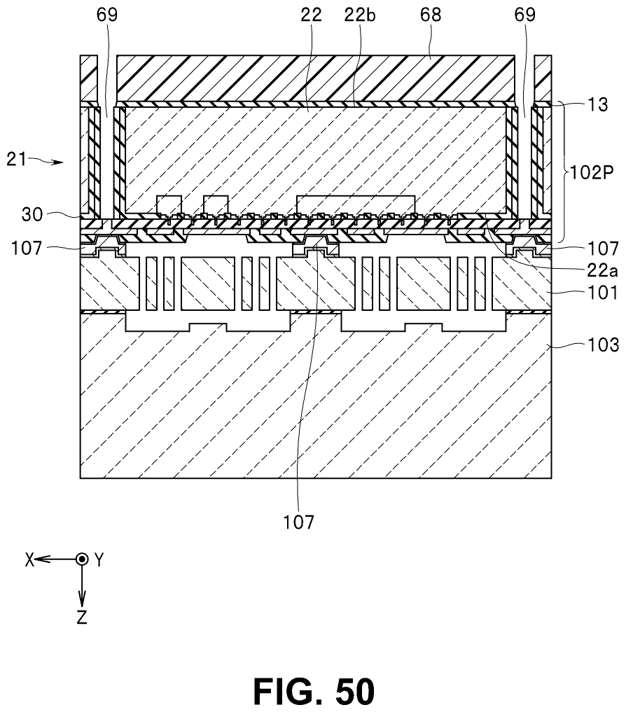

FIG. 50 illustrates the following step. In this step, the photoresist mask 68 is used as an etching mask, and the substrate 22 is subjected to etching, for example, RIE. The etching continues until the plurality of through holes 69 are formed in the substrate 22 to expose the electrode portion 12.

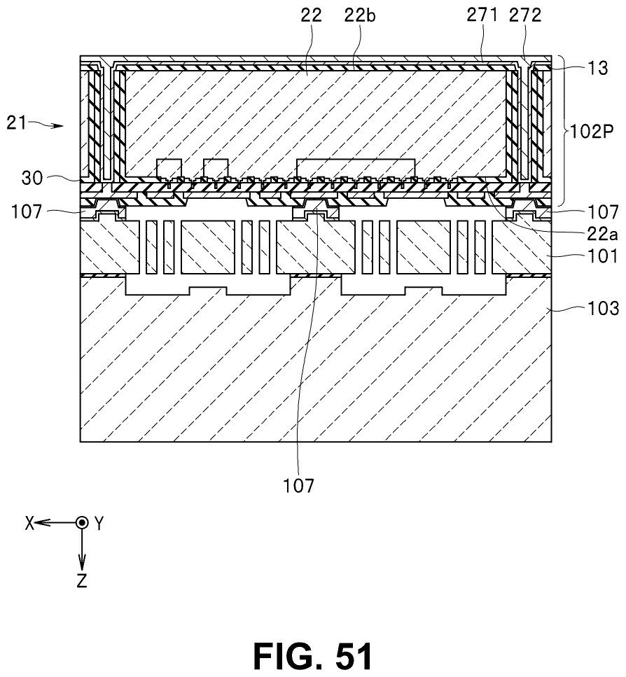

FIG. 51 illustrates the following step. In this step, first, the photoresist mask 68 is removed. Subsequently, the first layer 271 and the second layer 272 are subsequently formed in the plurality of through holes 69.

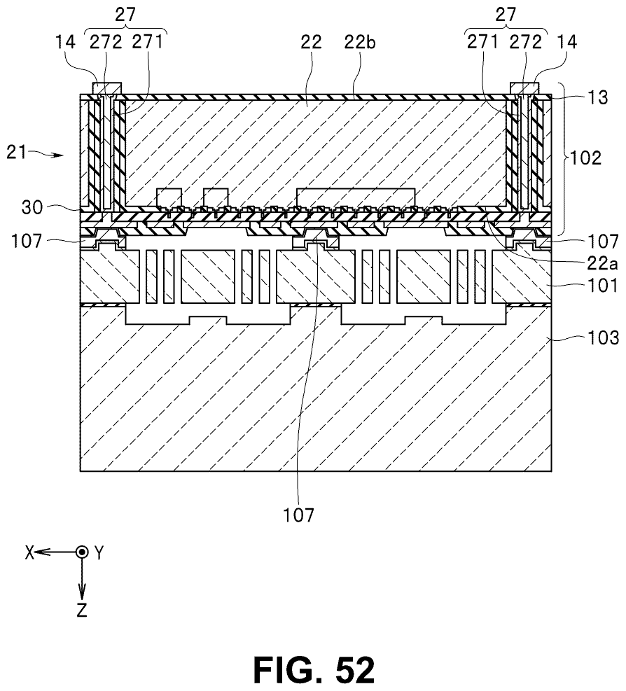

FIG. 52 illustrates the following step. In this step, the first layer 271 and the second layer 272 are polished until the insulating film 13 is exposed. With this, the plurality of electrodes 27 are completed. Then, the electrode pad 14 and the like are formed, and thus the MEMS device 100 is completed.

The configuration, operation and effects of the present embodiment are otherwise the same as those of the third embodiment, the fourth embodiment, or the sixth embodiment.

### Eighth Embodiment

Next, an eighth embodiment of the disclosure is described. A MEMS device 400 according to the present embodiment is configured by using the through-hole electrode substrate 21 of any one of the first embodiment to the fourth embodiment.

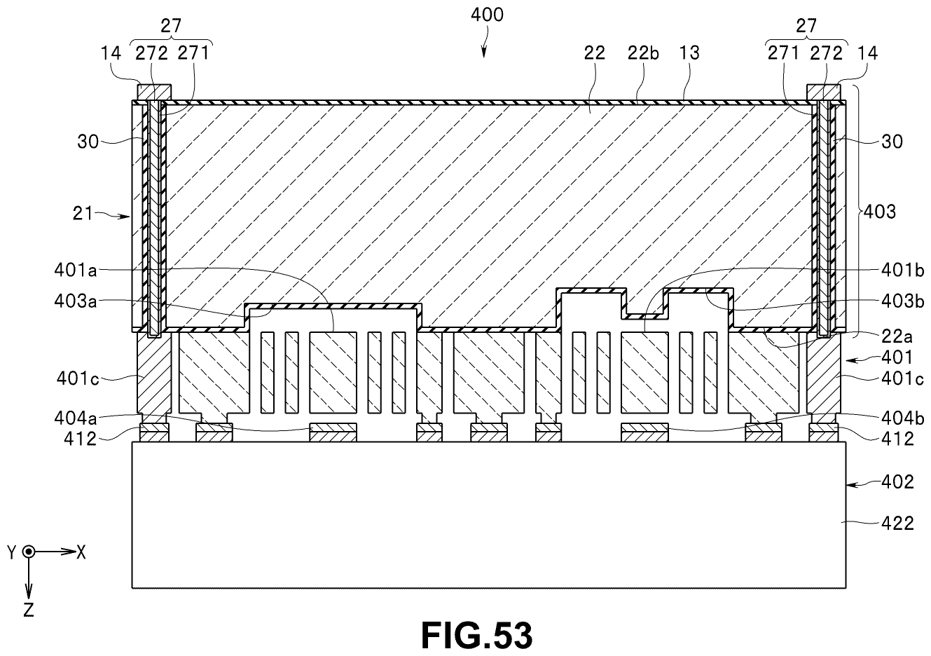

A configuration of the MEMS device 400 is described below while giving an example in which the MEMS device 400 according to the present embodiment is configured by using the through-hole electrode substrate 21 of the third embodiment. FIG. 53 is a cross-sectional view illustrating the MEMS device 400.

The MEMS device 400 includes a movable unit 401, and a circuit unit 402 and a cap 403 that are arranged to sandwich the movable unit 401. In the present embodiment, the cap 403 is configured by using the through-hole electrode substrate 21, and corresponds to the device 10 in the third embodiment (the first embodiment). In the following description, the constituent elements of the cap 403 that are commonly shared as the constituent elements of the device 10 are denoted with the same reference symbols as the constituent elements of the device 10.

The cap 403 includes cavities 403a and 403b having predetermined shapes. Particularly in the present embodiment, the insulating film 30 of the through-hole electrode substrate 21 may be formed on the front surfaces of the cavities 403a and 403b.

The main body of the cap 403 is configured by using the substrate 22 of the through-hole electrode substrate 21. The main body of the cap 403 includes a first surface facing the movable unit 401 and a second surface on a side opposite to the first surface. The first surface and the second surface of the main body of the cap 403 are configured by the first surface 22a and the second surface 22b of the substrate 22, respectively. The insulating film 13 and the plurality of electrode pads 14 are provided on the second surface of the main body of the cap 403.

Particularly in the present embodiment, the MEMS device 400 is configured as a motion sensor including an acceleration sensor and a gyro sensor. The movable unit 401 includes movable elements 401a and 401b as weights, a structure of fixing the movable elements 401a and 401b, a first electrode (a movable electrode) provided to the lower surface of the movable element 401a, and a second electrode (a movable electrode) provided to the lower surface of the movable element 401b. The movable element 401a may be a movable element of an acceleration sensor. The movable element 401b may be a movable element of a gyro sensor.

The movable element 401a is positioned within a space that includes the cavity 403a and is surrounded by the circuit unit 402 and the cap 403. The movable element 401a is configured to be movable in the space including the cavity 403a. Similarly, the movable element 401b is a space that includes the cavity 403b and is surrounded by the circuit unit 402 and the cap 403. The movable element 401b is configured to be movable in the space including the cavity 403b.

The movable unit 401 further includes a plurality of electrode portions 401c that are connected to the plurality of electrodes 27 of the through-hole electrode substrate 21. Each of the plurality of electrode portions 401c is formed of silicon in which an impurity is diffused. For example, each of the plurality of electrode portions 401c may be a heavily impurity-doped N-type conductor, or may be a heavily impurity-doped P-type conductor.

The configuration of the circuit unit 402 is the same as the configuration of the circuit unit 102 in the sixth embodiment, except that it is not configured by using the through-hole electrode substrate 21. Note that, in FIG. 53, for the sake of convenience, the circuit unit 402 is illustrated in simplified manner. The circuit unit 402 includes a substrate 422. The substrate 422 includes a first surface facing the movable unit 401 and a second surface on a side opposite to the first surface. The circuit unit 402 further includes stationary electrodes 404a and 404b that are formed on the first surface of the substrate 422, and a processor serving as a signal processing circuit that is formed on the substrate 422 and the first surface of the substrate 422. The stationary electrode 404a faces the first electrode provided to the lower surface of the movable element 401a. The stationary electrode 404b faces the second electrode provided to the lower surface of the movable element 401b.

The MEMS device 400 further includes a plurality of electrode portions 412 that connect the plurality of electrode portions 401c to the processor of the circuit unit 402. The plurality of electrode pads 14 are connected to the processor of the circuit unit 402 via the plurality of electrodes 27, the plurality of electrode portions 401c, and the plurality of electrode portions 412.

The configuration, operation and effects of the present embodiment are otherwise the same as those of any one of the first embodiment to the sixth embodiment.

### Ninth Embodiment

Next, a multilayered device according to a ninth embodiment of the disclosure is described. A multilayered device 500 according to the present embodiment includes the plurality of devices 501 being stacked. Each of the plurality of devices 501 is configured by using the through-hole electrode substrate 21 of any one of the first embodiment to the fourth embodiment.

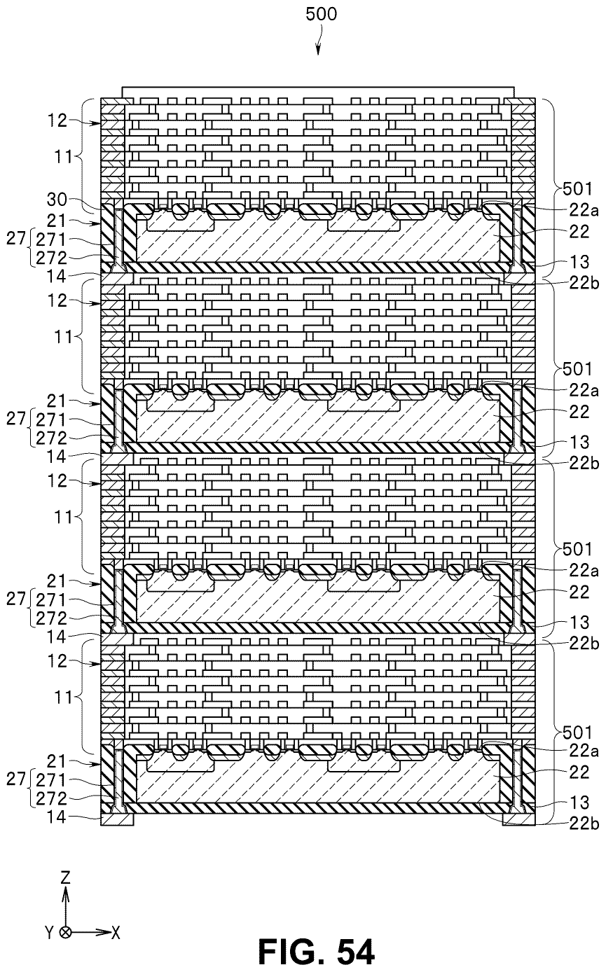

A configuration of the multilayered device 500 is described below while giving an example in which each of the plurality of devices 501 is configured by using the through-hole electrode substrate 21 of the third embodiment. FIG. 54 is a cross-sectional view illustrating the multilayered device 500.

A configuration of each of the plurality of devices 501 is similar to the configuration of the device 10 in the third embodiment (the first embodiment). In the following description, the constituent elements of each of the plurality of devices 501 that are commonly shared as the constituent elements of the device 10 are denoted with the same reference symbols as the constituent elements of the device 10. As illustrated in FIG. 54, the electrode 27 of one of two adjacent devices 501 among the plurality of devices 501 and the electrode 27 of the other of two adjacent devices are electrically connected to each other via the electrode pad 14. The two devices 501 may be joined by eutectic bonding or by using solder.

In the example illustrated in FIG. 54, the plurality of devices 501, specifically, four devices 501 are provided. However, as the plurality of devices 501, two, three, five, or more devices 501 may be provided.

Particularly in the present embodiment, the multilayered device 500 may be a stacked-type memory package, and each of the plurality of devices 501 may be a memory chip including a storage circuit, such as a flash memory.

The configuration, operation and effects of the present embodiment are otherwise the same as those of any one of the first embodiment to the fourth embodiment.

### Tenth Embodiment

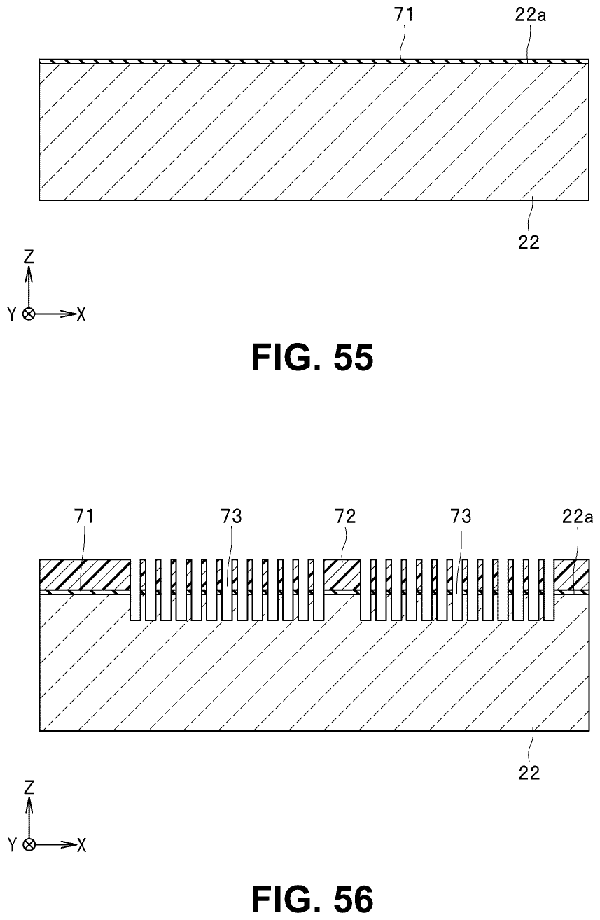

Next, a manufacturing method of the MEMS device 400 according to a tenth embodiment of the disclosure is described. The configuration of the MEMS device 400 according to the present embodiment is similar to the configuration of the MEMS device 400 according to the eighth embodiment. With reference to FIG. 55 to FIG. 69, description is made below on a step of forming the movable unit 401 and the cap 403 of the MEMS device 400. FIG. 55 to FIG. 69 are cross-sectional views illustrating a stacked body in the manufacturing process of the MEMS device 400.

As described in the eighth embodiment, the cap 403 is configured by using the through-hole electrode substrate 21. In the step of forming the movable unit 401 and the cap 403, first, as illustrated in FIG. 55, an insulating film 71 formed of, for example, Si₃N₄ is formed on the first surface 22a of the substrate 22 of the through-hole electrode substrate 21.

FIG. 56 illustrates the following step. In this step, first, a photoresist mask 72 is formed on the insulating film 71. Subsequently, the insulating film 71 is selectively subjected to etching, for example, RIE by using the photoresist mask 72 as an etching mask. Subsequently, the insulating film 71 and the photoresist mask 72 are used as etching masks, and the plurality of trenches 73 are formed in the substrate 22 by RIE, for example. Subsequently, the photoresist mask 72 is removed.

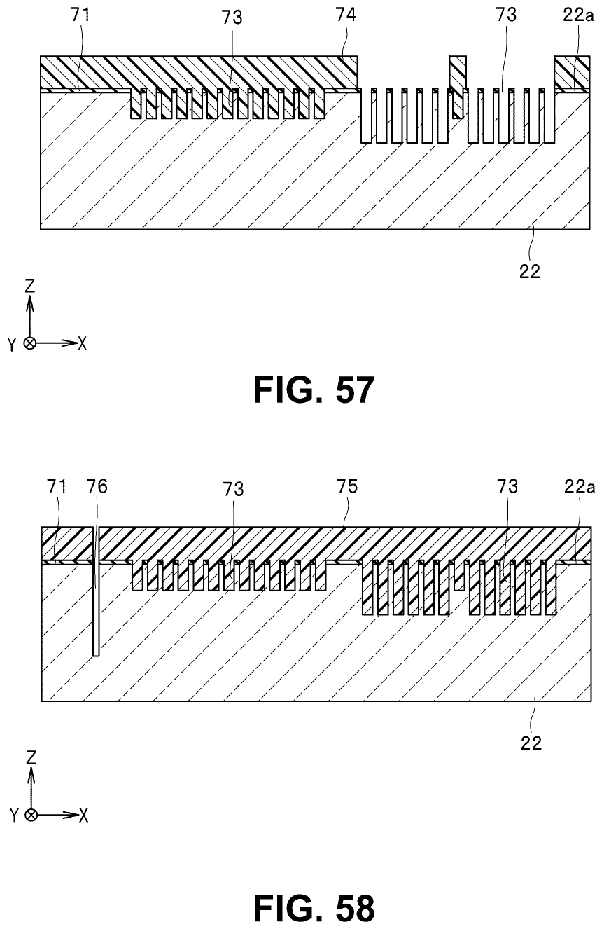

FIG. 57 illustrates the following step. In this step, first, a photoresist mask 74 is formed on the substrate 22 and the insulating film 71. The photoresist mask 74 covers some of the plurality of trenches 73, and includes an opening portion from which the other of the plurality of trenches 73. Subsequently, the insulating film 71 and the photoresist mask 74 are used as etching masks, and the other of the plurality of trenches 73 are subjected to etching, for example, by RIE so that the depths of the other of the plurality of trenches 73 are increased. Subsequently, the photoresist mask 74 is removed.

FIG. 58 illustrates the following step. In this step, first, a photoresist mask 75 is formed on the substrate 22 and the insulating film 71. The photoresist mask 75 covers the plurality of trenches 73, and includes an opening portion. Subsequently, the photoresist mask 75 is used as an etching mask, and the insulating film 71 is subjected to etching, for example, RIE. Subsequently, the insulating film 71 and the photoresist mask 75 are used as etching masks, and the substrate 22 is subjected to deep etching to form a trench 76. The trench 76 is formed from the first surface 22a of the substrate 22 to the inside of the substrate 22. Subsequently, the photoresist mask 75 is removed.

The trench 76 corresponds to the plurality of trenches 25 in the first embodiment to the fourth embodiment. Note that FIG. 58 illustrates one trench 76 for the sake of convenience. However, the plurality of trenches 76 are formed in the step illustrated in FIG. 58. As described in the first embodiment to the fourth embodiment, in the steps after that, the plurality of electrodes 23 or the plurality of electrodes 27 are formed by using the plurality of trenches 76. The plurality of electrodes 23 or the plurality of electrodes 27 are formed on the-X side of the trench 76 illustrated in FIG. 58, for example. In the following description, for the sake of convenience, description on the step of forming the plurality of electrodes 23 or the plurality of electrodes 27, and illustration of the plurality of electrodes 23 or the plurality of electrodes 27 are omitted.

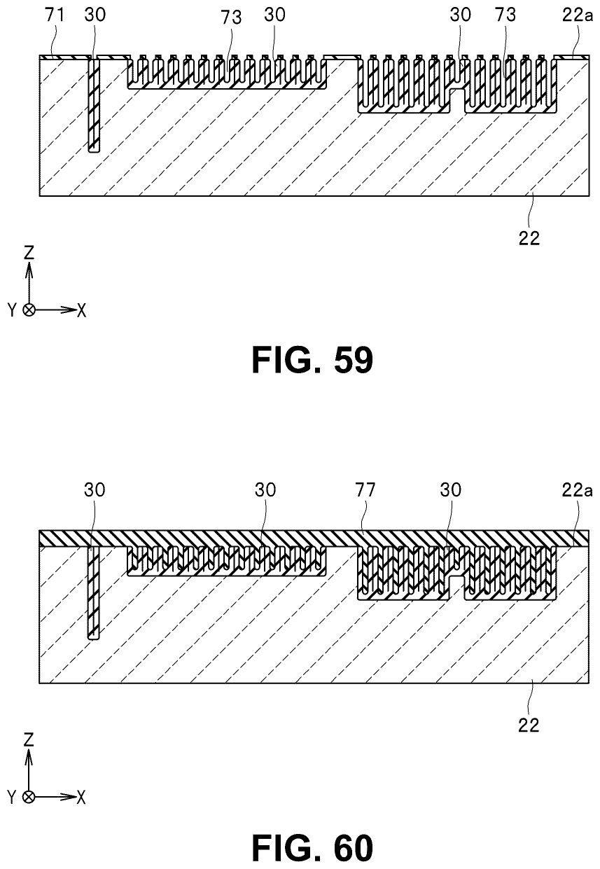

FIG. 59 illustrates the following step. In this step, the insulating film 30 is formed in the plurality of trenches 73 and the trench 76. The insulating film 30 may be an SiO₂ film formed by the thermal oxidation method, for example. In this case, the substrate 22 is oxidized from the wall surface and the bottom surface of each of the plurality of trenches 73 and the trench 76, and an SiO₂ film (the insulating film 30) is formed in the plurality of trenches 73 and the trench 76. The insulating film 30 is formed so as not to completely fill the plurality of trenches 73 and so as to completely fill the trench 76.

FIG. 60 illustrates the following step. In this step, first, the insulating film 71 is removed. Subsequently, an insulating layer 77 is formed on the entire upper surface of the stacked body. The insulating layer 77 is formed so as to completely fill the plurality of trenches 73. The insulating layer 77 may be formed of, for example, SiO₂ formed by the chemical vapor deposition (CVD) method, phosphosilicate glass (PSG), or a spin-on-glass (SOG) material.

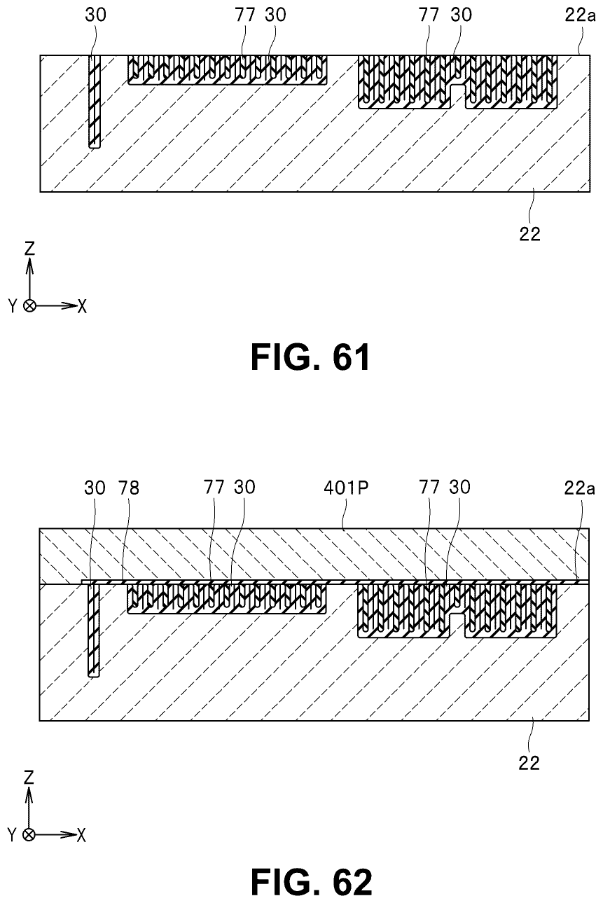

FIG. 61 illustrates the following step. In this step, first, a part of the insulating layer 77 is removed until the insulating film 30 is exposed. When the insulating layer 77 is formed of SiO₂ or phosphosilicate glass, the insulating layer 77 may be polished by chemical mechanical polishing (CMP), for example. When the insulating layer 77 is formed of a spin-on-glass material, the insulating layer 77 may be selectively removed by etch-back, for example.

FIG. 62 illustrates the following step. In this step, first, an insulating film 78 formed of, for example, Si₃N₄ is formed on the upper surface of the stacked body. The insulating film 78 may be formed so as not to cover the region where the plurality of electrodes 23 or the plurality of electrodes 27 are to be subsequently formed.

Subsequently, an initial movable unit 401P that later serves as the movable unit 401 is formed on the entire upper surface of the stacked body. The initial movable unit 401P may be formed of epitaxial polysilicon, or may be formed of a low-stress polysilicon material. When the initial movable unit 401P is formed of epitaxial polysilicon, the initial movable unit 401P is formed by thermally decomposing dichlorosilane (SiH₂Cl₂) or monosilane (SiH₄), for example. The thermal decomposition temperature falls within the range from 1,000 degrees Celsius to 1,100 degrees Celsius, for example.

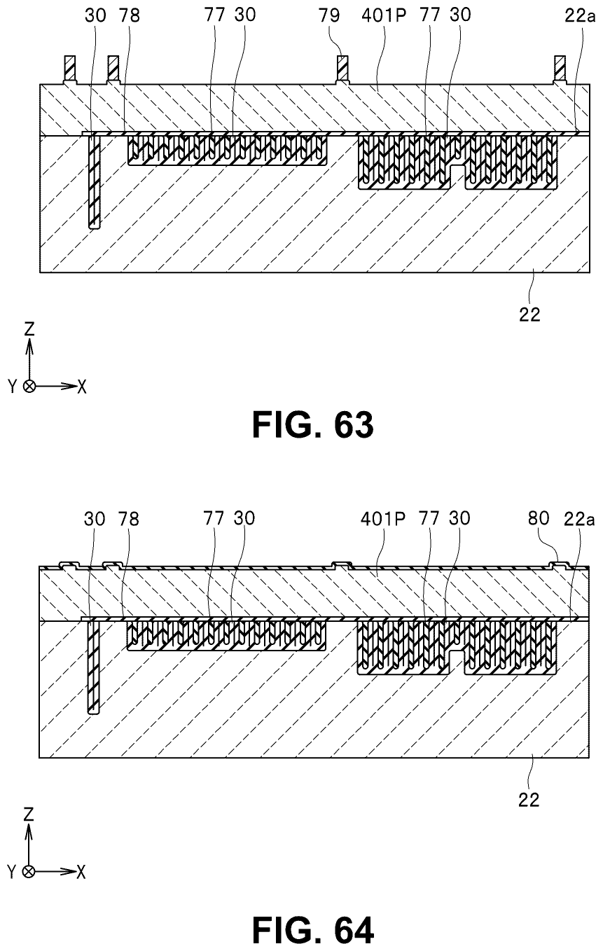

FIG. 63 illustrates the following step. In this step, first, a photoresist mask 79 is formed on the initial movable unit 401P. Subsequently, the photoresist mask 79 is used as an etching mask, and the upper surface of the initial movable unit 401P is partially subjected to etching, for example, RIE to form a plurality of protrusions for eutectic bonding. Subsequently, the photoresist mask 79 is removed.

FIG. 64 illustrates the following step. In this step, an insulating film 80 formed of, for example, Si₃N₄ is formed on the initial movable unit 401P.

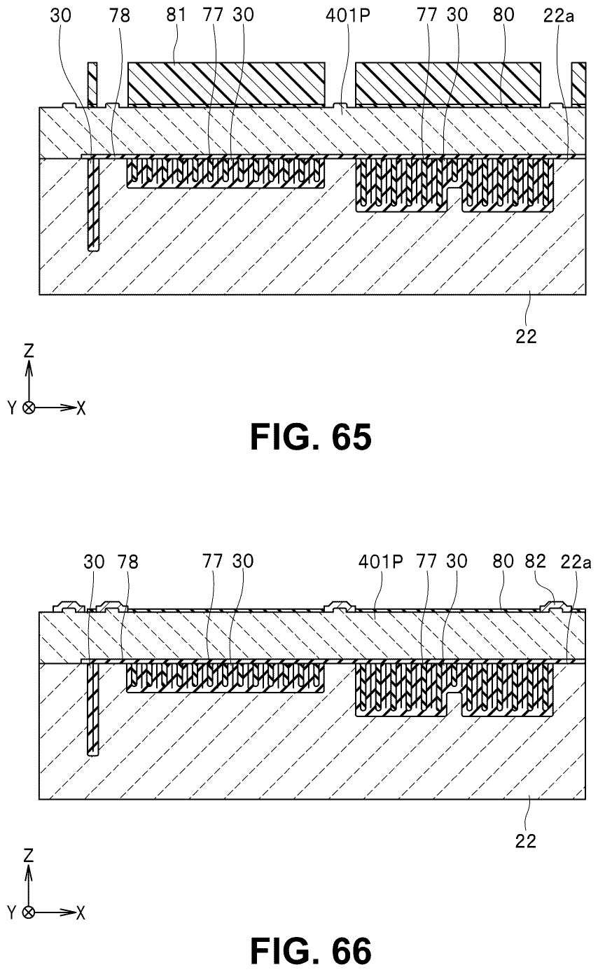

FIG. 65 illustrates the following step. In this step, first, a photoresist mask 81 is formed on the insulating film 80. Subsequently, the insulating film 80 is selectively subjected to etching, for example, RIE by using the photoresist mask 81 as an etching mask so that the plurality of protrusions formed on the upper surface of the initial movable unit 401P are exposed.

FIG. 66 illustrates the following step. In this step, first, a conductive layer 82 is formed on the plurality of protrusions formed on the upper surface of the initial movable unit 401P. The conductive layer 82 may contain metal used for eutectic bonding. For eutectic bonding, a material such as germanium is used. Subsequently, the photoresist mask 81 is removed.

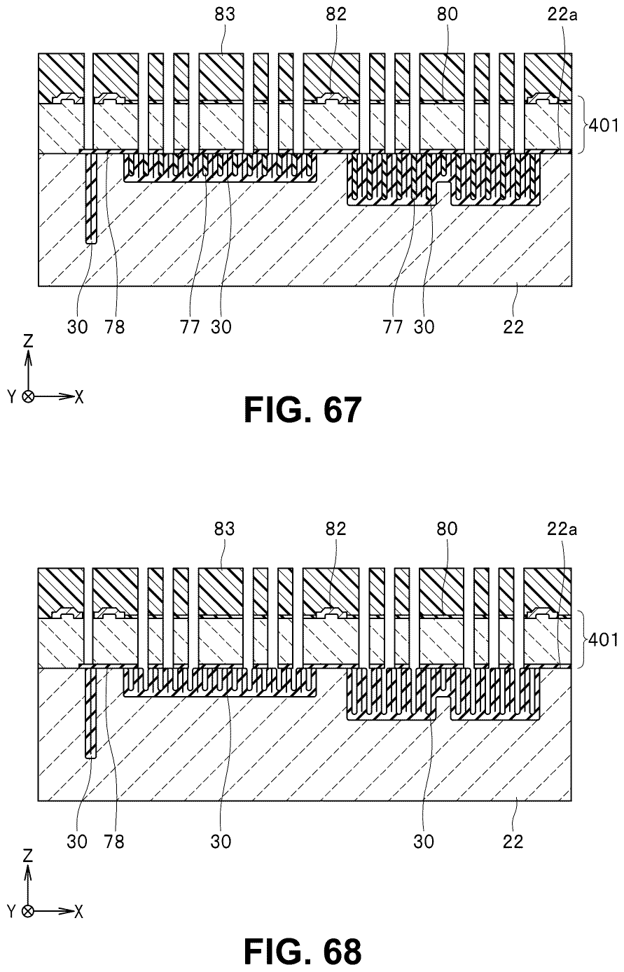

FIG. 67 illustrates the following step. In this step, first, a photoresist mask 83 having a shape corresponding to the movable unit 401 is formed on the initial movable unit 401P and the conductive layer 82. Subsequently, the photoresist mask 83 is used as an etching mask, the insulating films 78 and 80 are subjected to etching, for example RIE, and the initial movable unit 401P is subjected to deep etching. The initial movable unit 401P and the insulating films 78 and 80 are subjected to etching until parts formed in the plurality of trenches 73 of the insulating film 30 and the insulating layer 77 are exposed. Through the etching, the initial movable unit 401P serves as the movable unit 401.

FIG. 68 illustrates the following step. In this step, the insulating layer 77 is selectively removed through etching. As the etchant for the etching, a buffered oxide etchant (BOE) is used, for example. Through the etching, a plurality of groove portions are formed in the insulating film 30.

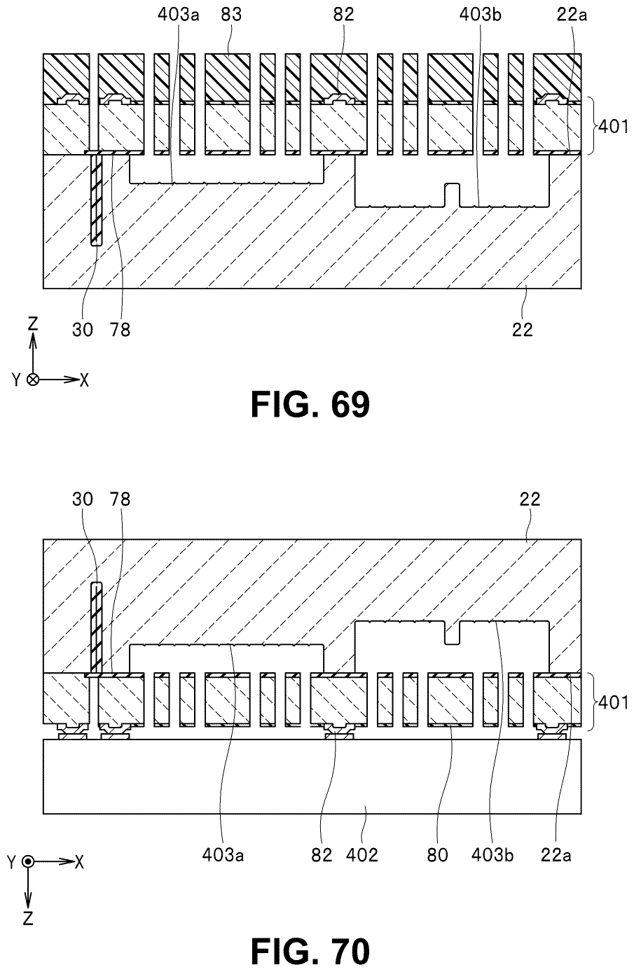

FIG. 69 illustrates the following step. In this step, parts formed in the plurality of trenches 73 of the insulating film 30 is removed through etching. As the etchant for the etching, a buffered oxide etchant (BOE) is used, for example. In this case, a buffered oxide etchant enters the plurality of groove portions formed in the insulating film 30, and then the insulating film 30 is subjected to etching in a direction orthogonal to the Z direction. With this, the etching time can be reduced as compared to a case in which etching of the insulating film 30 proceeds from the upper surface of the insulating film 30. Through the etching, the cavities 403a and 403b of the cap 403 are formed in the substrate 22. A plurality of micro protrusions may be formed on the bottom surface of each of the cavities 403a and 403b by subjecting the insulating film 30 to etching. The plurality of micro protrusions have a function of preventing the movable elements 401a and 401b from adhering to the bottom surfaces of the cavities 403a and 403b.

FIG. 70 illustrates the following step. In this step, the movable unit 401 is fixed to the circuit unit 402.

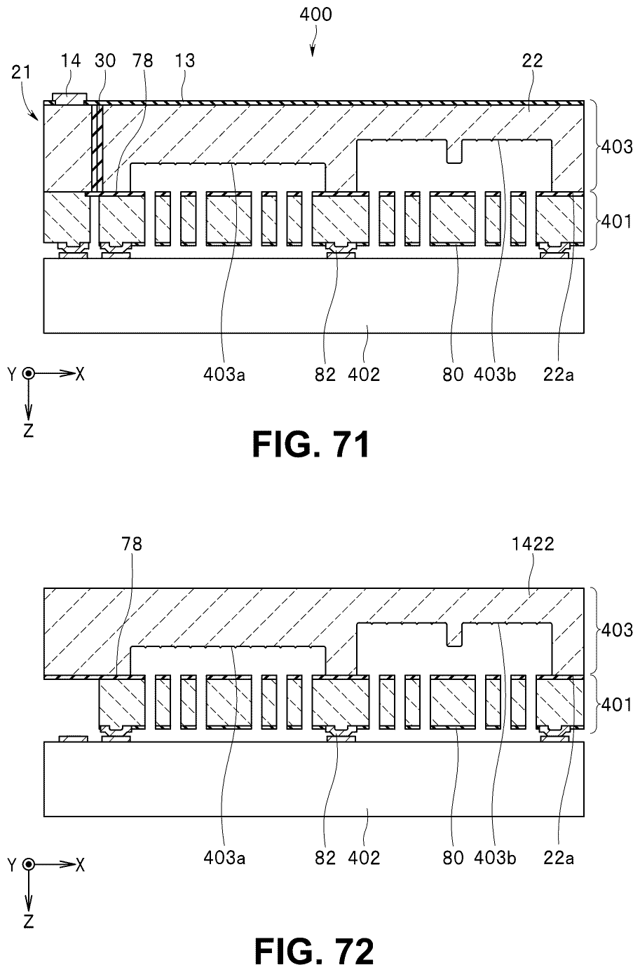

FIG. 71 illustrates the following step. In this step, first, the substrate 22 is polished until the insulating film 30 formed in the plurality of trenches 76 is exposed. The substrate 22 is polished from a polishing surface on a side opposite to the first surface 22a of the substrate 22. The polishing surface after polishing serves as the second surface 22b of the substrate 22. Subsequently, the insulating film 13 is formed on the second surface 22b of the substrate 22. Then, the electrode pad 14 and the like are formed, and thus the MEMS device 400 is completed.

Next, the operation and effects of the MEMS device 400 according to the present embodiment are described. In the present embodiment, the initial movable unit 401P formed on the substrate 22 is used to form the movable unit 401. With this, according to the present embodiment, as compared to a case in which the movable unit formed by using a silicon substrate is fixed to the circuit unit 402 and the cap 403, the number of silicon substrates used can be reduced. As a result, according to the present embodiment, the manufacturing cost of the MEMS device 400 can be reduced.

Incidentally, as a method of forming the cavity 403a of the cap 403, for example, a method of forming the cavities 403a and 403b in the substrate 22 before formation of the initial movable unit 401P is considered. In this case, the initial movable unit 401P is formed on the substrate 22 and the insulating layer after the cavities 403a and 403b are filled with the insulating layer. In this case, since the volume of the insulating layer is relatively increased, a relatively large stress is applied to the substrate 22 in the subsequent steps. As a result, there arises a problem in that the substrate 22 warps.

In contrast, in the present embodiment, the plurality of trenches 73 are formed, the insulating film 30 and the insulating layer 77 are formed in the plurality of trenches 73, and the insulating film 30 and the insulating layer 77 are removed. With this, the cavities 403a and 403b of the cap 403 are formed. With this, according to the present embodiment, a large stress can be prevented from being applied to the substrate 22.

In the present embodiment, the cavities 403a and 403b are formed by removing the insulating film 30 through etching. With this, in the present embodiment, a plurality of micro protrusions are formed on the bottom surface of each of the cavities 403a and 403b. The plurality of micro protrusions have a function of preventing the movable elements 401a and 401b from adhering to the bottom surfaces of the cavities 403a and 403b.

The configuration, operation and effects of the present embodiment are otherwise the same as those of any one of the first embodiment to the fourth embodiment and the eighth embodiment.

### Modification Example

Next, a modification of the manufacturing method of the MEMS device 400 according to the present embodiment is described. In the modification example, the cap 403 is configured by using a substrate 1422 in place of the through-hole electrode substrate 21. The substrate 1422 may be a silicon substrate. In the modification example, the trench 76 illustrated in FIG. 58 is not formed in the substrate 1422. Therefore, in the cap 403, the plurality of electrodes 23 or the plurality of electrodes 27 that are formed by using the plurality of trenches 76 are not provided.

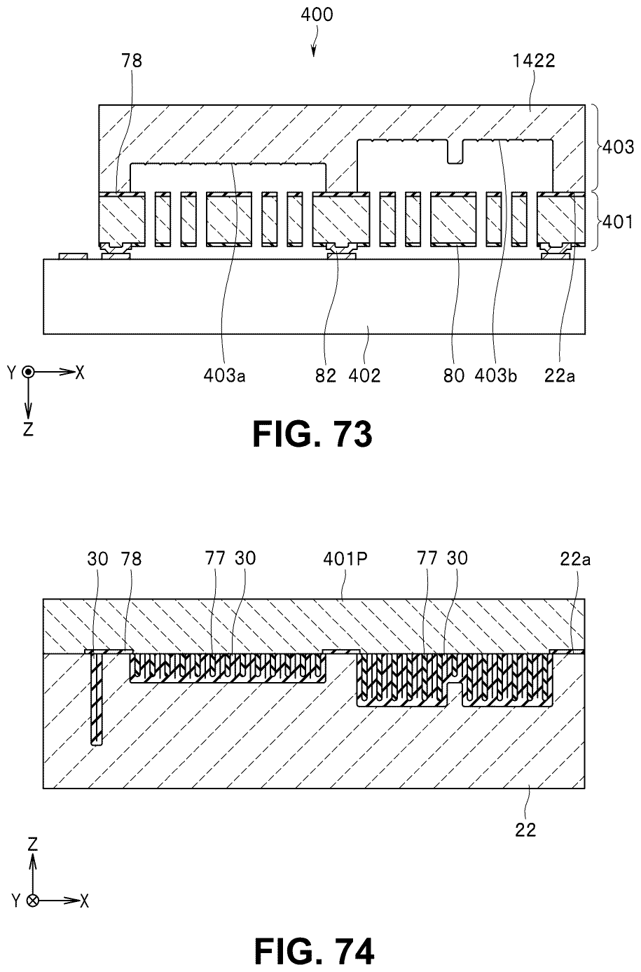

With reference to FIG. 72 and FIG. 73, description is made below on the step of forming the movable unit 401 and the cap 403 of the MEMS device 400. FIG. 72 and FIG. 73 are cross-sectional views illustrating a stacked body in the manufacturing process of the MEMS device 400.

It is similar to the manufacturing method of the MEMS device 400 according to the present embodiment up to the step of fixing the movable unit 401 to the circuit unit 402, except that the plurality of trenches 76, and the plurality of electrodes 23 or the plurality of electrodes 27 are not formed. FIG. 72 illustrates a state in which the movable unit 401 is fixed to the circuit unit 402. As illustrated in FIG. 72, the planar shape of the cap 403 is larger than the planar shape of the movable unit 401. In such a state, the cap 403 covers some of the plurality of electrodes formed in the circuit unit 402, which are not connected to the conductive layer 82.

FIG. 73 illustrates the following step. In this step, a part of the cap 403 is removed through, for example, dicing or RIE so as to expose some electrodes, which are not connected to the conductive layer 82, among the plurality of electrodes formed on the circuit unit 402. With this, the MEMS device 400 is completed.

### Eleventh Embodiment

Next, a manufacturing method of the MEMS device 400 according to an eleventh embodiment of the disclosure is described. With reference to FIG. 74 to FIG. 77, description is made below on the differences between the manufacturing method of the MEMS device 400 according to the present embodiment and the manufacturing method of the MEMS device 400 according to the tenth embodiment. FIG. 74 to FIG. 77 are cross-sectional views illustrating a stacked body in the manufacturing process of the MEMS device 400.

The manufacturing method of the MEMS device 400 according to the present embodiment is similar to the tenth embodiment up to the step of removing a part of the insulating layer 77 illustrated in FIG. 61. FIG. 74 illustrates the following step. In this step, first, the insulating film 78 formed of, for example, Si₃N₄ is selectively formed on the entire upper surface of the stacked body. The insulating film 78 includes an opening portion from which parts formed in the plurality of trenches 73 of the insulating film 30 and the insulating layer 77 are exposed. Subsequently, the initial movable unit 401P that later serves as the movable unit 401 is formed on the entire upper surface of the stacked body. The initial movable unit 401P may be formed of epitaxial polysilicon, or may be formed of a low-stress polysilicon material.

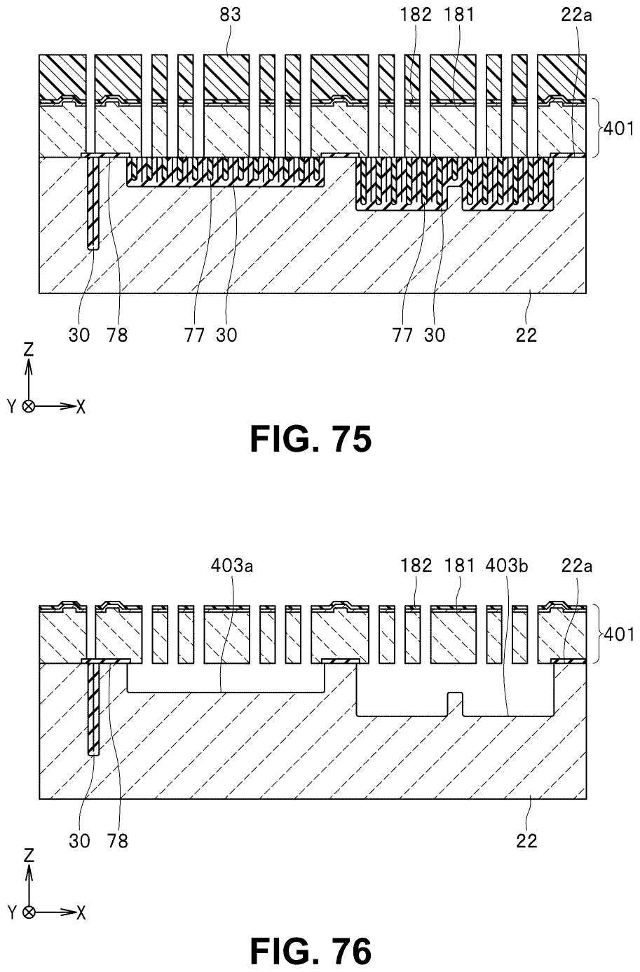

FIG. 75 illustrates the following step. In this step, first, similarly to the step illustrated in FIG. 63 in the tenth embodiment, the upper surface of the initial movable unit 401P is partially subjected to etching. Subsequently, a conductive layer 181 is formed on the initial movable unit 401P. Particularly in the present embodiment, the conductive layer 181 may be formed of polysilicon. Subsequently, an insulating film 182 formed of, for example, Si₃N₄ is formed on the conductive layer 181. Subsequently, the photoresist mask 83 having a shape corresponding to the movable unit 401 is formed on the insulating film 182. Subsequently, the photoresist mask 83 is used as an etching mask, and the insulating film 182 is subjected to etching, for example, RIE. Subsequently, the insulating film 182 and the photoresist mask 83 are used as etching masks, the conductive layer 181 is subjected to etching, for example, RIE, and the initial movable unit 401P is subjected to deep etching. The initial movable unit 401P is subjected to etching until parts formed in the plurality of trenches 73 of the insulating film 30 and the insulating layer 77 are exposed. Through the etching, the initial movable unit 401P serves as the movable unit 401. Subsequently, the photoresist mask 83 is removed.

FIG. 76 illustrates the following step. In this step, parts formed in the plurality of trenches 73 of the insulating film 30 and the insulating layer 77 are removed through etching. As the etchant for the etching, a buffered oxide etchant (BOE) is used, for example. With this, the cavities 403a and 403b of the cap 403 are formed in the substrate 22.

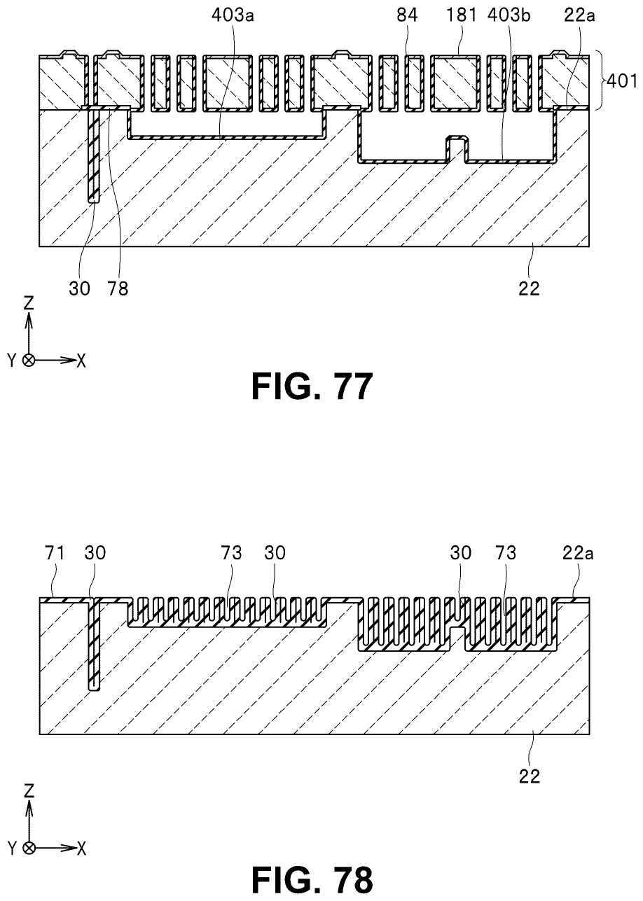

FIG. 77 illustrates the following step. In this step, first, an insulating film 84 is formed on an exposed front surface of the substrate 22 and an exposed front surface of the movable unit 401. The insulating film 84 may be an SiO₂ film formed by the thermal oxidation method, for example. Subsequently, an insulating film 82 is removed. The insulating film 82 may be removed by dry etching, or may be removed by etching using hot phosphoric acid as an etchant.

Subsequently, the movable unit 401 is fixed to the circuit unit 402. The subsequent steps are similar to those in the tenth embodiment.

The configuration, operation and effects of the present embodiment are otherwise the same as those of the tenth embodiment.

### Twelfth Embodiment

Next, a manufacturing method of the MEMS device 400 according to a twelfth embodiment of the disclosure is described. With reference to FIG. 78 to FIG. 84, description is made below on the differences between the manufacturing method of the MEMS device 400 according to the present embodiment and the manufacturing method of the MEMS device 400 according to the tenth embodiment. FIG. 78 to FIG. 84 are cross-sectional views illustrating a stacked body in the manufacturing process of the MEMS device 400.

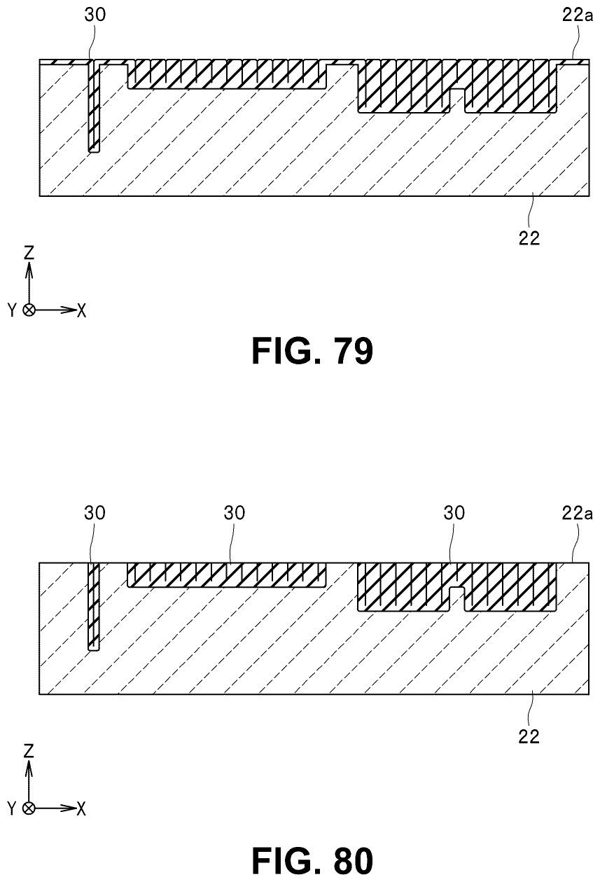

The manufacturing method of the MEMS device 400 according to the present embodiment is basically similar to the tenth embodiment up to the step of forming the trench 76 illustrated in FIG. 58. However, in the present embodiment, the step of forming the insulating film 71 is omitted. FIG. 78 illustrates the following step. In this step, the insulating film 30 is formed in the plurality of trenches 73 and the trench 76. The insulating film 30 may be an SiO₂ film formed by the thermal oxidation method, for example. In this case, the substrate 22 is oxidized from the wall surface and the bottom surface of each of the plurality of trenches 73 and the trench 76, and an SiO₂ film (the insulating film 30) is formed in the plurality of trenches 73 and the trench 76. FIG. 78 illustrates the midst of the step of forming the insulating film 30. Particularly in the present embodiment, the insulating film 30 is formed so as to completely fill the plurality of trenches 73 and the trench 76. FIG. 79 illustrates the stacked body after the insulating film 30 is formed. Note that, in the present embodiment, the insulating film 30 is also formed on the first surface 22a of the substrate 22.

FIG. 80 illustrates the following step. In this step, the insulating film 30 is polished until the first surface 22a of the substrate 22 is exposed.

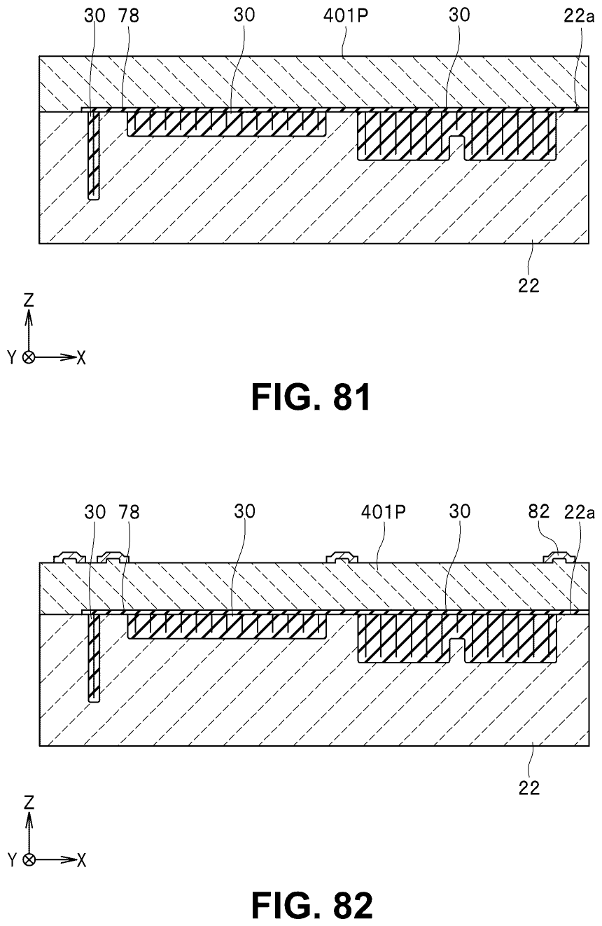

FIG. 81 illustrates the following step. In this step, first, the insulating film 78 formed of, for example, Si₃N₄ is formed on the upper surface of the stacked body. The insulating film 78 may be formed so as not to cover the region where the plurality of electrodes 23 or the plurality of electrodes 27 are to be subsequently formed. Subsequently, the initial movable unit 401P that later serves as the movable unit 401 is formed on the entire upper surface of the stacked body. The initial movable unit 401P may be formed of epitaxial polysilicon, or may be formed of a low-stress polysilicon material.

FIG. 82 illustrates the following step. In this step, first, similarly to the step illustrated in FIG. 63 in the tenth embodiment, the upper surface of the initial movable unit 401P is partially subjected to etching. Subsequently, the conductive layer 82 is formed on the initial movable unit 401P. The conductive layer 82 may contain metal used for eutectic bonding.

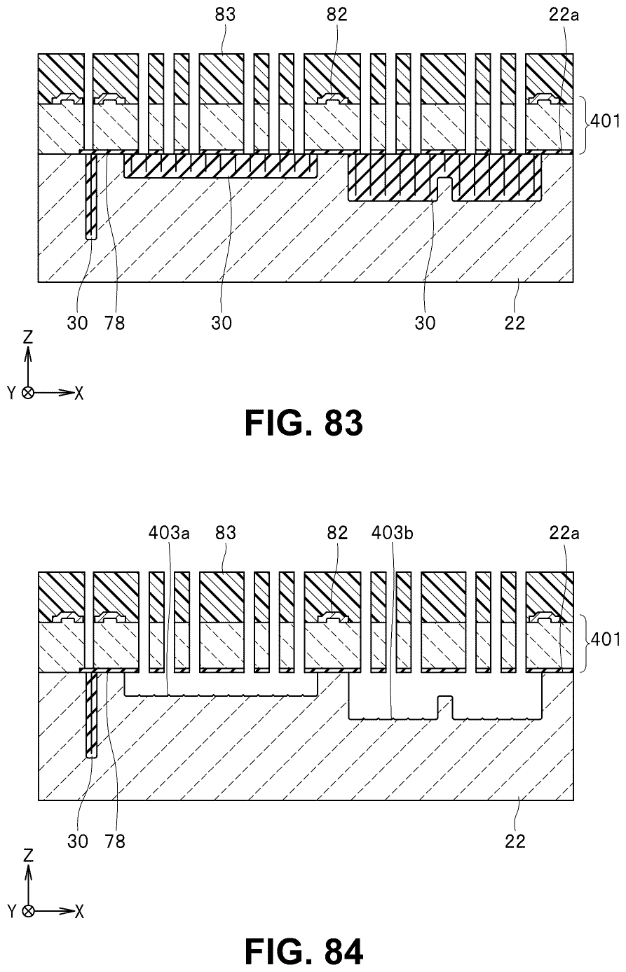

FIG. 83 illustrates the following step. In this step, first, the photoresist mask 83 having a shape corresponding to the movable unit 401 is formed on the initial movable unit 401P and the conductive layer 82. Subsequently, the photoresist mask 83 is used as an etching mask, and the initial movable unit 401P and the insulating film 78 are subjected to deep etching through RIE, for example. The initial movable unit 401P and the insulating film 78 are subjected to etching until parts formed in the plurality of trenches 73 of the insulating film 30 are exposed. Through the etching, the initial movable unit 401P serves as the movable unit 401.

FIG. 84 illustrates the following step. In this step, parts formed in the plurality of trenches 73 of the insulating film 30 is removed through etching. With this, the cavities 403a and 403b of the cap 403 are formed in the substrate 22. A plurality of micro protrusions may be formed on the bottom surface of each of the cavities 403a and 403b by subjecting the insulating film 30 to etching. The subsequent steps are similar to those in the tenth embodiment.

The configuration, operation and effects of the present embodiment are otherwise the same as those of the tenth embodiment.

### Thirteenth Embodiment

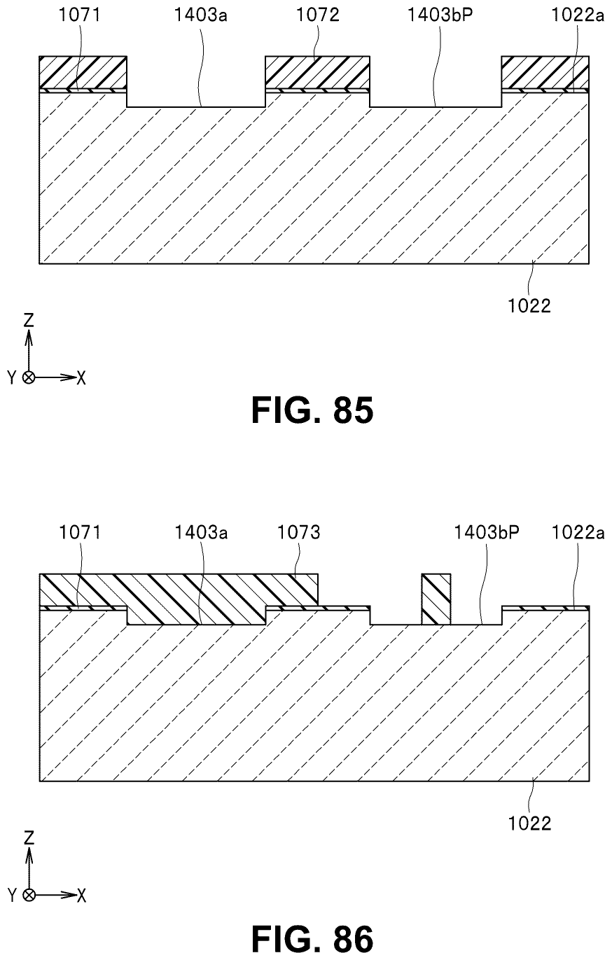

Next, a manufacturing method of the MEMS device 400 according to a thirteenth embodiment of the disclosure is described. The MEMS device 400 according to the present embodiment includes a movable unit 1401 and a cap 1403 in place of the movable unit 401 and the cap 403 of the tenth embodiment. With reference to FIG. 85 to FIG. 96, the manufacturing method of the MEMS device 400 according to the present embodiment is described below. FIG. 85 to FIG. 96 are cross-sectional views illustrating a stacked body in the manufacturing process of the MEMS device 400. The following description involves description on a step of forming the movable unit 1401 and the cap 1403.

In the step of forming the movable unit 1401 and the cap 1403, first, as illustrated in FIG. 85, an insulating film 1071 formed of, for example, Si₃N4 is formed on a first surface 1022a of a substrate 1022. Subsequently, a photoresist mask 1072 is formed on the insulating film 1071. Subsequently, the insulating film 1071 is selectively subjected to etching, for example, RIE by using the photoresist mask 1072 as an etching mask. Subsequently, the insulating film 1071 and the photoresist mask 1072 are used as etching masks, and a cavity 1403a and an initial cavity 1403bP are formed in the substrate 1022 by RIE, for example. Subsequently, the photoresist mask 1072 is removed.

FIG. 86 illustrates the following step. In this step, a photoresist mask 1073 is formed on the substrate 1022 and the insulating film 1071. The photoresist mask 1073 covers the cavity 1403a, and includes an opening portion from which a part of the initial cavity 1403bP is exposed.

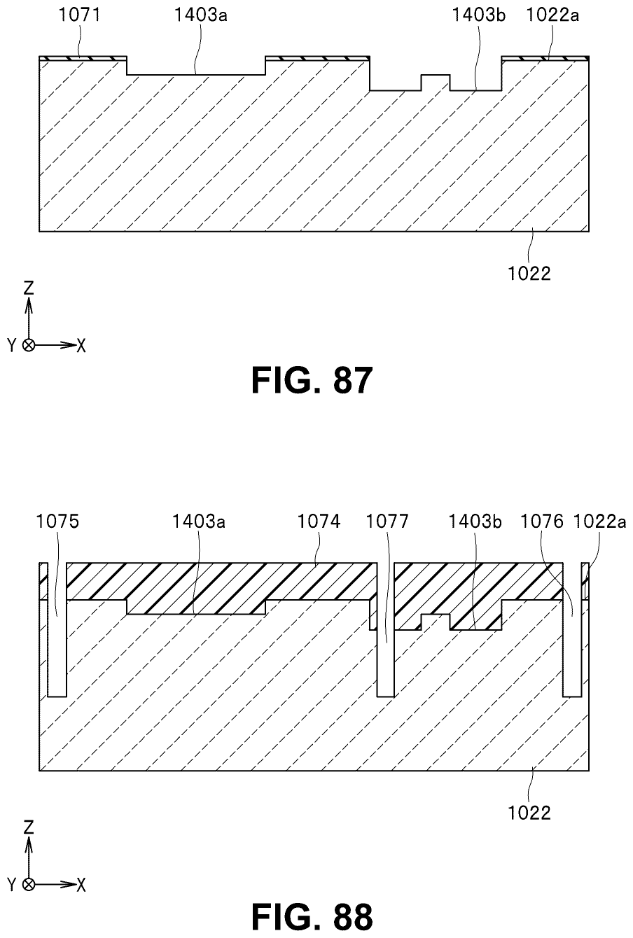

FIG. 87 illustrates the following step. In this step, first, the insulating film 1071 and the photoresist mask 1073 are used as etching masks, and the substrate 1022 is subjected to etching, for example, RIE so that a depth of a part of the initial cavity 1403bP is increased. Through the etching, the initial cavity 1403bP serves as a cavity 1403b. Subsequently, the photoresist mask 1073 is removed.

FIG. 88 illustrates the following step. In this step, first, the insulating film 1071 is removed. Subsequently, a photoresist mask 1074 is formed on the entire upper surface of the stacked body. The photoresist mask 1074 covers the cavity 1403a, and includes an opening portion from which a part of the cavity 1403b is exposed. Subsequently, the photoresist mask 1074 is used as an etching mask, and the substrate 1022 is subjected to deep etching through RIE, for example so that trenches 1075, 1076. and 1077 are formed in the substrate 1022. Particularly in the present embodiment, the trench 1077 is formed in the cavity 1403b. Subsequently, the photoresist mask 1074 is removed.

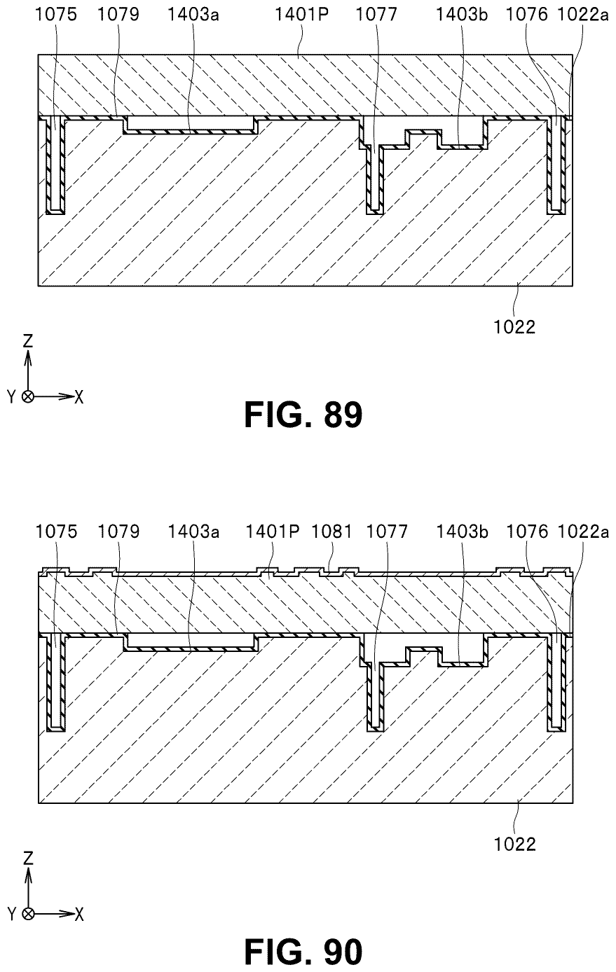

FIG. 89 illustrates the following step. In this step, first, an insulating film 1079 is formed on the front surface of the substrate 1022. The insulating film 1079 may be an SiO₂ film formed by the thermal oxidation method, for example. Subsequently, an initial movable unit 1401P that later serves as the movable unit 1401 is joined to the substrate 1022. The initial movable unit 1401P may be a silicon substrate. The initial movable unit 1401P may be joined to the substrate 1022 by fusion bonding. Subsequently, a surface (polishing surface) of the initial movable unit 1401P, which is on a side opposite to the surface facing the substrate 1022, is polished so that the initial movable unit 1401P has a predetermined thickness.

FIG. 90 illustrates the following step. In this step, first, similarly to the step illustrated in FIG. 63 in the tenth embodiment, the upper surface of the initial movable unit 1401P is partially subjected to etching. Subsequently, a conductive layer 1081 is formed on the initial movable unit 1401P. Particularly in the present embodiment, the conductive layer 1081 may be formed of polysilicon.

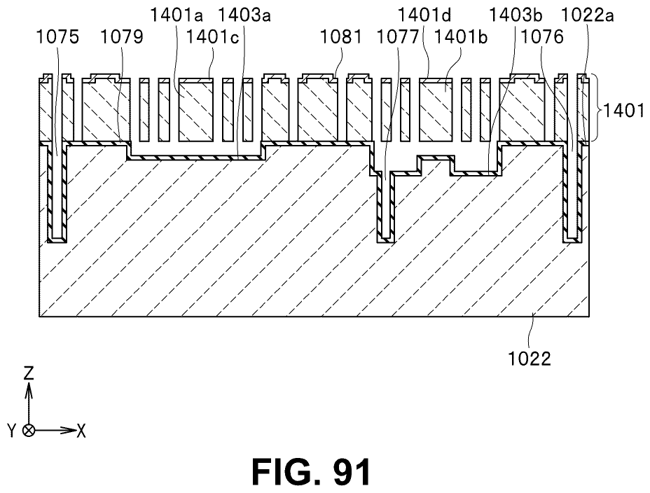

FIG. 91 illustrates the following step. In this step, first, a photoresist mask having a shape corresponding to the movable unit 1401, which is omitted in illustration, is formed on the initial movable unit 1401P and the conductive layer 1081.

Subsequently, a photoresist mask, which is omitted in illustration, is used as an etching mask, and the initial movable unit 1401P is subjected to deep etching through RIE, for example. During the etching, a through hole passing through the trench 1075 and a through hole passing through the trench 1076 are also formed. Through the etching, the initial movable unit 1401P serves as the movable unit 1401. The movable unit 1401 includes movable elements 1401a and 1401b as weights, a structure of fixing the movable elements 1401a and 1401b, an electrode (movable electrode) 1401c provided to the movable element 1401a, and an electrode (movable electrode) 1401d provided to the movable element 1401b. The electrodes 1401c and 1401d are formed by subjecting the conductive layer 1081 to etching. Subsequently, the photoresist mask, which is omitted in illustration, is removed.

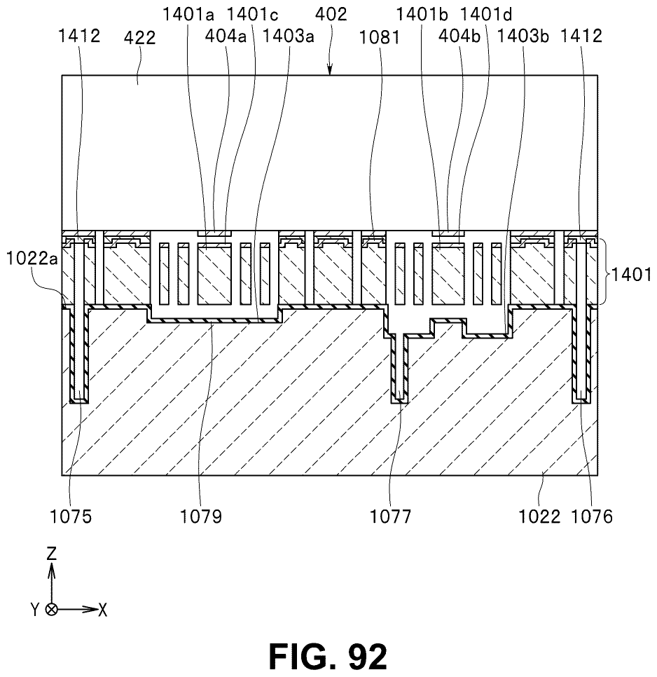

FIG. 92 illustrates the following step. In this step, the movable unit 1401 is fixed to the circuit unit 402. The movable unit 1401 may be fixed to the circuit unit 402 by eutectic bonding, for example. In FIG. 92, the reference symbol 1412 indicates an electrode that connects the movable unit 1401 and the circuit unit 402 to each other.

The stationary electrodes 404a and 404b formed on the first surface of the substrate 422 of the circuit unit 402 face the electrodes 1401c and 1401d, respectively. In the present embodiment, the movable unit 1401 may be fixed to the circuit unit 402 so that the space that includes the cavity 1403a and is surrounded by the circuit unit 402 and the substrate 1022 is maintained under a vacuum state after the movable unit 1401 is fixed to the circuit unit 402.

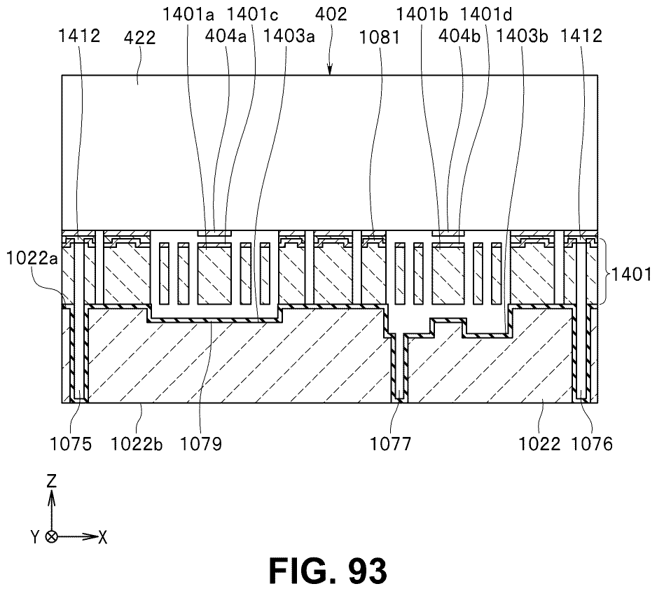

FIG. 93 illustrates the following step. In this step, the substrate 1022 is polished until the insulating film 1079 formed in the trenches 1075 to 1077 is exposed. The substrate 1022 is polished from a polishing surface on a side opposite to the first surface 1022a of the substrate 1022. The polishing surface after polishing serves as a second surface 1022b of the substrate 1022.

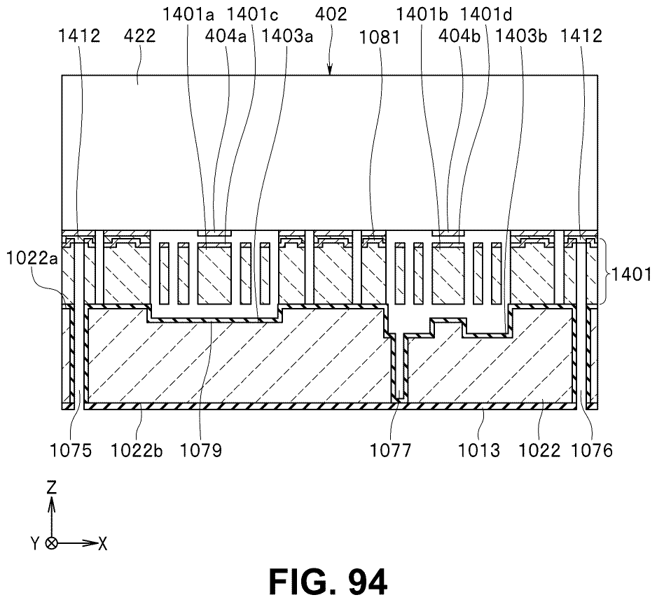

FIG. 94 illustrates the following step. In this step, first, the insulating film 1013 is formed on the second surface 1022b of the substrate 1022. Subsequently, at least one through hole passing through the trenches 1075 and 1076 is formed in the insulating films 1013 and 1079.

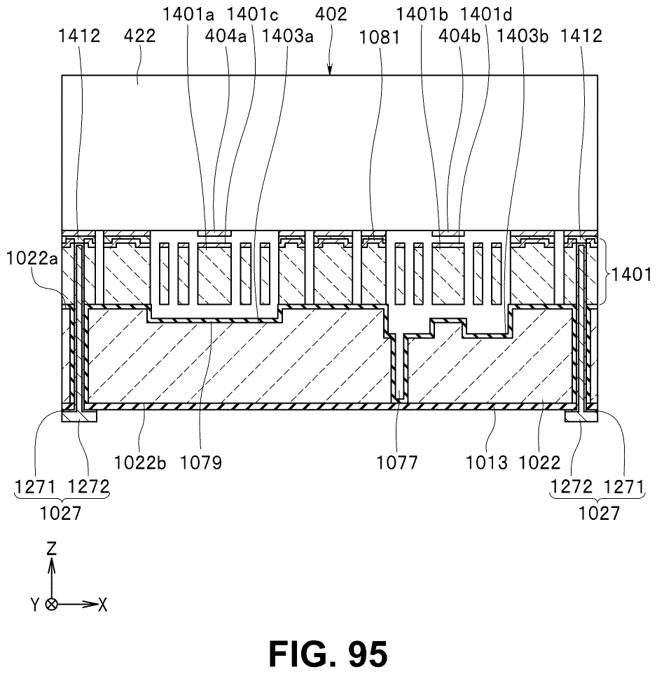

FIG. 95 illustrates the following step. In this step, first, a step of forming an electrode 1027 in each of the trench 1075 and 1076 is performed. The electrode 1027 includes a first layer 1271 and a second layer 1272. In the step of forming the electrode 1027, first, the first layer 1271 is formed in the trenches 1075 and 1076. The first layer 1271 is also formed on the insulating film 1013. The first layer 1271 is formed by the electroless plating method, for example. Subsequently, the second layer 1272 is formed on the first layer 1271. The second layer 1272 is formed by the electroplating method, for example. The first layer 1271 is used as an electrode and a seed layer at the time of forming the second layer 1272 by the electroplating method. Subsequently, the part of the first layer 1271, which is not covered with the second layer 1272, is removed. The electrode 1027 is electrically connected to the electrode 1412.

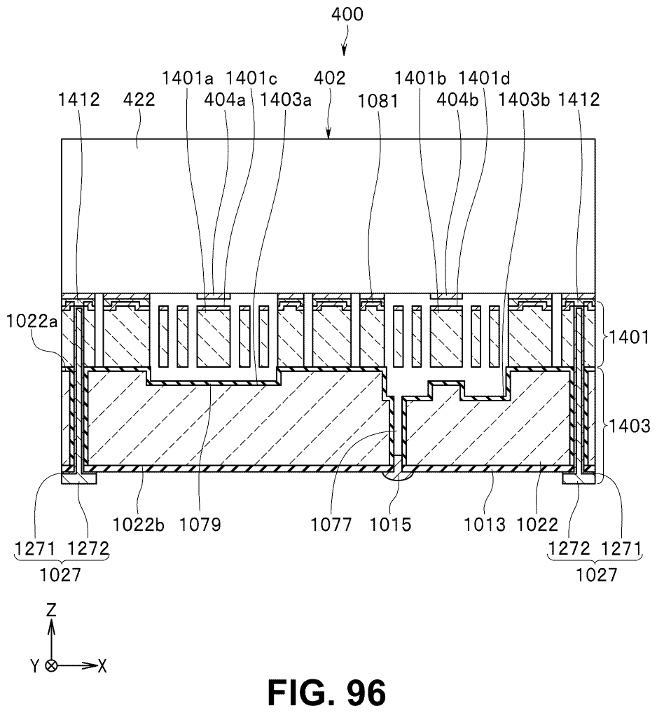

FIG. 96 illustrates the following step. In this step, first, at least one through hole communicating with the trench 1077 is formed in the insulating films 1013 and 1079. Particularly in the present embodiment, at least one through hole may include a plurality of through holes. The cavity 1403b communicates with the outside through the trench 1077 and at least one through hole. Subsequently, for example, a sealing member 1015 formed of a metal material seals at least one through hole so that the space that includes the cavity 1403b and is surrounded by the circuit unit 402 and the substrate 1022 is maintained under a vacuum state. With this, the cap 1403 is completed, and thus the MEMS device 400 is completed. As a metal material of the sealing member 1015, for example, an alloy such as Ti, Au, and AlCu is used.

As described above, in the present embodiment, the space that includes the cavity 1403a and is surrounded by the circuit unit 402 and the substrate 1022 (hereinafter, referred to as a first space) and the space that includes the cavity 1403b and is surrounded by the circuit unit 402 and the substrate 1022 (hereinafter, referred to as a second space) are sealed at the different timing. With this, according to the present embodiment, the vacuum degree of the first space and the vacuum degree of the second space can be controlled independently. In the present embodiment, the vacuum degree of the first space and the vacuum degree of the second space may be different from each other.

Note that, in the present embodiment, instead of forming the plurality of electrodes 1027, a plurality of electrodes similar to the plurality of electrodes 23 in the first embodiment and the second embodiment may be formed, or the plurality of electrodes 27 in the third embodiment and the fourth embodiment may be formed. The configuration, operation and effects of the present embodiment are otherwise the same as those of any one of the first embodiment to the fourth embodiment and the tenth embodiment.

### Fourteenth Embodiment

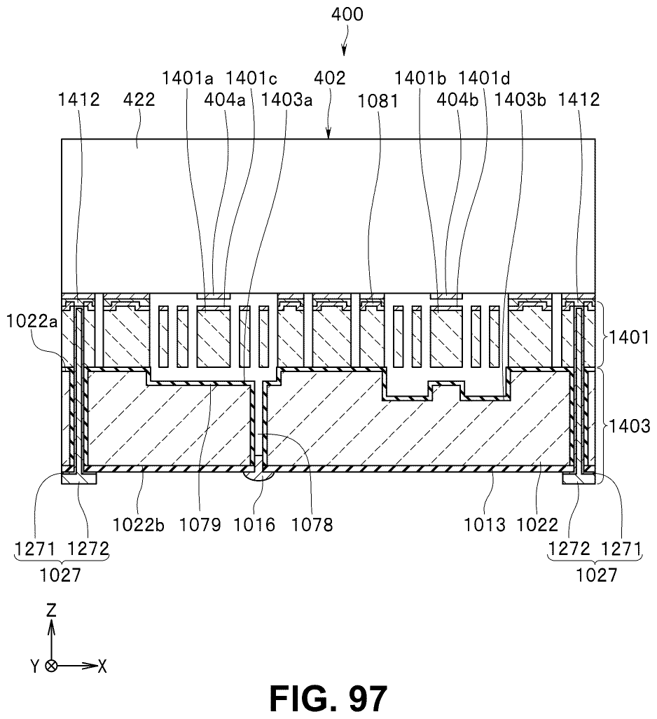

Next, the MEMS device 400 according to a fourteenth embodiment of the disclosure is described. With reference to FIG. 97, description is made below on the differences between the MEMS device 400 according to the present embodiment and the MEMS device 400 according to the thirteenth embodiment. FIG. 97 is a cross-sectional view illustrating the MEMS device 400 according to the present embodiment.

In the present embodiment, the cap 1403 includes a trench 1078 and a sealing member 1016 in place of the trench 1077 and the sealing member 1015 in the thirteenth embodiment. The trench 1078 is formed in the cavity 1403a. Each of the insulating films 1013 and 1079 includes at least one through hole communicating with the trench 1077. The sealing member 1016 is formed of, for example, metal, and seals the space that includes the cavity 1403a and is surrounded by the circuit unit 402 and the substrate 1022 so that the space is maintained in a vacuum state.

Note that, in the present embodiment, the movable unit 1401 may be fixed to the circuit unit 402 so that the space that includes the cavity 1403b and is surrounded by the circuit unit 402 and the substrate 1022 is maintained in a vacuum state after the movable unit 1401 is fixed to the circuit unit 402.

The configuration, operation and effects of the present embodiment are otherwise the same as those of the thirteenth embodiment.

Note that the disclosure is not limited to each of the embodiments described above, and various modifications may be made thereto. For example, the step of forming the movable unit 401 and the cap 403 of the MEMS device 400 according to the tenth embodiment is applicable to the step of forming the movable unit 101 and the cap 103 of the MEMS device 100 according to the sixth embodiment and the seventh embodiment, except that the plurality of electrodes 23 or the plurality of electrodes 27 are formed in the cap 403.

The circuit unit 102 in the sixth embodiment and the seventh embodiment may be configured by using the through-hole electrode substrate 21 in the fifth embodiment. The cap 403 in the eighth embodiment and the tenth embodiment may be configured by using the through-hole electrode substrate 21 in the fifth embodiment.

In the tenth embodiment, the insulating layer 77 is not a necessary constituent element, and may not be provided.

As described above, a through-hole electrode substrate of the disclosure includes a substrate including a first surface and a second surface on a side opposite to the first surface, at least one electrode extending from the first surface to the second surface, and an insulating film including a first part extending along the at least one electrode and contacting with the at least one electrode, a second part extending along the first part and being adjacent to the first part, and a boundary surface between the first part and the second part.

In the through-hole electrode substrate of the disclosure, the insulating film may further include a third part provided on the first surface. A total thickness of the first part and the second part may be equal to or more than a thickness of the third part. The second part and the third part may be continuous to each other. Alternatively, the second part and the third part may not be continuous to each other.

In the through-hole electrode substrate of the disclosure, the first part and the second part may surround the at least one electrode.

In the through-hole electrode substrate of the disclosure, the at least one electrode may include a first end portion and a second end portion that are positioned at both ends in an extension direction of the at least one electrode. The first end portion may be at a position closer to the first surface with respect to the second surface. The second end portion may be at a position closer to the second surface with respect to the first surface. An interval between the first end portion and the second end portion in the extension direction may be more than an interval between the first surface and the second surface in the extension direction.

In the through-hole electrode substrate of the disclosure, the at least one electrode may be made of silicon in which an impurity is diffused or metal.

The through-hole electrode substrate of the disclosure may further include an electrode pad. The at least one electrode may include a plurality of electrodes connected to the electrode pad.

A MEMS device according to a first aspect of the disclosure is a MEMS device including a movable unit, and a circuit unit and a cap that are arranged to sandwich the movable unit. The circuit unit is configured by using the through-hole electrode substrate of the disclosure.

The MEMS device according to the first aspect of the disclosure may be mounted on a mounting target object to fix the circuit unit to the mounting target object. The first surface of the substrate may face the movable unit. The second surface of the substrate may face the mounting target object. The at least one electrode may include a first end portion and a second end portion that are positioned at both ends in an extension direction of the at least one electrode. The first end portion may be at a position closer to the first surface with respect to the second surface. The second end portion may be at a position closer to the second surface with respect to the first surface. The MEMS device may further include an electrode pad connected to the second end portion. The electrode pad may be directly connected to a wiring layer of the mounting target object in a state that the MEMS device is mounted on the mounting target object.

The MEMS device according to the first aspect of the disclosure may be mounted on a mounting target object to fix the cap to the mounting target object. The first surface of the substrate may face the movable unit. The second surface of the substrate may be oriented to a side opposite the mounting target object. The at least one electrode may include a first end portion and a second end portion that are positioned at both ends in an extension direction of the at least one electrode. The first end portion may be at a position closer to the first surface with respect to the second surface. The second end portion may be at a position closer to the second surface with respect to the first surface. The MEMS device may further include an electrode pad connected to the second end portion. The electrode pad may be connected to a wiring layer of the mounting target object via a bonding wire in a state that the MEMS device is mounted on the mounting target object.

A manufacturing method of the MEMS device according to the first aspect of the disclosure includes a step of forming the movable unit and the cap, and a step of forming the circuit unit. The step of forming the circuit unit includes a through-hole electrode formation step of forming the at least one electrode and the insulating film on the substrate, and a circuit formation step of forming a signal processing circuit on the substrate.

In the manufacturing method of the MEMS device according to the first aspect of the disclosure, the substrate may be a silicon substrate. The through-hole electrode formation step may include a step of forming at least one trench from the first surface of the substrate toward an inside of the substrate, a step of diffusing an impurity from a wall surface and a bottom surface of the at least one trench into the substrate to form an impurity diffusion region that later serves as at least one electrode, a step of forming the insulating film in the at least one trench, and a polishing step of polishing a surface of the substrate opposite to the first surface so that the impurity diffusion region serves the at least one electrode. The polishing step may be performed after the circuit formation step, and may be performed until the insulating film and the impurity diffusion region are exposed.

Further in the manufacturing method of the MEMS device according to the first aspect of the disclosure, the through-hole electrode formation step may include a step of forming at least one trench from the first surface of the substrate toward an inside of the substrate, a step of forming the insulating film in the at least one trench, a polishing step of polishing a surface of the substrate opposite to the first surface to expose the insulating film, a step of forming at least one through hole by removing a part surrounded by the insulating film from the substrate after the polishing step, and a step of forming the at least one electrode in the at least one through hole. The polishing step may be performed after the circuit formation step.

A MEMS device according to a second aspect of the disclosure includes a movable unit, and a circuit unit and a cap that are arranged to sandwich the movable unit. The cap is configured by using the through-hole electrode substrate of the disclosure.

A manufacturing method of the MEMS device according to the second aspect of the disclosure includes a step of forming the movable unit and the cap, and a step of forming the circuit unit. The step of forming the movable unit and the cap includes a through-hole electrode formation step of forming the at least one electrode and the insulating film on the substrate, a step of forming an insulating portion on the substrate, a step of forming the movable unit on the substrate and the insulating portion, and a step of forming a cavity in the substrate by forming the movable unit and then removing the insulating portion through etching.

In the manufacturing method of the MEMS device according to the second aspect of the disclosure, the insulating portion may include an insulating layer formed of phosphosilicate glass.

In the manufacturing method of the MEMS device according to the second aspect of the disclosure, the movable unit may be formed of epitaxial polysilicon.

In the manufacturing method of the MEMS device according to the second aspect of the disclosure, the substrate may be a silicon substrate. The step of forming the movable unit and the cap may further include a step of forming a plurality of trenches from the first surface of the substrate toward an inside of the substrate. The step of forming the insulating portion may include a step of forming an oxide insulating film by oxidizing the substrate from a wall surface and a bottom surface of each of the plurality of trenches, and a step of forming an insulating film formed of phosphosilicate glass in each of the plurality of trenches.

A multilayered device of the disclosure includes a plurality of devices being stacked. Each of the plurality of devices is configured by using the through-hole electrode substrate of the disclosure. Among the plurality of devices, the at least one electrode of one of two adjacent devices is electrically connected to the at least one electrode of the other of two adjacent devices.

1. A through-hole electrode substrate comprising:
a substrate including a first surface and a second surface on a side opposite to the first surface;
at least one electrode extending from the first surface to the second surface; and
an insulating film including a first part extending along the at least one electrode and contacting with the at least one electrode, a second part extending along the first part and being adjacent to the first part, and a boundary surface between the first part and the second part.

2. The through-hole electrode substrate according to claim 1, wherein
the insulating film further includes a third part provided on the first surface, and
a total thickness of the first part and the second part is equal to or more than a thickness of the third part.

3. The through-hole electrode substrate according to claim 2, wherein
the second part and the third part are continuous to each other.

4. The through-hole electrode substrate according to claim 2, wherein
the second part and the third part are not continuous to each other.

5. The through-hole electrode substrate according to claim 1, wherein
the first part and the second part surround the at least one electrode.

6. The through-hole electrode substrate according to claim 1, wherein
the at least one electrode includes a first end portion and a second end portion that are positioned at both ends in an extension direction of the at least one electrode,
the first end portion is at a position closer to the first surface with respect to the second surface,
the second end portion is at a position closer to the second surface with respect to the first surface, and
an interval between the first end portion and the second end portion in the extension direction is more than an interval between the first surface and the second surface in the extension direction.

7. The through-hole electrode substrate according to claim 1, wherein
the at least one electrode is made of silicon in which an impurity is diffused or metal.

8. The through-hole electrode substrate according to claim 1, further comprising:
an electrode pad, wherein
the at least one electrode includes a plurality of electrodes connected to the electrode pad.

9. A MEMS device comprising:
a movable unit; and
a circuit unit and a cap that are arranged to sandwich the movable unit, wherein
the circuit unit is configured by using the through-hole electrode substrate according to claim 1.

10. The MEMS device according to claim 9, wherein
the MEMS device is mounted on a mounting target object to fix the circuit unit to the mounting target object,
the first surface of the substrate faces the movable unit,
the second surface of the substrate faces the mounting target object,
the at least one electrode includes a first end portion and a second end portion that are positioned at both ends in an extension direction of the at least one electrode,
the first end portion is at a position closer to the first surface with respect to the second surface,
the second end portion is at a position closer to the second surface with respect to the first surface,
the MEMS device further includes an electrode pad connected to the second end portion, and
the electrode pad is directly connected to a wiring layer of the mounting target object in a state that the MEMS device is mounted on the mounting target object.

11. The MEMS device according to claim 9, wherein
the MEMS device is mounted on a mounting target object to fix the cap to the mounting target object,
the first surface of the substrate faces the movable unit,
the second surface of the substrate is oriented to a side opposite the mounting target object,
the at least one electrode includes a first end portion and a second end portion that are positioned at both ends in an extension direction of the at least one electrode,
the first end portion is at a position closer to the first surface with respect to the second surface,
the second end portion is at a position closer to the second surface with respect to the first surface,
the MEMS device further includes an electrode pad connected to the second end portion, and
the electrode pad is connected to a wiring layer of the mounting target object via a bonding wire in a state that the MEMS device is mounted on the mounting target object.

12. A manufacturing method of the MEMS device according to claim 9, the manufacturing method comprising:
a step of forming the movable unit and the cap; and
a step of forming the circuit unit, wherein
the step of forming the circuit unit includes a through-hole electrode formation step of forming the at least one electrode and the insulating film on the substrate, and a circuit formation step of forming a signal processing circuit on the substrate.

13. The manufacturing method according to 12, wherein
the substrate is a silicon substrate,
the through-hole electrode formation step includes:
a step of forming at least one trench from the first surface of the substrate toward an inside of the substrate;
a step of diffusing an impurity from a wall surface and a bottom surface of the at least one trench into the substrate to form an impurity diffusion region that later serves as at least one electrode;
a step of forming the insulating film in the at least one trench; and
a polishing step of polishing a surface of the substrate opposite to the first surface so that the impurity diffusion region serves the at least one electrode, and
the polishing step is performed after the circuit formation step, and is performed until the insulating film and the impurity diffusion region are exposed.

14. The manufacturing method according to 12, wherein
the through-hole electrode formation step includes:
a step of forming at least one trench from the first surface of the substrate toward an inside of the substrate;
a step of forming the insulating film in the at least one trench;
a polishing step of polishing a surface of the substrate opposite to the first surface to expose the insulating film;
a step of forming at least one through hole by removing a part surrounded by the insulating film from the substrate after the polishing step; and
a step of forming the at least one electrode in the at least one through hole, and
the polishing step is performed after the circuit formation step.

15. A MEMS device comprising:
a movable unit; and
a circuit unit and a cap that are arranged to sandwich the movable unit, wherein
the cap is configured by using the through-hole electrode substrate according to claim 1.

16. A manufacturing method of the MEMS device according to claim 15, the manufacturing method comprising:
a step of forming the movable unit and the cap; and
a step of forming the circuit unit, wherein
the step of forming the movable unit and the cap includes:
a through-hole electrode formation step of forming the at least one electrode and the insulating film on the substrate;
a step of forming an insulating portion on the substrate;
a step of forming the movable unit on the substrate and the insulating portion; and
a step of forming a cavity in the substrate by forming the movable unit and then removing the insulating portion through etching.

17. The manufacturing method according to claim 16, wherein
the insulating portion includes an insulating layer formed of phosphosilicate glass.

18. The manufacturing method according to claim 16, wherein
the movable unit is formed of epitaxial polysilicon.

19. The manufacturing method according to claim 16, wherein
the substrate is a silicon substrate,
the step of forming the movable unit and the cap further includes a step of forming a plurality of trenches from the first surface of the substrate toward an inside of the substrate, and
the step of forming the insulating portion includes:
a step of forming an oxide insulating film by oxidizing the substrate from a wall surface and a bottom surface of each of the plurality of trenches; and
a step of forming an insulating film formed of phosphosilicate glass in each of the plurality of trenches.

20. A multilayered device comprising:
a plurality of devices being stacked, wherein
each of the plurality of devices is configured by using the through-hole electrode substrate according to claim 1,
among the plurality of devices, the at least one electrode of one of two adjacent devices is electrically connected to the at least one electrode of the other of two adjacent devices.
